(19) United States
(12) Patent Application Publication
(10) Pub. No.: US 2026/0324192 A1
(43) Pub. Date: Oct. 15, 2026

(54) ELECTRONIC DEVICE

(71) Applicant: Samsung Display Co., Ltd., Yongin-si (KR)

(72) Inventors: GI-NA YOO, Yongin-si (KR); HYOMIN KIM, Yongin-si (KR); JIHYE KIM, Yongin-si (KR); SIJIN SUNG, Yongin-si (KR)

(21) Appl. No.: 19/637,967

(22) Filed: Apr. 2, 2026

(30) Foreign Application Priority Data
Apr. 4, 2025 (KR) 10-2025-0044312

(51) Int. Cl. H10K 50/17; H10K 59/35; H10K 102/00

(52) U.S. Cl. CPC H10K 50/17; H10K 59/353; H10K 2102/351

(57) ABSTRACT

An electronic device includes a display panel including a first pixel having a first opening area, a second pixel having a second opening area smaller than the first opening area, a first light emitting element corresponding to the first pixel, and a second light emitting element corresponding to the second pixel. Each of the first light emitting element and the second light emitting element includes a first electrode, organic layers, and a second electrode, a first hole injection layer included in the first light emitting element includes a first doped region including a p-dopant and having a first thickness, and a second hole injection layer included in the second light emitting element includes a second doped region including the p-dopant and having a second thickness greater than the first thickness, or includes a second doped region including the p-dopant and having a third thickness equal to the first thickness.

### CROSS-REFERENCE TO RELATED APPLICATION

The present application claims priority to and the benefit of Korean Patent Application No. 10-2025-0044312, filed on Apr. 4, 2025, in the Korean Intellectual Property Office, the entire content of which is incorporated herein by reference.

### BACKGROUND

### 1. Field

One or more embodiments of the present disclosure described herein relates to an electronic device, for example, an electronic device including a display panel exhibiting improved display quality.

### 2. Description of the Related Art

Electronic devices including display panels are widely used in various applications (e.g., in a variety of devices), including television sets, mobile phones, tablets, and vehicle systems. In certain usage environments—such as those requiring information privacy or compliance with safety regulations—it is desirable or necessary to restrict the viewing angle of the display surface. Accordingly, ongoing research efforts are directed toward technologies that limit viewing angles in a controlled manner.

### SUMMARY

Aspects according to one or more embodiments of the present disclosure are directed towards an electronic device with improved display quality and reliability.

Additional aspects of embodiments will be set forth in part in the description which follows and, in part, will be apparent from the description, or may be learned by practice of the presented embodiments of the disclosure.

One or more embodiments of the disclosure provide an electronic device including a display panel including a first pixel having a first opening area, a second pixel having a second opening area smaller than the first opening area, a first light emitting element arranged corresponding to the first pixel, and a second light emitting element arranged corresponding to the second pixel. Each of the first light emitting element and the second light emitting element includes a first electrode, a plurality of organic layers, and a second electrode, the organic layers of the first light emitting element include a first hole transport region including a first hole injection layer, a first emission layer, and a first electron transport region, the organic layers of the second light emitting element include a second hole transport region including a second hole injection layer, a second emission layer, and a second electron transport region, the first hole injection layer includes a first doped region including a p-dopant and having a first thickness, and the second hole injection layer includes a second doped region including the p-dopant and having a second thickness greater than the first thickness, or includes a second doped region including the p-dopant and having a third thickness equal to the first thickness.

According to one or more embodiments, the second hole injection layer may include the second doped region having the second thickness, the first doped region may be in direct contact with the first electrode of the first light emitting element, and the second doped region may be in direct contact with the first electrode of the second light emitting element.

According to one or more embodiments, the first hole injection layer may further include a first undoped region that does not include the p-dopant, the second hole injection layer may further include a second undoped region that does not include the p-dopant, the first undoped region may be provided on the first doped region, and the second undoped region may be provided on the second doped region.

According to one or more embodiments, the first thickness may be greater than about 0 Å and about 50 Å or less, and the second thickness may be greater than about 0 Å and about 100 Å or less.

According to one or more embodiments, for example, the second hole injection layer may include the second doped region having the third thickness, the first doped region may be in direct contact with the first electrode of the first light emitting element, and the second doped region may be spaced apart from the first electrode of the second light emitting element in a thickness direction.

According to one or more embodiments, the first hole injection layer may further include the first undoped region that does not include the p-dopant, the second hole injection layer may further include the second undoped region that does not include the p-dopant, and the second undoped region may include a first sub-undoped region and a second sub-undoped region.

According to one or more embodiments, the first undoped region may be provided on the first doped region, the first sub-undoped region may be in direct contact with the first electrode of the second light emitting element, and the second sub-undoped region may be spaced apart from the first sub-undoped region with the second doped region therebetween.

According to one or more embodiments, each of the first thickness and the third thickness may be about greater than about 0 Å and about 75 Å or less.

According to one or more embodiments, the first hole injection layer and the second hole injection layer may have the same thickness.

According to one or more embodiments, the first hole transport region may further include a first hole transport layer, the second hole transport region may further include a second hole transport layer, the first hole transport layer may be between the first hole injection layer and the first emission layer, and the second hole transport layer may be between the second hole injection layer and the second emission layer.

According to one or more embodiments, the first electron transport region and the second electron transport region each may include at least one of an electron injection layer, an electron transport layer, or a hole blocking layer.

According to one or more embodiments, the display panel displays an image in a first mode or a second mode, the first mode may be a mode that displays the image at a first viewing angle, and the second mode may be a mode that displays the image at a second viewing angle that is narrower than the first viewing angle.

According to one or more embodiments, in the first mode, the first light emitting element may be driven and the second light emitting element may not be driven, and in the second mode, the first light emitting element may not be driven and the second light emitting element may be driven.

According to one or more embodiments, the electronic device may include a display device including the display panel, wherein the display device may include a first region and a second region adjacent to the first region, and at least one of the first region or the second region may be switched to the first mode or the second mode.

According to one or more embodiments, the electronic device may further include an optical path control layer arranged on the display panel, wherein the optical path control layer may include a black matrix in which a transmitting portion is defined.

According to one or more embodiments, on a plane, the second light emitting element may overlap the black matrix.

According to one or more embodiments, of the present disclosure, an electronic device includes a display device including a first pixel group and a second pixel group that are spaced apart in a first direction and displaying images, the first pixel group includes a first red pixel, a first green pixel, and a first blue pixel that are spaced apart in a second direction crossing the first direction, and the second pixel group includes a second red pixel, a second green pixel, and a second blue pixel that are spaced apart in the second direction. The display device includes a plurality of first light emitting elements corresponding to each of the first red pixel, the first green pixel, and the first blue pixel; and a plurality of second light emitting elements corresponding to each of the second red pixel, the second green pixel, and the second blue pixel, the first light emitting elements include a first hole injection layer commonly overlapping the first red pixel, the first green pixel, and the first blue pixel, the second light emitting elements include a second hole injection layer commonly overlapping the second red pixel, the second green pixel, and the second blue pixel, the first hole injection layer includes a first doped region including a p-dopant and having a first thickness, and the second hole injection layer includes a second doped region including the p-dopant and having a second thickness greater than the first thickness, or includes a second doped region including the p-dopant and having a third thickness equal to the first thickness.

According to one or more embodiments, the first red pixel may have a greater area on a plane than the second red pixel, the first green pixel may have a greater area on a plane than the second green pixel, and the first blue pixel may have a greater area on a plane than the second blue pixel.

According to one or more embodiments, the first light emitting elements may include a first red light emitting element corresponding to the first red pixel, a first green light emitting element corresponding to the first green pixel, and a first blue light emitting element corresponding to the first blue pixel, the second light emitting elements may include a second red light emitting element corresponding to the second red pixel, a second green light emitting element corresponding to the second green pixel, and a second blue light emitting element corresponding to the second blue pixel, and each of the first red light emitting element, the first green light emitting element, the first blue light emitting element, the second red light emitting element, the second green light emitting element, and the second blue light emitting element may overlap only the corresponding pixel and include an emission layer provided as a pattern layer.

According to one or more embodiments, each of the first light emitting elements and the second light emitting elements may further include a first electrode, when the second doped region has the second thickness, the first doped region and the second doped region may be in contact with the first electrode, and when the second doped region has the third thickness, the first doped region may be in contact with the first electrode and the second doped region may be spaced apart from the first electrode.

For example, the present disclosure provides an electronic device and display panel architecture that enables mode-dependent pixel driving with tailored hole injection layer configurations to reduce gray crushing and color shift between wide and narrow pixels. By selectively varying the thickness or position of doped regions within hole injection layers corresponding to different pixel types, the device maintains consistent color perception across public and private viewing modes. The described embodiments, including common and patterned layer arrangements, support the pixel group structures, emission layer configurations, and viewing angle control mechanisms, thereby enhancing display quality and reliability in multi-mode environments.

### BRIEF DESCRIPTION OF THE DRAWINGS

The accompanying drawings are included to provide a further understanding of the present disclosure, and are incorporated in and constitute a part of this specification. The drawings illustrate embodiments of the disclosure and, together with the description, serve to explain principles of the present disclosure. In the drawings:

FIG. 1 is a block diagram of an electronic device according to one or more embodiments;

FIG. 2 shows schematic views of an electronic device according to one or more suitable embodiments;

FIG. 3 is a view showing the inside of a vehicle in which an electronic device according to one or more embodiments is arranged;

FIG. 4 is a cross-sectional view of an electronic device according to one or more embodiments;

FIG. 5 is a plan view showing an enlarged partial region of a display device according to one or more embodiments;

FIG. 6A is a cross-sectional view showing a portion of a display device according to one or more embodiments;

FIG. 6B is a cross-sectional view showing a portion of a display device according to one or more embodiments;

FIG. 7A is a cross-sectional view schematically showing a light emitting element according to one or more embodiments;

FIG. 7B is a cross-sectional view schematically showing a light emitting element according to one or more embodiments;

FIG. 7C is a cross-sectional view schematically showing a light emitting element according to one or more embodiments;

FIG. 7D is a cross-sectional view schematically showing a light emitting element according to one or more embodiments;

FIG. 7E is a cross-sectional view schematically showing a light emitting element according to one or more embodiments;

FIG. 8 is a cross-sectional view schematically showing a light emitting element according to one or more embodiments;

FIG. 9A is a cross-sectional view schematically showing a light emitting element according to one or more embodiments;

FIG. 9B is a cross-sectional view schematically showing a light emitting element according to one or more embodiments;

FIGS. 10A and 10B are cross-sectional views showing some components of a display device according to one or more embodiments; and

FIGS. 11A and 11B are graphs showing the results of evaluating gray crushing indices for display devices according to Comparative Example and Example.

### DETAILED DESCRIPTION

The present disclosure may be modified in one or more suitable ways and may take one or more suitable forms, and specific/example embodiments are illustrated in the drawings and will be described in more detail in the text. However, this is not intended to limit the present disclosure to a specific disclosure form, but should be understood to include all modifications, equivalents, or substitutes included in the teachings and technical scope of the disclosure.

In the present disclosure, it will be understood that if (e.g., when) an element (or a region, a layer, a portion, and/or the like) is referred to as being “on”, “connected to” or “coupled to” another element, it may be directly arranged on, connected to, or coupled to the other element, or other elements may be arranged therebetween. In contrast, “directly on” may refer to that there are no additional layers, films, regions, plates, and/or the like, between the element and the other element. For example, “directly on” or “directly under” may refer to two layers or two members are arranged without utilizing an additional member such as an adhesive member therebetween. In the present disclosure, like reference numerals or symbols refer to like elements throughout, and duplicative descriptions thereof may not be provided for conciseness. In the drawings, the thickness, ratio, and/or size of an element may be exaggerated or reduced for effectively describing the technical contents. The term “and/or” or “or” includes any and all combinations of one or more of the associated listed elements.

It will be understood that, although the terms “first”, “second”, and/or the like may be used herein to describe one or more suitable elements, the elements are not to be limited by these terms. These terms are only used to distinguish one element from another element. For instance, a first element could be termed a second element without departing from the scope and teaching of the disclosure. Similarly, a second element could be termed a first element. The singular expressions “a”, “an” and “the” are intended to include the plural forms as well, unless the context clearly indicates otherwise. Further, the utilization of “may” when describing embodiments of the present disclosure refers to “one or more embodiments of the present disclosure”.

In addition, the terms “below”, “under”, “on the lower side”, “above”, “over”, “on the upper side”, and/or the like may be used to describe the relationships between the elements illustrated in the drawings. These terms are relative concepts and are described on the basis of the directions indicated in the drawings.

In the present disclosure, it will be further understood that the terms “includes, includes, has” and/or “including, including, having”, if (e.g., when) used in this specification, specify the presence of stated features, numbers, steps, operations, elements, components or combinations thereof, but do not preclude the possibility of the presence or addition of one or more other features, numbers, steps, operations, elements, components, and/or combinations thereof. Additionally, the terms “comprise(s)/comprising,” “include(s)/including,” “has (have)/having,” or other similar terms include or support the terms “consisting of” and “consisting essentially of,” indicating the presence of stated features, numbers, steps, operations, elements, and/or components, without or essentially without the presence of other features, numbers, steps, operations, elements, components, and/or groups thereof.

The terms “part” and “unit” refer to a software component or a hardware component that performs a specific function. The hardware component may include, for example, a field-programmable gate array (FPGA) or an application-specific integrated circuit (ASIC). The software component may refer to executable codes and/or data used by executable codes in an addressable storage medium. Thus, software components may be, for example, aspect-oriented software components, class components, and task components, and may include processes, functions, attributes, procedures, sub routines, program code segments, drivers, pieces of firmware, micro codes, circuits, data, databases, data structures, tables, arrays, or variables.

Unless otherwise defined, all terms (including technical and scientific terms) used herein have the same meaning as commonly understood by one of ordinary skill in the art to which this invention belongs. Terms in common usage such as those defined in commonly used dictionaries should be interpreted to contextually match the lexical meanings in the relevant art, and should not be interpreted in an idealized or overly formal sense unless otherwise defined explicitly.

Hereinafter, embodiments of the disclosure are described with reference to the drawings.

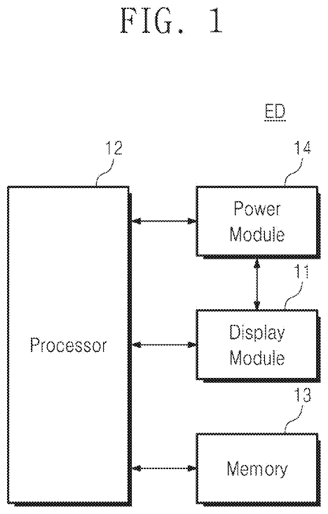

FIG. 1 is a block diagram of an electronic device ED according to one or more embodiments. Referring to FIG. 1, an electronic device ED according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller. The memory 13 may store data information desired or required for the operation of the processor 12 and/or the display module 11. When the processor 12 executes an application stored in the memory 13, image data signals and/or input control signals are transmitted to the display module 11, and the display module 11 may process the received signals and output image information through a display screen. The display module 11 may include a display panel that displays an image.

The power module 14 may include a power supply module such as a power adapter or a battery device, and a power conversion module that converts power supplied by the power supply module to generate power desired or required for the operation of the electronic device ED.

At least one of the components of the electronic device ED described above may be included in a display panel according to one or more embodiments, which will be described in more detail later, and a display device according to one or more embodiments including the display panel. In one or more embodiments, some of the individual modules functionally included in one module may be included in the display device, and others may be separately provided from the display device. For example, the display device may include a display module 11, and the processor 12, the memory 13 and the power module 14 may be provided in the form of other devices within the electronic device ED, rather than the display device.

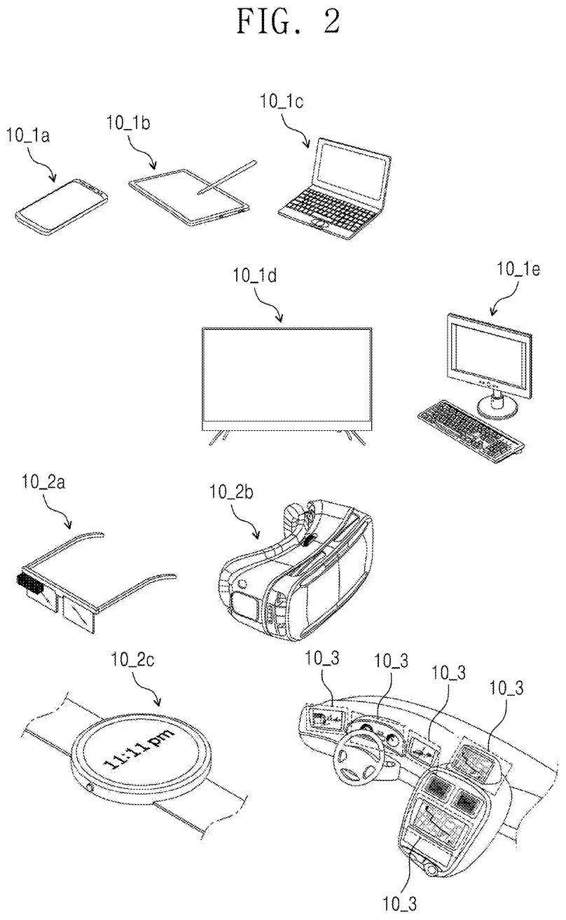

FIG. 2 shows schematic views of electronic devices according to one or more suitable embodiments.

Referring to FIG. 2, one or more suitable electronic devices including the display device according to one or more embodiments may include electronic devices for displaying images, such as a smart phone 10_1a, a tablet PC 10_1b, a laptop 10_1c, a TV 10_1d, and a desk monitor 10_1e, wearable electronic devices such as smart glasses 10_2a, a head mounted display 10_2b, and a smart watch 10_2c, and vehicle electronic devices 10_3 such as a center information display (CID) and a room mirror display arranged on an instrument panel, a center fascia, and/or a dashboard of a vehicle.

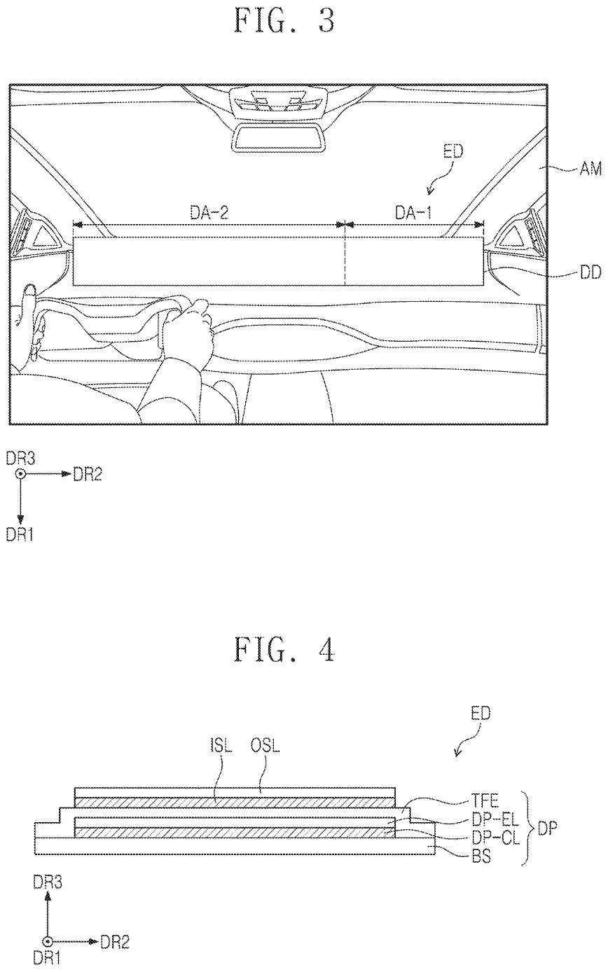

FIG. 3 is a view showing the inside of a vehicle in which an electronic device ED according to one or more embodiments of the disclosure is arranged.

Referring to FIG. 3, the electronic device ED may be arranged inside a vehicle AM to provide suitable information to users (e.g., drivers and front passengers). The electronic device ED may provide users with images such as weather, speed, maps, and/or movies. The electronic device ED may be a touch-based electronic device that is operable according to a user's touch input.

Referring to FIG. 3, the electronic device ED may have a plane defined by a first direction DR1 and a second direction DR2 crossing each other. The electronic device ED may have short sides extending in the first direction DR1 and long sides extending in the second direction DR2. The electronic device ED may have a rectangular shape, but the shape of the electronic device ED is not limited thereto and the electronic device ED may have one or more suitable shapes. For example, corner portions of the electronic device ED, which connect the short sides and the long sides, may have a curved shape.

A front surface of the electronic device ED may be defined as a display surface, and may display images in a third direction DR3 crossing the first direction DR1 and the second direction DR2. Images generated from the electronic device ED may be provided to users through the display surface.

Herein, the first direction DR1 and the second direction DR2 may be perpendicular to each other, and the third direction DR3 may be a direction normal to the plane defined by the first direction DR1 and the second direction DR2. In one or more embodiments, the phrase “on a plane” herein may indicate a view on the plane defined by the first direction DR1 and the second direction DR2. In addition, the phrase “on a plane” may indicate a state viewed in the third direction DR3. A thickness direction may indicate the third direction DR3 which is a normal direction to the plane defined by the first direction DR1 and the second direction DR2.

The electronic device ED may include a display device DD configured to display images. The display device DD may include a display panel, and the display panel may be configured to substantially generate images. The display panel may be a light emitting display panel. For example, the display panel may be an organic light emitting display panel, an inorganic light emitting display panel, an organic-inorganic light emitting display panel, a quantum dot display panel, a micro LED display panel, and/or a nano LED display panel.

The display device DD may include a first region DA-1 and a second region DA-2, which are consecutively provided. For example, both (e.g., simultaneously) the first region DA-1 and the second region DA-2 may be implemented within a single display device DD. The second region DA-2 may be adjacent to the first region DA-1. The first region DA-1 and the second region DA-2 may be arranged consecutively along the second direction DR2. The first region DA-1 may be a region positioned close to a front passenger, and the second region DA-2 may be a region positioned close to a driver.

Each of the first region DA-1 and the second region DA-2 may display images in the third direction DR3 through a display surface parallel to the plane defined by the first direction DR1 and the second direction DR2. The display surface is described as being a plane, but may also be a curved surface. The first region DA-1 and the second region DA-2 may separately display images including respective information desired or required by the driver and the front passenger.

In one or more embodiments, the first region DA-1 may display images desired or required by the front passenger. For example, one or more suitable information including images unrelated to driving as well as information desired or required for driving may be displayed. The second region DA-2 may display images desired or required for driving to the driver at the wheel. For example, driving speed information, vehicle status information, vehicle internal operation information, and navigation information desired or required for driving may be displayed.

In one or more embodiments, each of the first region DA-1 and the second region DA-2 may be driven independently of each other. At least one of the first region DA-1 or the second region DA-2 may be switched to a first mode or a second mode. The first region DA-1 may display images in the first mode or the second mode, and the second region DA-2 may also display images in the first mode or the second mode. For example, the first mode may be a wide viewing angle mode, a normal mode, or a public mode, which displays images at a first viewing angle. The second mode may be a viewing angle control mode or a private mode, which displays images at a second viewing angle. Herein, the first viewing angle may be referred to as a ‘wide viewing angle’. The second viewing angle displays images at a narrower viewing angle than the first viewing angle, and may be referred to as a ‘narrow viewing angle’. The first viewing angle and the second viewing angle may be defined as angles at which images may be viewed without quality distortion with respect to the normal direction of the image display surface.

When each of the first region DA-1 and the second region DA-2 operates in the first mode, a viewing range of images may be increased. Accordingly, images displayed in the first region DA-1 may be viewed from the front and side directions of the first region DA-1, and images displayed in the second region DA-2 may be viewed from the front and side directions of the second region DA-2. When each of the first region DA-1 and the second region DA-2 operates in the second mode, a viewing range of images narrows, and thus the images may be viewed only in the front direction of each of the first region DA-1 and the second region DA-2.

For example, in a non-driving environment of the vehicle AM, both (e.g., simultaneously) the first region DA-1 and the second region DA-2 may operate in the first mode. In this case, the driver and the front passenger of the vehicle AM may view all images displayed in both (e.g., simultaneously) the first region DA-1 and the second region DA-2. Not limited thereto, the first region DA-1 may operate in the first mode, and the second region DA-2 may operate in the second mode. In this case, the front passenger may view images displayed in the first region DA-1, but may not view images displayed in the second region DA-2.

For example, in a driving environment of the vehicle AM, the first region DA-1 may operate in the second mode, and the second region DA-2 may operate in the first mode. In this case, the driver of the vehicle AM may view images displayed in the second region DA-2, but may not view images displayed in the first region DA-1. However, the front passenger of the vehicle AM may view all images displayed in both (e.g., simultaneously) the first region DA-1 and the second region DA-2.

FIG. 4 is a cross-sectional view of an electronic device ED according to one or more embodiments. Referring to FIG. 4, an electronic device ED may include a display panel DP and an input sensing layer ISL. The electronic device ED may further include an optical path control layer OSL.

The display panel DP may include a base layer BS, a circuit layer DP-CL, a display element layer DP-EL, and an encapsulation layer TFE. The base layer BS may be a member providing a base surface on which the circuit layer DP-CL is arranged. The base layer BS may be a glass substrate, a metal substrate, a silicon substrate, a polymer substrate, and/or the like. However, embodiments are not limited thereto, and the base layer BS may be an inorganic layer, an organic layer, or a composite material layer (e.g., a composite layer including an inorganic layer and an organic layer). The base layer BS may be of a flexible type (kind).

The circuit layer DP-CL may be arranged on the base layer BS. The circuit layer DP-CL may include an insulating layer (e.g., an electrically insulating layer), a semiconductor pattern, a conductive pattern (e.g., an electrically conductive pattern), a signal line, and/or the like. In the circuit layer DP-CL, an insulating layer, a semiconductor layer, and a conductive layer may be formed on the base layer BS through coating, deposition, and/or the like, and then the insulating layer, the semiconductor layer, and the conductive layer may be patterned (e.g., selectively patterned) through a plurality of photolithography processes. Thereafter, the semiconductor pattern, the conductive pattern, and the signal line included in the circuit layer DP-CL may be formed.

The display element layer DP-EL may be arranged on the circuit layer DP-CL. The display element layer DP-EL may include light emitting elements. For example, the display element layer DP-EL may include organic light emitting diodes, inorganic light emitting diodes, quantum dots, quantum rods, micro LEDs, and/or nano LEDs.

The encapsulation layer TFE may be arranged on the display element layer DP-EL. The encapsulation layer TFE may serve to protect the display element layer DP-EL from moisture, oxygen, and/or foreign substances, such as dust particles.

The input sensing layer ISL may be arranged on the encapsulation layer TFE. The input sensing layer ISL may detect external inputs applied from the outside. The external inputs may be user inputs. The user inputs may include one or more suitable types (kinds) of external inputs, such as a direct or indirect touch of the user, light, heat, pen, and/or pressure. The input sensing layer ISL may be referred to as a sensor or an input sensing panel. The input sensing layer ISL may be formed along with the display panel DP through a substantially continuous process and directly arranged on the encapsulation layer TFE. However, embodiments are not particularly limited thereto. For example, the input sensing layer ISL may be bonded to the display panel DP through an adhesive layer. The adhesive layer may include a typical adhesive or bonding agent.

The optical path control layer OSL may be arranged on the input sensing layer ISL. The optical path control layer OSL may be formed along with the display panel DP and the input sensing layer ISL through a substantially continuous process, and may be directly arranged on the input sensing layer ISL. However, embodiments are not limited thereto. For example, the optical path control layer OSL may be coupled to the input sensing layer ISL through an adhesive layer.

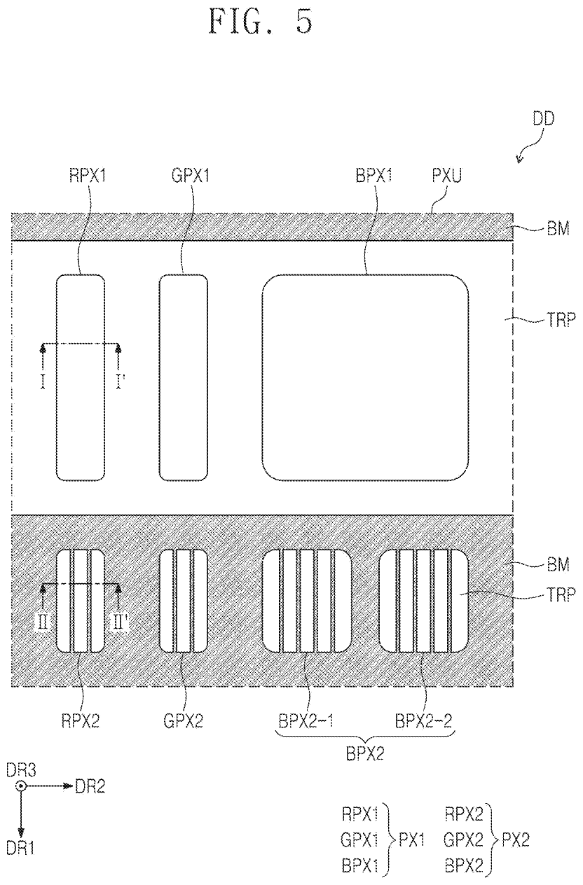

FIG. 5 is a plan view showing an enlarged partial region of a display device according to one or more embodiments.

Referring to FIG. 5, a display device DD may include a pixel unit PXU. The pixel unit PXU may be provided in plurality and repeatedly arranged along the first direction DR1 and the second direction DR2.

The pixel unit PXU may include a plurality of pixel groups PX1 and PX2. The pixel unit PXU may include a first pixel group PX1 and a second pixel group PX2. The first pixel group PX1 may include a plurality of first pixels RPX1, GPX1, and BPX1 that provide light of different wavelength ranges, and the second pixel group PX2 may include second pixels RPX2, GPX2, and BPX2 that provide light of different wavelength ranges. For example, the first pixel group PX1 may include a (1-1)-th pixel RPX1, a (1-2)-th pixel GPX1, and a (1-3)-th pixel BPX1. The second pixel group PX2 may include a (2-1)-th pixel RPX2, a (2-2)-th pixel GPX2, and a (2-3)-th pixel BPX2. The (2-3)-th pixel BPX2 may include a first sub-pixel BPX2-1 and a second sub-pixel BPX2-2.

The (1-1)-th pixel RPX1 and the (2-1)-th pixel RPX2 may provide first light, and the (1-2)-th pixel GPX1 and the (2-2)-th pixel GPX2 may provide second light different from the first light. The (1-3)-th pixel BPX1 and the (2-3)-th pixel BPX2 may provide third light different from the first light and the second light. In one or more embodiments, the first light may be a red color, the second light may be a green color, and the third light may be a blue color. The (1-1)-th pixel RPX1 and the (2-1)-th pixel RPX2 may be red pixels, the (1-2)-th pixel GPX1 and the (2-2)-th pixel GPX2 may be green pixels, and the (1-3)-th pixel BPX1 and the (2-3)-th pixel BPX2 may be blue pixels. Herein, the (1-1)-th pixel RPX1 may be referred to as a first red pixel, and the (2-1)-th pixel RPX2 may be referred to as a second red pixel. The (1-2)-th pixel GPX1 may be referred to as a first green pixel, and the (2-2)-th pixel GPX2 may be referred to as a second green pixel. The (1-3)-th pixel BPX1 may be referred to as a first blue pixel, and the (2-3)-th pixel BPX2 may be referred to as a second blue pixel. In addition, the first sub-pixel BPX2 may be referred to as a first sub-blue pixel, and the second sub-pixel BPX2-2 may be referred to as a second sub-blue pixel.

The first red pixel RPX1, the first green pixel GPX1, and the first blue pixel BPX1 may be spaced and/or apart (e.g., spaced apart or separated) in the second direction DR2 and may form the first pixel group PX1. The second red pixel RPX2, the second green pixel GPX2, and the second blue pixel BPX2 may be spaced and/or apart (e.g., spaced apart or separated) in the second direction DR2 and may form the second pixel group PX2. The first pixel group PX1 and the second pixel group PX2 may be arranged alternately along the first direction DR1.

On a plane, the first red pixel RPX1 and the second red pixel RPX2 may be spaced and/or apart (e.g., spaced apart or separated) in the first direction DR1. On a plane, the first green pixel GPX1 and the second green pixel GPX2 may be spaced and/or apart (e.g., spaced apart or separated) in the first direction DR1. On a plane, the first blue pixel BPX1 and the second blue pixel BPX2 may be spaced and/or apart (e.g., spaced apart or separated) in the first direction DR1.

The first pixels RPX1, GPX1, and BPX1 may have a first opening area. For example, the first red pixel RPX1 may have a first red opening area, and the first green pixel GPX1 may have a first green opening area. The first blue pixel BPX1 may have a first blue opening area. The first blue opening area may be larger than the first red opening area and the first green opening area. The first red opening area and the first green opening area may be substantially the same.

The second pixels RPX2, GPX2, and BPX2 may have a second opening area. The second opening area may be smaller than the first opening area. For example, the second red pixel RPX2 may have a second red opening area smaller than the first red opening area, and the second green pixel GPX2 may have a second green opening area smaller than the first green opening area. The second blue pixel BPX2 may have a second blue opening area smaller than the first blue opening area. The opening area of the first sub-blue pixel BPX2-1 and the opening area of the second sub-blue pixel BPX2-2 may be the same. The first sub-blue pixel BPX2-1 and the second sub-blue pixel BPX2-2 may have a second blue opening area smaller than the first blue opening area. Herein, the first red pixel RPX1, the first green pixel GPX1, and the first blue pixel BPX1 may be referred to as ‘wide pixels’, and the second red pixel RPX2, the second green pixel GPX2, and the second blue pixel BPX2 may be referred to as ‘narrow pixels’.

Each of the wide pixels RPX1, GPX1, and BPX1 and the narrow pixels RPX2, GPX2, and BPX2 may be driven or non-driven depending on the first mode or the second mode. For example, in the first mode, the wide pixels RPX1, GPX1, and BPX1 may be driven and the narrow pixels RPX2, GPX2, and BPX2 may be non-driven. For example, in the first mode, the pixel unit PXU may display images using the first red pixel RPX1, the first green pixel GPX1, and the first blue pixel BPX1. In the second mode, the wide pixels RPX1, GPX1, and BPX1 may be non-driven and only the narrow pixels RPX2, GPX2, and BPX2 may be driven. In the second mode, the pixel unit PXU may display images using the second red pixels RPX2, the second green pixel GPX2, and the second blue pixel BPX2.

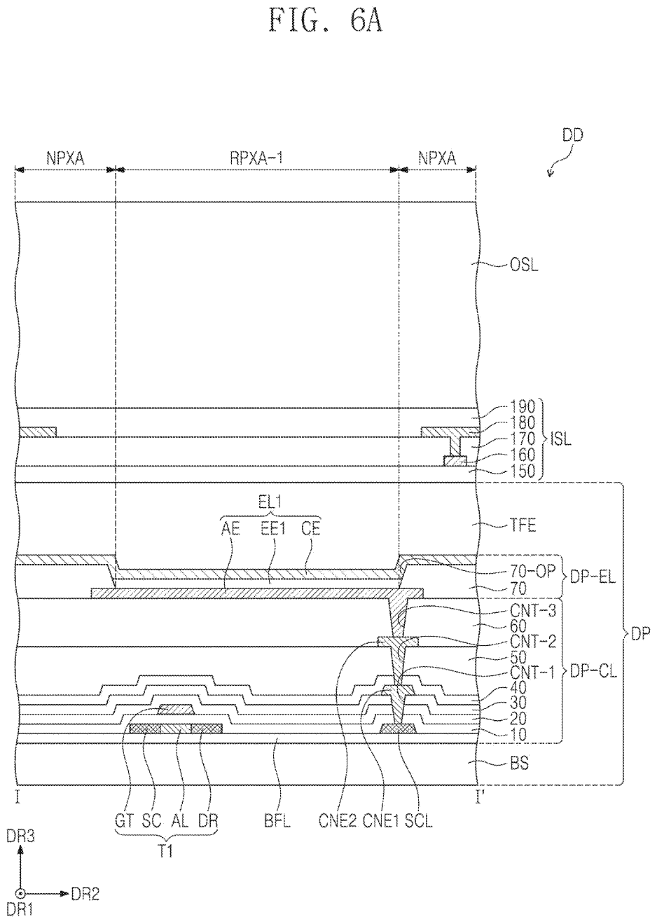

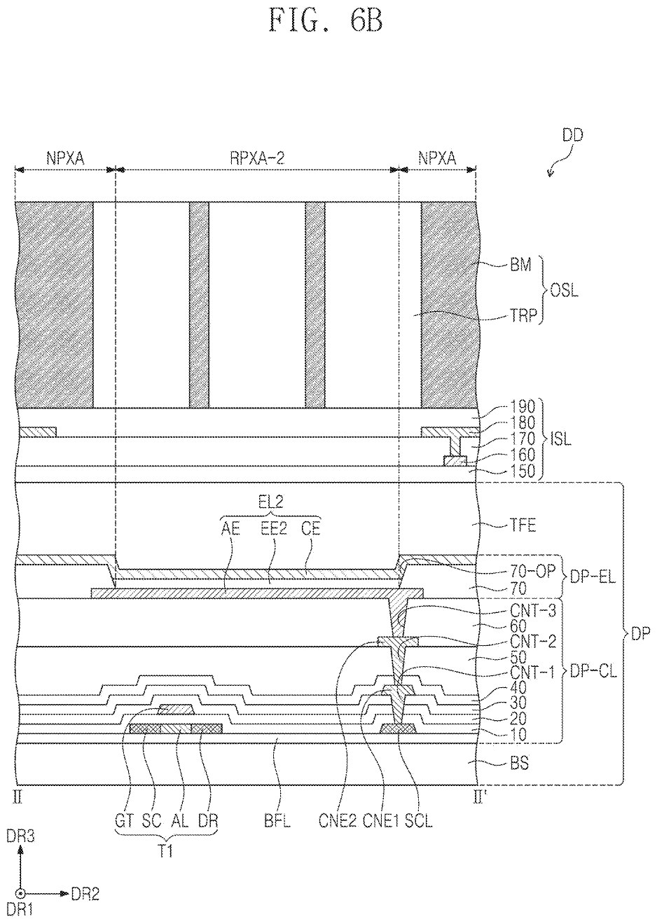

A black matrix BM may be arranged on an upper portion of the wide pixels RPX1, GPX1, and BPX1 and the narrow pixels RPX2, GPX2, and BPX2. A transmitting portion TRP may be defined in the black matrix BM. The black matrix BM and the transmitting portion TRP may be components included in the optical path control layer OSL shown in FIGS. 6A and 6B. On a plane, the wide pixels RPX1, GPX1, and BPX1 may not overlap the black matrix BM and may overlap the transmitting portion TRP. The narrow pixels RPX2, GPX2, and BPX2 may overlap at least a portion of the black matrix BM and the transmitting portion TRP. The transmitting portions TRP overlapping the narrow pixels RPX2, GPX2, and BPX2 may be provided in plurality. For example, a plurality of transmitting portions TRP may be defined in the black matrix BM overlapping the narrow pixels RPX2, GPX2, and BPX2. The plurality of transmitting portions TRP overlapping the narrow pixels RPX2, GPX2, and BPX2 may extend in the first direction DR1 and be spaced and/or apart (e.g., spaced apart or separated) in the second direction DR2. On the narrow pixels RPX2, GPX2, and BPX2, the black matrix BM may be located between the transmitting portions TRP which are spaced and/or apart (e.g., spaced apart or separated).

FIG. 5 shows a structure in which each of the second red pixel RPX2, the second green pixel GPX2, the first sub-blue pixel BPX2-1, and the second sub-blue pixel BPX2-1 overlaps three or five transmitting portions TRP by the black matrix BM arranged on the narrow pixels RPX2, GPX2, and BPX2, but the structure of each of the black matrix BM and the transmitting portions TRP is not limited thereto.

FIGS. 6A and 6B are each cross-sectional views showing a portion of a display device DD according to one or more embodiments. FIG. 6A is a cross-sectional view of a display device DD according to one or more embodiments, taken along I-I′ of FIG. 5. FIG. 6B is a cross-sectional view of a display device DD according to one or more embodiments, taken along II-II′ of FIG. 5. FIG. 6A shows a cross-sectional view of a display device DD corresponding to a first red pixel as a representative of a wide pixel, and FIG. 6B shows a cross-sectional view of a display device DD corresponding to a second red pixel as a representative of a narrow pixel. The description provided with reference to FIG. 6A may equally apply to the first green pixel and the first blue pixel. In addition, the description with reference to FIG. 6B may equally apply to the second green pixel and the second blue pixel.

Referring to FIGS. 6A and 6B, a display device DD according to one or more embodiments may include a base layer BS, a circuit layer DP-CL, a display element layer DP-EL, an input sensing layer ISL, and an optical path control layer OSL.

The base layer BS may be a member providing a base surface on which the circuit layer DP-CL is arranged. The base layer BS may include a synthetic resin layer. The synthetic resin layer may be a polyimide-based resin layer, but the material thereof is not particularly limited. For example, the base layer BS may include a glass substrate, a metal substrate, or an organic/inorganic composite material substrate (e.g., a composite layer including an inorganic layer and an organic layer).

At least one inorganic layer is formed on an upper surface of the base layer BS. The inorganic layer may include an aluminum oxide, titanium oxide, a silicon oxide, a silicon nitride, a silicon oxynitride, a zirconium oxide, and/or a hafnium oxide. The inorganic layer may be formed as a multi-layer. Inorganic layers of the multi-layer may form a barrier layer and/or a buffer layer. In one or more embodiments, the display panel DP is shown to include a buffer layer BFL.

The buffer layer BFL may improve a bonding force between the base layer BS and a semiconductor pattern. The buffer layer BFL may include a silicon oxide, a silicon nitride, and/or a silicon oxynitride. For example, the buffer layer BFL may include a structure in which silicon oxide layers and silicon nitride layers are alternately stacked.

The semiconductor pattern may be arranged on the buffer layer BFL. The semiconductor pattern may include polysilicon. However, embodiments of the disclosure are not limited thereto, and the semiconductor pattern may include amorphous silicon, low-temperature polycrystalline silicon, or oxide semiconductor.

FIGS. 6A and 6B only shows a partial semiconductor pattern, and a semiconductor pattern may be further arranged in another region. The semiconductor patterns may be arranged over pixels according to a particular rule. The semiconductor patterns may have different electric properties according to with/without doping. The semiconductor patterns may include a first region having high conductivity and a second region having low conductivity. The first region may be doped with an N-type (kind) dopant or a P-type (kind) dopant. A P-type (kind) transistor may include a doped region doped with a P-type (kind) dopant, and an N-type (kind) transistor may include a doped region doped with an N-type (kind) dopant. The second region may be an undoped region or a region doped at a lower concentration than that of the first region.

The first region has greater conductivity than the second region, and may substantially serve as an electrode or a signal line. The second region may substantially correspond to an active region (or a channel) of a transistor. For example, a portion of the semiconductor pattern may be an active region of a transistor, another portion may be a source or drain region of the transistor, and the other portion may be a connection electrode or a connection signal line.

In FIG. 6A, one transistor T1 and a light emitting element EL1 included in a pixel are shown as an example. In FIG. 6B, one transistor T1 and one light emitting element EL2 included in a pixel are shown as an example.

A source region SC, an active region AL (or active, active region), and a drain region DR of the transistor T1 may be formed from a semiconductor pattern. The source region SC and the drain region DR may extend in opposite directions from the active region AL in a cross-sectional view. FIGS. 6A and 6B shows a portion of a connection signal line SCL formed from the semiconductor pattern. The connection signal line SCL may be connected to the drain region DR of the transistor T1 in a plan view.

A first insulating layer 10 may be arranged on the buffer layer BFL. The first insulating layer 10 may commonly overlap a plurality of pixels, and may cover the semiconductor pattern. The first insulating layer 10 may be an inorganic layer and/or organic layer, and may have a single-layer or multi-layer structure. The first insulating layer 10 may include a aluminum oxide, titanium oxide, a silicon oxide, a silicon nitride, a silicon oxynitride, a zirconium oxide, and/or a hafnium oxide. In one or more embodiments, the first insulating layer 10 may be a single layer of a silicon oxide layer. The first insulating layer 10 as well as the insulating layer of the circuit layer 120 are described in more detail may be an inorganic layer and/or an organic layer, and may have a single-layer or multi-layer structure. The inorganic layer may include at least one of the materials described above, but the present disclosure is not limited thereto.

A gate electrode GT of the transistor T1 is arranged on the first insulating layer 10. The gate electrode GT may be a portion of a metal pattern. The gate electrode GT overlaps the active region AL. The gate electrode GT may function as a mask during a process of doping a semiconductor pattern.

A second insulating layer 20 may be arranged on the first insulating layer 10, and may cover the gate electrode GT. The second insulating layer 20 may commonly overlap pixels. The second insulating layer 20 may be an inorganic layer and/or organic layer, and may have a single-layer or multi-layer structure. The second insulating layer 20 may include a silicon oxide, a silicon nitride, and/or a silicon oxynitride. In one or more embodiments, the second insulating layer 20 may have a multi-layer structure including a silicon oxide layer and a silicon nitride layer.

A third insulating layer 30 may be arranged on the second insulating layer 20. The third insulating layer 30 may have a single-layer or multi-layer structure. For example, the third insulating layer 30 may have a multi-layer structure including a silicon oxide layer and a silicon nitride layer.

A first connection electrode CNE1 may be arranged on the third insulating layer 30. The first connection electrode CNE1 may be connected to the connection signal line SCL through a contact hole CNT-1 passing through the first, second, and third insulating layers 10, 20, and 30.

A fourth insulating layer 40 may be arranged on the third insulating layer 30. The fourth insulating layer 40 may be a single layer of a silicon oxide layer. A fifth insulating layer 50 may be arranged on the fourth insulating layer 40. The fifth insulating layer 50 may be an organic layer.

A second connection electrode CNE2 may be arranged on the fifth insulating layer 50. The second connection electrode CNE2 may be connected to the first connection electrode CNE1 through a contact hole CNT-2 passing through the fourth insulating layer 40 and the fifth insulating layer 50.

A sixth insulating layer 60 may be arranged on the fifth insulating layer 50, and may cover the second connection electrode CNE2. The sixth insulating layer 60 may be an organic layer.

The stacking relationship of the circuit layer DP-CL shown in FIGS. 6A and 6B is only an example and embodiments are not particularly limited thereto. For example, at least one of the first to sixth insulating layers 10, 20, 30, 40, 50, and 60 may not be provided, and other insulating layers may be further added.

The display element layer DP-EL may be arranged on the circuit layer DP-CL. The display element layer DP-EL may include light emitting elements EL1 and EL2 arranged corresponding to each of the first red pixel RPX1 (FIG. 5) and the second red pixel RPX2 (FIG. 5). For example, the display element layer DP-EL may include organic light emitting materials, inorganic light emitting materials, organic-inorganic light emitting materials, quantum dots, quantum rods, micro LEDs, and/or nano LEDs. Hereinafter, the light emitting elements EL1 and EL2 will be described as an organic light emitting element as an example, but are not particularly limited thereto.

The light emitting elements EL1 and EL2 may include an anode AE (referred to as a first electrode), organic layers EE1 and EE2, and a cathode CE (referred to as a second electrode). For example, the light emitting element EL1 may include a first electrode AE, first organic layers EE1, and a second electrode CE. The second light emitting element EL2 may include a first electrode AE, second organic layers EE2, and a second electrode CE.

The first electrode AE may be arranged on the sixth insulating layer 60. The first electrode AE may be connected to the second connection electrode CNE2 through a contact hole CNT-3 passing through the sixth insulating layer 60.

A pixel defining film 70 may be arranged on the sixth insulating layer 60, and may cover a portion of the first electrode AE. An opening 70-OP is defined in the pixel defining film 70. The opening portion 70-OP of the pixel defining film 70 exposes at least a portion of the first electrode AE. As used herein and unless stated otherwise, a pixel “opening area” is the area of the aperture defined by the pixel defining film opening (e.g., opening 70-OP) through which the emissive stack is exposed within a pixel region, as viewed on a plane (DR1-DR2), e.g., in plan view. The first region DA-1 (FIG. 3) and the second region DA-2 (FIG. 3) of the display device DD may include light emitting regions RPXA-1 and RPXA-2 and a non-light emitting region NPXA adjacent to the light emitting regions RPXA-1 and RPXA-2. The light emitting regions RPXA-1 and RPXA-2 may be regions emitting light generated from the light emitting elements EL1 and EL2. The non-light emitting region NPXA may be around (e.g., surround) the light emitting regions RPXA-1 and RPXA-2. In one or more embodiments, the light emitting regions RPXA-1 and RPXA-2 may be defined by the opening portion 70-OP.

The organic layers EE1 and EE2 may be arranged on the first electrode AE. The organic layers EE1 and EE2 may include a hole transport region, an emission layer, and an electron transport region. The hole transport region may include a hole injection layer, and may further include a hole transport layer, an emission auxiliary layer, and an electron blocking layer. The electron transport region may include an electron injection layer, an electron transport layer, and a hole blocking layer. In FIGS. 6A and 6B, the organic layers EE1 and EE2 are shown to be arranged in a region corresponding to the opening portion 70-OP, but at least a portion of the organic layers EE1 and EE2 may be commonly provided to a plurality of pixels. For example, at least a portion of the hole transport region, the emission layer, and the electron transport region may be commonly arranged in the light emitting regions RPXA-1 and RPXA-2 and the non-light emitting region NPXA. For example, the hole transport region and the electron transport region included in the first light emitting element EL1 may be commonly arranged in the first red light emitting region RPXA-1 and the non-light emitting region NPXA, and the emission layer included in the first light emitting element EL1 may be provided as a pattern layer corresponding to the first red light emitting region RPXA-1. The hole transport region and the electron transport region included in the second light emitting element EL2 may be commonly arranged in the second red light emitting region RPXA-2 and the non-light emitting region NPXA, and the emission layer included in the second light emitting element EL2 may be provided as a pattern layer corresponding to the second red light emitting region RPXA-2. The first red light emitting region RPXA-1 may correspond to the first red pixel RPX1 (FIG. 5), and the second red light emitting region RPXA-2 may correspond to the second red pixel RPX2 (FIG. 5). Herein, the wording “region/portion corresponds to another region/portion” represents “overlapping each other” on a plane, but is not limited to cases in which the regions/portions have the same area size.

The second electrode CE may be arranged on the organic layers EE1 and EE2. The second electrode CE may have a shape of a single body, and may be arranged commonly in a plurality of pixels.

The encapsulation layer TFE may be arranged on the display element layer DP-EL. The encapsulation layer TFE may include an inorganic layer, an organic layer, and an inorganic layer which are sequentially stacked, but the layers forming the encapsulation layer TFE are not limited thereto.

The inorganic layers may protect the display element layer DP-EL from moisture and oxygen, and the organic layer may protect the display element layer DP-EL from foreign substances, such as dust particles. The inorganic layers may include a silicon nitride layer, a silicon oxy nitride layer, a silicon oxide layer, a titanium oxide layer, an aluminum oxide layer, and/or the like. The organic layer may include an acryl-based organic layer, but the present disclosure is not limited thereto.

The input sensing layer ISL may include a sensor base layer 150, a first conductive layer 160, a sensing insulating layer 170, a second conductive layer 180, and a cover insulating layer 190.

The sensor base layer 150 may be an inorganic layer including a silicon nitride, a silicon oxynitride, or a silicon oxide. In one or more embodiments, the sensor base layer 150 may be an organic layer including an epoxy resin, an acrylic resin, or an imide-based resin. The sensor base layer 150 may have a single-layer structure or may have a multi-layer structure stacked along the third direction DR3. According to one or more embodiments, the sensor base layer 150 may not be provided.

Each of the first conductive layer 160 and the second conductive layer 180 may have a single-layer structure, or may have a multi-layer structure stacked along the third direction DR3.

A conductive layer having a single-layer structure may include a metal layer or a transparent conductive layer. The metal layer may include molybdenum, silver, titanium, copper, aluminum, or an alloy thereof. The transparent conductive layer may include a transparent conductive oxide, such as an indium tin oxide (ITO), an indium zinc oxide (IZO), a zinc oxide (ZnO), indium zinc tin oxide (IZTO), and/or the like. In addition, the transparent conductive layer may include a conductive polymer such as PEDOT, metal nanowire, graphene, and/or the like.

A conductive layer having a multi-layer structure may include metal layers. The metal layers may have, for example, a triple-layer structure of titanium/aluminum/titanium. The conductive layer having a multi-layer structure may include at least one metal layer and at least one transparent conductive layer.

At least any one of the sensing insulating layer 170 or the cover insulating layer 190 may include an inorganic film. The inorganic film may include an aluminum oxide, a titanium oxide, a silicon oxide, a silicon oxynitride, a zirconium oxide, or a hafnium oxide.

At least any one of the sensing insulating layer 170 or the cover insulating layer 190 may include an organic film. The organic film may include acrylic resin, methacrylic resin, polyisoprene, vinyl-based resin, epoxy-based resin, urethane-based resin, cellulosic resin, siloxane-based resin, polyimide-based resin, polyamide-based resin, perylene-based resin, and/or the like.

The optical path control layer OSL may be arranged on the input sensing layer ISL. For example, the optical path control layer OSL may be arranged on the cover insulating layer 190. The optical path control layer OSL may include a black matrix BM and transmitting portions TRP. In one or more embodiments, a portion of the optical path control layer OSL in which the black matrix BM is not arranged may correspond to the transmitting portions TRP. The first light emitting element EL1 shown in FIG. 6A is arranged corresponding to the first red pixel RPX1 (FIG. 5) included in the first pixel group PX1 (FIG. 5), and may not overlap the black matrix BM (FIG. 6B) and may overlap the transmitting portions TRP.

The second light emitting element EL2 shown in FIG. 6B is arranged corresponding to the second red pixel RPX2 included in the second pixel group PX2, and the black matrix BM may be arranged on an upper portion of the second light emitting element EL2. The black matrix BM may be spaced apart with the transmitting portion TRP therebetween in a region overlapping the second red light emitting region RPXA-2. The emission range of light output from the second light emitting element EL2 may be controlled or selected by the black matrix BM. For example, side light from the light output from the second light emitting element EL2 is absorbed by the black matrix BM and is not output to the outside. The emission range of the light output from the second light emitting element EL2 may be narrowed by the black matrix BM, and accordingly, a viewing angle of images displayed in the second mode may be narrower than a viewing angle of images displayed in the first mode. Therefore, if (e.g., when) the first region DA-1 (FIG. 3) operates in the second mode, the driver may not view images displayed in the first region DA-1, and if (e.g., when) the second region DA-2 (FIG. 3) operates in the second mode, the front passenger may not view images displayed in the second region DA-2.

The black matrix BM may include a light-absorbing material or a light-blocking material. For example, light incident on the black matrix BM may not be reflected but may be absorbed by the black matrix BM. The transmitting portion TRP may include a transparent organic material.

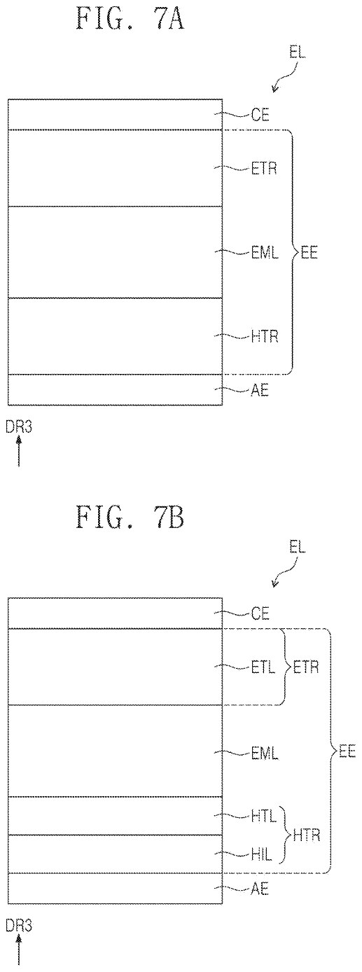

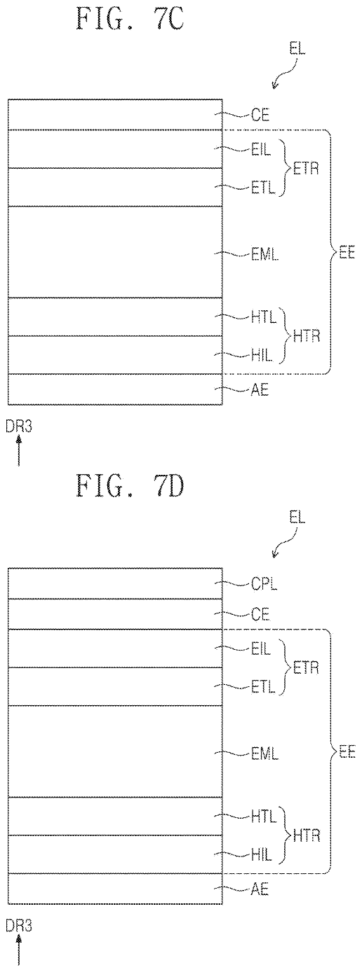

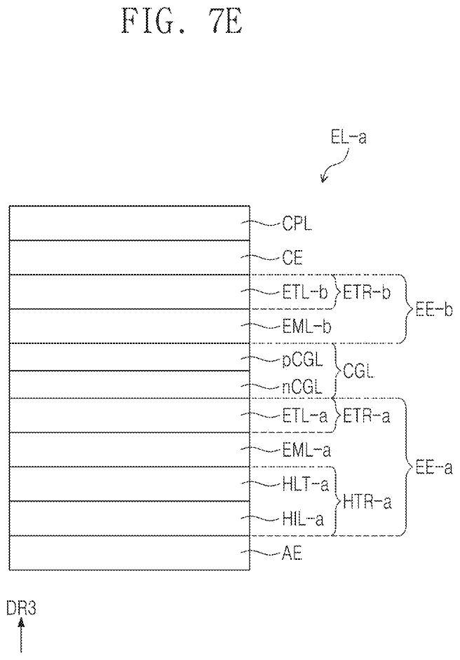

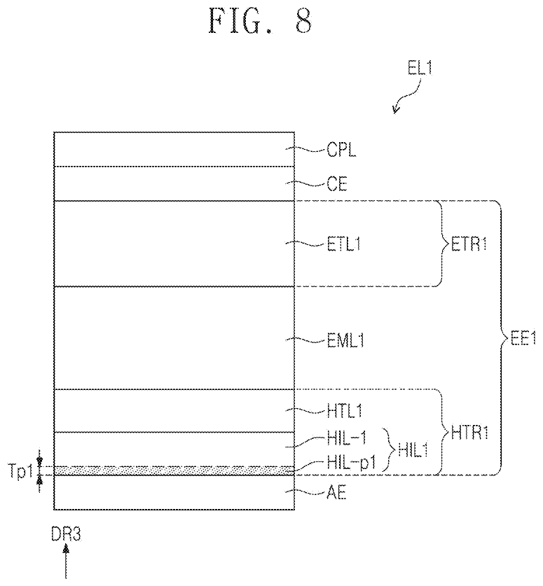

FIGS. 7A to 7E are each cross-sectional views schematically showing a light emitting element according to one or more embodiments. The light emitting element described with reference to FIGS. 7A to 7E may apply to both (e.g., simultaneously) a light emitting element corresponding to a wide pixel and a light emitting element corresponding to a narrow pixel. For example, a structure of light emitting elements EL and EL-a of FIGS. 7A to 7E may apply to the first light emitting element EL1 shown in FIG. 6A and the second light emitting element EL2 shown in FIG. 6B. For FIGS. 7A to 7E, the same/similar reference signs are used for the same/similar components described in FIGS. 6A and 6B, and overlapping descriptions will not be provided.

Referring to FIG. 7A, the light emitting element EL may include a first electrode AE, organic layers EE, and a second electrode CE. The organic layers EE may include a hole transport region HTR, an emission layer EML, and an electron transport region ETR. The light emitting element EL according to one or more embodiments may include a first electrode AE, a hole transport region HTR, an emission layer EML, an electron transport region ETR, and a second electrode CE, which are sequentially stacked.

FIG. 7B shows, compared with FIG. 7A, a cross-sectional view of a light emitting element EL according to one or more embodiments in which the hole transport region HTR includes a hole injection layer HIL and a hole transport layer HTL, and the electron transport region ETR includes an electron transport layer ETL. FIG. 7C shows, compared with FIG. 7A, a cross-sectional view of a light emitting element EL according to one or more embodiments in which the hole transport region HTR includes a hole injection layer HIL and a hole transport layer HTL, and the electron transport region ETR includes an electron injection layer EIL and an electron transport layer ETL. FIG. 7D shows, compared with FIG. 7C, a cross-sectional view of a light emitting element EL according to one or more embodiments, which includes a capping layer CPL arranged on the second electrode CE.

FIG. 7E shows, compared with FIG. 7A, a cross-sectional view of a light emitting element EL-a according to one or more embodiments, which includes lower organic layers EE-a, a charge generation layer CGL, and upper organic layers EE-b sequentially stacked between the first electrode AE and the second electrode CE, and further includes a capping layer CPL arranged on the second electrode CE. In the light emitting element EL-a according to one or more embodiments shown in FIG. 7E, the lower organic layers EE-a include a hole transport region HTR-a, an emission layer EML-a, and an electron transport region ETR-a, and the upper organic layers EE-b include an emission layer EML-b and an electron transport region ETR-b. The hole transport region HTR-a includes a hole injection layer HIL-a and a hole transport layer HTL-a, and the electron transport regions ETR-a and ETR-b include an electron transport layers ETL-a and ETL-b.

The hole transport regions HTR and HTR-a are provided on the first electrode AE. The hole transport regions HTR and HTR-a may include a hole injection layers HIL and HIL-a, and may further include at least one of hole transport layers HTL and HTL-a, an electron blocking layer, a buffer layer, or an emission auxiliary layer. The hole transport regions HTR and HTR-a may have a single layer formed of a plurality of different materials, or a multi-layer structure having a plurality of layers formed of a plurality of different materials. For example, the hole transport regions HTR and HTR-a may have a single-layer structure of hole injection layers HIL and HIL-a formed of a hole injection material and a charge generation material, or may have a single-layer structure formed of a hole injection material, a hole transport material, and a charge generation material. In addition, the hole transport regions HTR and HTR-a may have a structure of hole injection layers HIL and HIL-a/hole transport layers HTL and HTL-a, hole injection layers HIL and HIL-a/hole transport layers HTL and HTL-a/buffer layer, a hole injection layers HIL and HIL-a/buffer layer, or hole injection layers HIL and HTL-a/hole transport layers HTL and HTL-a/electron blocking layer sequentially stacked from the first electrode AE, but embodiments are not limited thereto.

The hole transport regions HTR and HTR-a may have a thickness of about 100 Å to about 10000 Å, for example, about 100 Å to about 5000 Å. When the hole transport regions HTR and HTR-a include the hole injection layers HIL and HIL-a, the hole injection layers HIL and HIL-a may have a thickness of, for example, about 30 Å to about 1500 Å. When the hole transport regions HTR and HTR-a include the hole transport layers HTL and HTL-a, the hole transport layers HTL and HTL-a may have a thickness in a range of about 30 Å to about 1000 Å. For example, if (e.g., when) the hole transport regions HTR and HTR-a include the electron blocking layer, the electron blocking layer may have a thickness in a range of about 10 Å to about 1000 Å. When the thicknesses of the hole transport regions HTR and HTR-a, the hole injection layers HIL and HIL-a, the hole transport layers HTL and HTL-a, and the electron blocking layer satisfy the above-described ranges, satisfactory hole transport properties may be obtained without a substantial increase in driving voltage.

The hole transport regions HTR and HTR-a may be formed using one or more suitable methods such as a vacuum deposition method, a spin coating method, a cast method, a Langmuir-Blodgett (LB) method, an inkjet printing method, a laser printing method, and a laser induced thermal imaging (LITI) method.

The hole transport regions HTR and HTR-a may include a compound represented by Formula H-1. The compound represented by Formula H-1 may be used as a hole injection material and/or a hole transport material, but the present disclosure is not limited thereto.

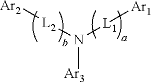

In Formula H-1 above, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. a and b may each independently be an integer of 0 to 10. In one or more embodiments, if (e.g., when) a or b is an integer of 2 or greater, f multiple L₁ in plurality and/or L₂ may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In one or more embodiments, in Formula H-1, Ar₃ may be a substituted or unsubstituted aryl group having 6 to 30 ring-forming carbon atoms, or a substituted or unsubstituted heteroaryl group having 2 to 30 ring-forming carbon atoms.

In one or more embodiments, the compound represented by Formula H-1 may be a monoamine compound. In one or more embodiments, the compound represented by Formula H-1 above may be a diamine compound in which at least one of Ar₁ to Ar₃ includes an amine group as a substituent. In one or more embodiments, the compound represented by Formula H-1 above may be a carbazole-based compound including a substituted or unsubstituted carbazole group in at least one of Ar₁ or Ar₂ or a substituted or unsubstituted fluorene-based group including a substituted or unsubstituted fluorene group in at least one of Ar₁ or Ar₂.

In one or more embodiments, herein, the term “substituted or unsubstituted” may indicate that one is substituted or unsubstituted with at least one substituent selected from the group consisting of deuterium, a halogen, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In one or more embodiments, each of the substituents presented as an example above may be substituted or unsubstituted. For example, a biphenyl group may be interpreted as an aryl group or as a phenyl group substituted with a phenyl group.

Herein, the term “bonded to an adjacent group to form a ring” may refer to forming a substituted or unsubstituted hydrocarbon ring, or a substituted or unsubstituted heterocycle by adjacent groups being bonded to each other. The hydrocarbon ring may include an aliphatic hydrocarbon ring and/or an aromatic hydrocarbon ring. The heterocycle may include an aliphatic heterocycle and/or an aromatic heterocycle. The hydrocarbon ring and the heterocycle may each be monocyclic ring or polycyclic ring. In one or more embodiments, the ring formed by adjacent groups being bonded to each other may be linked to another ring to form a spiro structure.

Herein, the term “adjacent group” may refer to a substituent substituted for an atom which is directly linked to an atom substituted with a corresponding substituent, another substituent substituted for an atom which is substituted with a corresponding substituent, or a substituent sterically closest to a corresponding substituent. For example, two methyl groups in 1,2-dimethylbenzene may be interpreted as mutually “adjacent groups” to each other and two ethyl groups in 1,1-diethylcyclopentane may be interpreted as mutually “adjacent groups” to each other. In addition, two methyl groups in 4,5-dimethylphenanthrene may be interpreted as mutually “adjacent groups” to each other.

Herein, examples of a halogen may include fluorine, chlorine, bromine, or iodine.

Herein, an alkyl group may be linear or branched. The number of carbon atoms in the alkyl group is 1 to 50, 1 to 30, 1 to 20, 1 to 10, or 1 to 6. Examples of the alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, 3-methylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-icosyl group, a 2-ethylicosyl group, a 2-butylicosyl group, a 2-hexylicosyl group, a 2-octylicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, and/or the like, but the embodiments of the present disclosure are not limited thereto.

Herein, a cycloalkyl group may refer to a cyclic alkyl group. The number of carbon atoms in the cycloalkyl group is 3 to 50, 3 to 30, 3 to 20, or 3 to 10. Examples of the cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, and/or the like, but the embodiments of the present disclosure are not limited thereto.

Herein, an alkenyl group refers to a hydrocarbon group including one or more carbon-carbon double bonds in the middle or end of an alkyl group having 2 or more carbon atoms. The alkenyl group may be linear or branched. The number of carbon atoms in the alkenyl group is not particularly limited, but may be 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, and/or the like, but the embodiments of the present disclosure are not limited thereto.

Herein, an alkynyl group refers to a hydrocarbon group including one or more carbon-carbon triple bonds in the middle or end of an alkyl group having 2 or more carbon atoms. The alkynyl group may be linear or branched. The number of carbon atoms in the alkynyl group is not particularly limited, but is 2 to 30, 2 to 20, or 2 to 10. Examples of the alkynyl group may include an ethynyl group, a propynyl group, and/or the like, but the embodiments of the present disclosure are not limited thereto.

Herein, a hydrocarbon ring group refers to any functional group or substituent derived from an aliphatic hydrocarbon ring. The hydrocarbon ring group may be a saturated hydrocarbon ring group having 5 to 20 ring-forming carbon atoms.

Herein, an aryl group refers to any functional group or substituent derived from an aromatic hydrocarbon ring. The aryl group may be a monocyclic aryl group or a polycyclic aryl group. The number of ring-forming carbon atoms in the aryl group may be 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, and/or the like, but the embodiments of the present disclosure are not limited thereto.

Herein, a fluorenyl group may be substituted, and two substituents may be bonded to each other to form a spiro structure. An example that the substituted fluorenyl group is as follows. However, embodiments are not limited thereto.

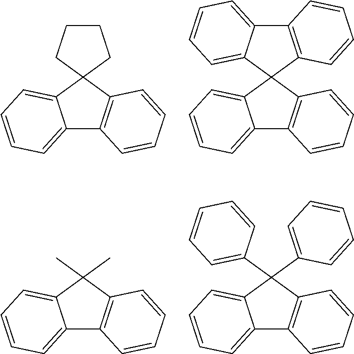

Herein, a heterocyclic group refers to any functional group or substituent derived from a ring containing at least one selected from among B, O, N, P, Si, or S as a hetero atom. The heterocyclic group may include an aliphatic heterocyclic group and/or an aromatic heterocyclic group. The aromatic heterocyclic group may be a heteroaryl group. The aliphatic heterocycle and the aromatic heterocycle may each be a monocyclic ring or polycyclic ring.

Herein, the heterocyclic group may contain at least one selected from among B, O, N, P, Si, or S as a hetero atom. If (e.g., when) the heterocyclic group contains two or more hetero atoms, the two or more hetero atoms may be the same as or different from each other. The heterocyclic group may be a monocyclic heterocyclic group or a polycyclic heterocyclic group, and include a heteroaryl group. The number of ring-forming carbon atoms in the heterocyclic group may be 2 to 30, 2 to 20, or 2 to 10.

Herein, the aliphatic heterocyclic group may contain at least one selected from among B, O, N, P, Si, or S as a hetero atom. The number of ring-forming carbon atoms in the aliphatic heterocyclic group may be 2 to 30, 2 to 20, or 2 to 10. Examples of the aliphatic heterocyclic group include an oxirane group, a thiirane group, a pyrrolidine group, a piperidine group, a tetrahydrofuran group, a tetrahydrothiophene group, a thiane group, a tetrahydropyran group, a 1,4-dioxane group, and/or the like, but the embodiments of the present disclosure are not limited to thereto.

Herein, a heteroaryl group may contain at least one selected from among B, O, N, P, Si, or S as a hetero atom. If (e.g., when) the heteroaryl group contains two or more hetero atoms, the two or more hetero atoms may be the same as or different from each other. The heteroaryl group may be a monocyclic heteroaryl group or a polycyclic heteroaryl group. The number of ring-forming carbon atoms in the heteroaryl group may be 2 to 30, 2 to 20, or 2 to 10. Examples of the heteroaryl group include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, and/or the like, but the embodiments of the present disclosure are not limited thereto.

Herein, the aryl group described above may also apply to an arylene group, except that the arylene group is a divalent group. The above description of the heteroaryl group may also apply to a heteroarylene group, except that the heteroarylene group is a divalent group.

Herein, a silyl group may include an alkyl silyl group and an aryl silyl group. Examples of the silyl group include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, and/or the like, but the embodiments of the present disclosure are not limited thereto.

Herein, the number of carbon atoms in a carbonyl group is not particularly limited, but may be 1 to 40, 1 to 30, or 1 to 20. For example, the carbonyl group may have the following structure, but the present disclosure is not limited thereto.

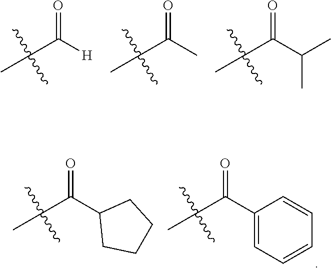

Herein, the number of carbon atoms in a sulfinyl group and a sulfonyl group is not particularly limited, but may be 1 to 30. The sulfinyl group may include an alkyl sulfinyl group and/or an aryl sulfinyl group. The sulfonyl group may include an alkyl sulfonyl group and/or an aryl sulfonyl group.

Herein, a thio group may include an alkyl thio group and an aryl thio group. The thio group may refer to the alkyl group or the aryl group as defined above bonded to a sulfur atom. Examples of the thio group include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, and/or the like, but the embodiments of the present disclosure are not limited to thereto.

Herein, an oxy group may refer to the alkyl group or the aryl group as defined above bonded to an oxygen atom. The oxy group may include an alkoxy group and/or an aryl oxy group. The alkoxy group may be linear, branched, or cyclic. The number of carbon atoms in the alkoxy group is not particularly limited, but may be, for example, 1 to 20, or 1 to 10. Examples of the oxy group include methoxy, ethoxy, n-propoxy, isopropoxy, butoxy, pentyloxy, hexyloxy, octyloxy, nonyloxy, decyloxy, benzyloxy, and/or the like, but the embodiments of the present disclosure are not limited thereto.

Herein, a boron group may refer to the alkyl group or the aryl group as defined above bonded to a boron atom. The boron group may include an alkyl boron group and/or an aryl boron group. Examples of the boron group include a dimethyl boron group, a diethyl boron group, a t-butylmethyl boron group, a diphenyl boron group, a phenyl boron group, and/or the like, but the embodiments of the present disclosure are not limited thereto.

Herein, the number of carbon atoms in an amine group is not particularly limited, but may be 1 to 30. The amine group may include an alkyl amine group and/or an aryl amine group. Examples of the amine group include a methylamine group, a dimethylamine group, a phenylamine group, a diphenylamine group, a naphthylamine group, a 9-methyl-anthracenylamine group, and/or the like, but the embodiments of the present disclosure are not limited thereto.

Herein, the above-described examples of the alkyl group also apply to an alkylthio group, an alkyl sulfoxy group, an alkylaryl group, an alkylamino group, an alkyl boron group, an alkyl silyl group, and an alkyl amine group.

Herein, the above-described examples of the aryl group may also apply to an aryloxy group, an arylthio group, an aryl sulfoxy group, an arylamino group, an aryl boron group, an aryl silyl group, and an aryl amine group.

Herein, a direct linkage may refer to a single bond.

Herein,

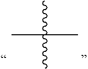

and “-*” each refers to a position to be connected.

In one or more embodiments, the compound represented by Formula H-1 may be represented by any one of the compounds from Compound Group H. However, the compounds listed in Compound Group H are presented as an example, and the compound represented by Formula H-1 is not limited to the those listed in Compound Group H.

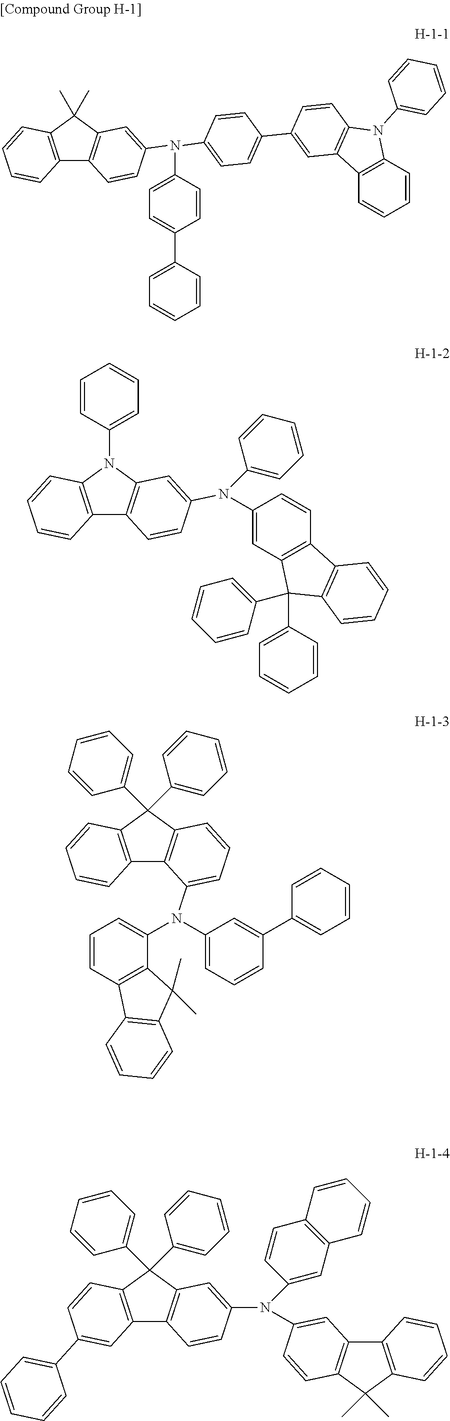 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2cccc(N(c3cccc(-c4ccccc4)c3)c3cccc4c3-c3ccccc3C4(c3ccccc3)c3ccccc3)c21 ; CC1(C)c2ccccc2-c2cc(N(c3ccc4c(c3)C(c3ccccc3)(c3ccccc3)c3ccc(-c5ccccc5)cc3-4)c3ccc4ccccc4c3)ccc21]

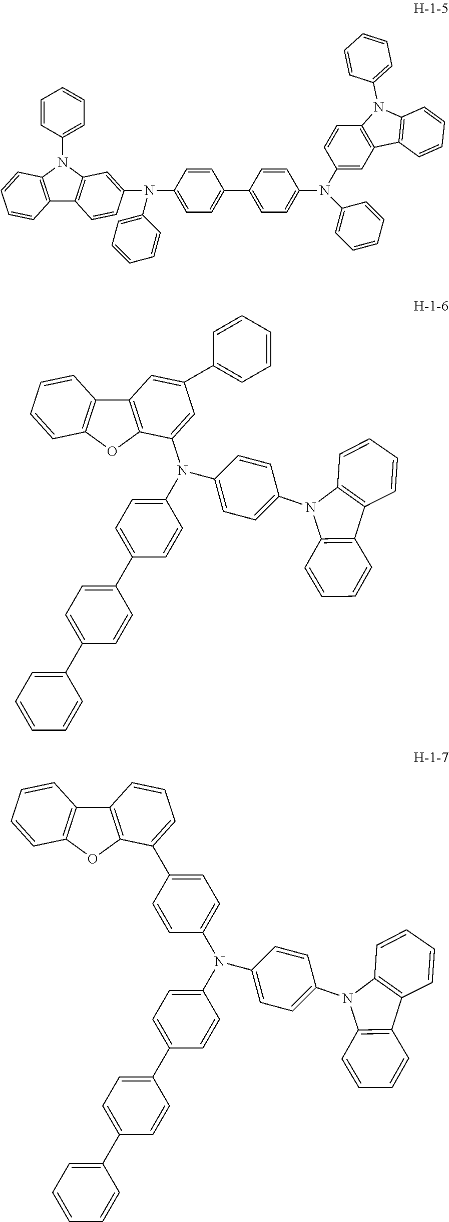 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

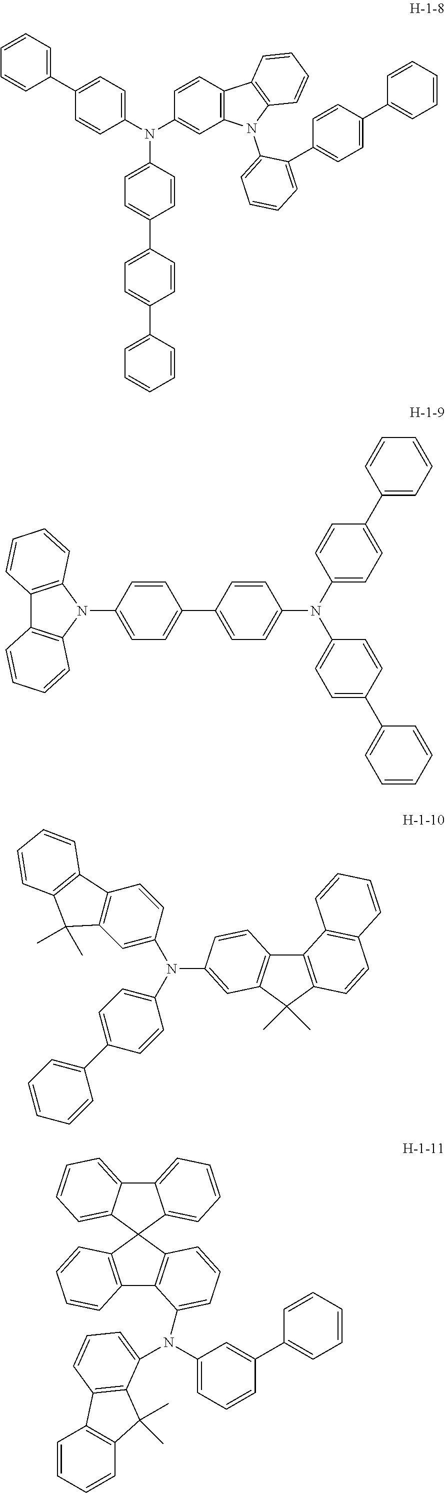

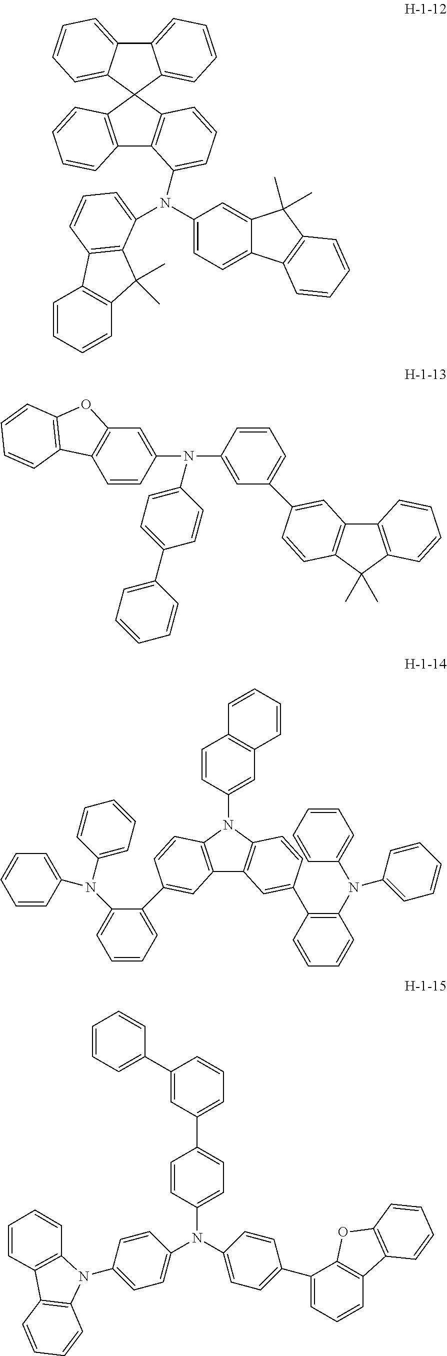 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1 ; c1ccc(-c2cccc(-c3ccc(N(c4ccc(-c5cccc6c5oc5ccccc56)cc4)c4ccc(-n5c6ccccc6c6ccccc65)cc4)cc3)c2)cc1]

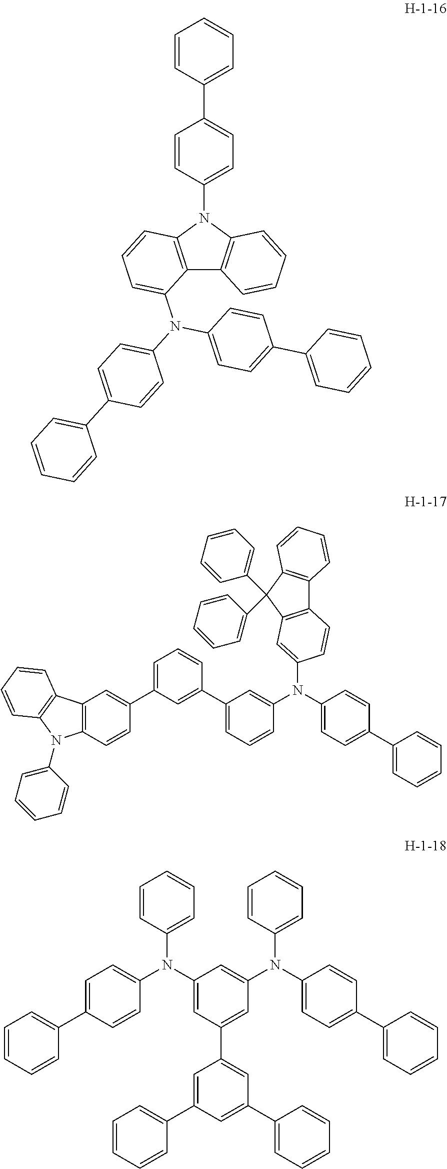 [SMILES: c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1 ; c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1]

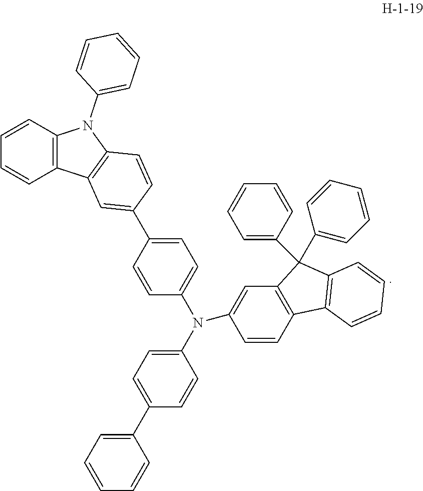 [SMILES: c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

In one or more embodiments, the hole transport regions HTR and HTR-a may include one or more selected from among a phthalocyanine compound, such as copper phthalocyanine, N¹, N¹′-([1,1′-biphenyl]-4,4′-diyl)bis(N¹-phenyl-N₄, N₄-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonicacid (PANI/CSA), polyaniline/poly(4-styrenesulfonate) (PANI/PSS), N,N′-di(1-naphthalen-1-yl)-N,N′-diphenyl-benzidine (NPB), triphenylamine-containing polyetherketone (TPAPEK), 4-isopropyl-4′-methyldiphenyliodonium tetrakis(pentafluorophenyl) borate, dipyrazino[2,3-f: 2′,3′-h]quinoxaline-2,3,6,7,10,11-hexacarbonitrile (HATCN), and/or the like.

In one or more embodiments, the hole transport regions HTR and HTR-a may include carbazole-based derivatives such as N-phenyl carbazole and polyvinyl carbazole, fluorene-based derivatives, N,N′-bis(3-methylphenyl)-N, N′-diphenyl-[1,1-biphenyl]-4,4′-diamine (TPD), triphenylamine-based derivatives such as 4,4′,4″-tris(N-carbazolyl)triphenylamine (TCTA), N,N′-di(1-naphthalen-1-yl)-N, N′-diphenyl-benzidine (NPB), 4,4′,4″-tris[N,N-bis(4-methylphenyl)benzenamine](TAPC), 4,4′-bis[N,N′-(3-tolyl)amino]-3,3′-dimethylbiphenyl (HMTPD), and 1,3-bis(N-carbazolyl)benzene (mCP), and/or the like.

In one or more embodiments, the hole transport regions HTR and HTR-a may include one or more selected from among 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), and/or the like.

In one or more embodiments, the hole transport regions HTR and HTR-a may further include a charge generation material to increase conductivity (e.g., electric conductivity) in addition to the above-described materials. For example, the hole injection layers HIL and HIL-a may further include a charge generation material to improve conductivity (e.g., electric conductivity). The charge generation material may be, for example, a p-dopant. The p-dopant may be uniformly (e.g., substantially uniformly) dispersed (or distributed) within the hole injection layers HIL and HIL-a. The light emitting elements EL and EL-a according to one or more embodiments may include a doped region including a p-dopant in the hole injection layers HIL and HIL-a. When a doped region is introduced into the hole injection layers HIL and HIL-a, the light emitting elements EL and EL-a may lower hole injection barriers and exhibit improved hole injection characteristics, thereby enhancing luminous efficiency.

For example, the p-dopant may be dispersed (or distributed) in a region adjacent to or in contact with the first electrode AE within the hole injection layers HIL and HIL-a, or may be dispersed (or distributed) in a region spaced apart from each of the first electrode AE and the second electrode CE within the hole injection layers HIL and HIL-a. Accordingly, the hole injection layers HIL and HIL-a may include a doped region including a p-dopant and an undoped region not including a p-dopant. The hole injection layers HIL and HIL-a may be divided into a doped region and an undoped region. In the hole injection layers HIL and HIL-a, the doped region may include a p-dopant and a hole injection material, and the undoped region may include only a hole injection material.

The p-dopant may include at least one selected from among halogenated metal compounds, quinone derivatives, metal oxides, or cyano group-containing compounds, but the present disclosure is not limited thereto. For example, the p-dopant may include halogenated metal compounds such as Cul and Rbl, quinone derivatives such as tetracyanoquinodimethane (TCNQ) and 2,3,5,6-tetrafluoro-7,7,8,8-tetracyanoquinodimethane (F4-TCNQ), metal oxides such as tungsten oxides and molybdenum oxides, cyano group-containing compounds such as dipyrazino[2,3-f: 2′,3′-h]quinoxaline-2,3,6,7,10,11-hexacarbonitrile (HATCN) and 4-[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and/or the like, but embodiments are not limited thereto.

Referring to FIGS. 7A-7D, in the light emitting element EL according to one or more embodiments, the emission layer EML may be on the hole transport region HTR. Referring to FIG. 7E, in the light emitting element EL-a according to one or more embodiments, the emission layers EML-a and EML-b may be on the hole transport region HTR-a and the charge generation layer CGL. For example, the emission layer EML-a included in the lower organic layers EE-a may be on the hole transport region HTR-a. The emission layer EML-b included in the upper organic layers EE-b may be on the charge generation layer CGL.

The emission layers EML, EML-a, and EML-b may have, for example, a thickness of about 100 Å to about 1000 Å or about 100 Å to about 300 Å. The emission layers EML, EML-a, and EML-b may have a single layer formed of a single material, a single layer formed of a plurality of different materials, or a multi-layer structure having a plurality of layers formed of a plurality of different materials.

The emission layers EML, EML-a, and EML-b may include an anthracene derivative, a pyrene derivative, a fluoranthene derivative, a chrysene derivative, a dihydrobenzanthracene derivative, and/or a triphenylene derivative. For example, the emission layers EML, EML-a, and EML-b may include an anthracene derivative or a pyrene derivative.

The emission layers EML, EML-a, and EML-b may be formed using one or more suitable methods such as a vacuum deposition method, a spin coating method, a cast method, a Langmuir-Blodgett (LB) method, an inkjet printing method, a laser printing method, and/or a laser induced thermal imaging (LITI) method.

The emission layers EML, EML-a, and EML-b may include hosts and dopants. The emission layers EML, EML-a, and EML-b may include a compound represented by Formula E-1. For example, the emission layers EML, EML-a, and EML-b may include a compound represented by Formula E-1. The compound represented by Formula E-1 may be used as a fluorescent host material.

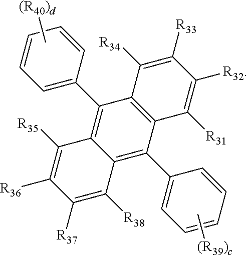

In Formula E-1, R₃₁ to R₄₀ may each independently be hydrogen, deuterium, a halogen, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, a substituted or unsubstituted heteroaryl group having 2 to 30 ring-forming carbon atoms, or bonded to an adjacent group to form a ring. In one or more embodiments, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

Formula E-1 may be represented by any one among compounds E1 to E19.

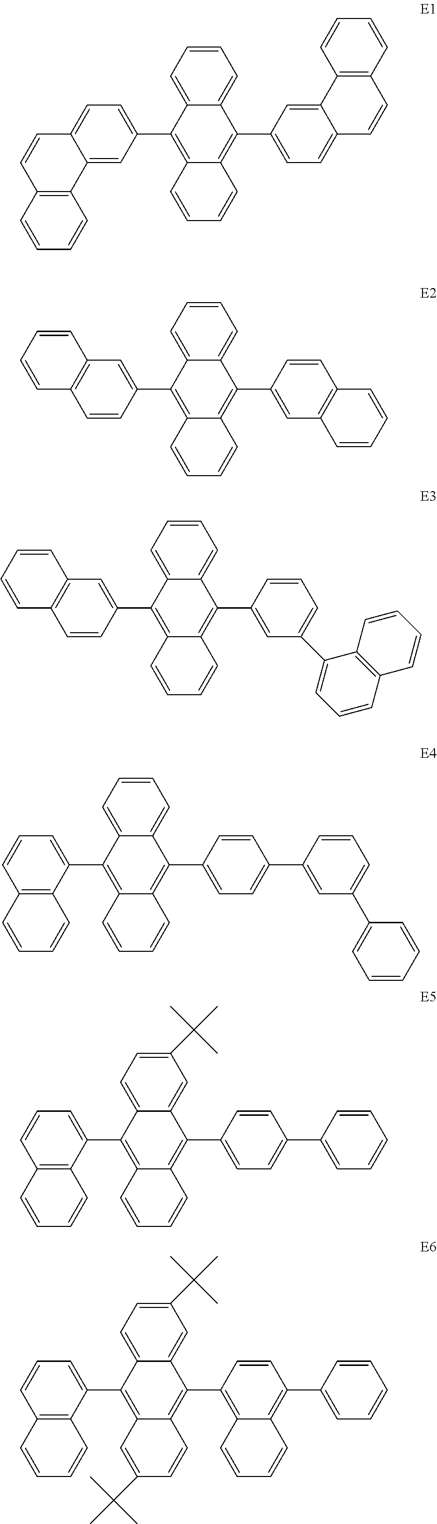

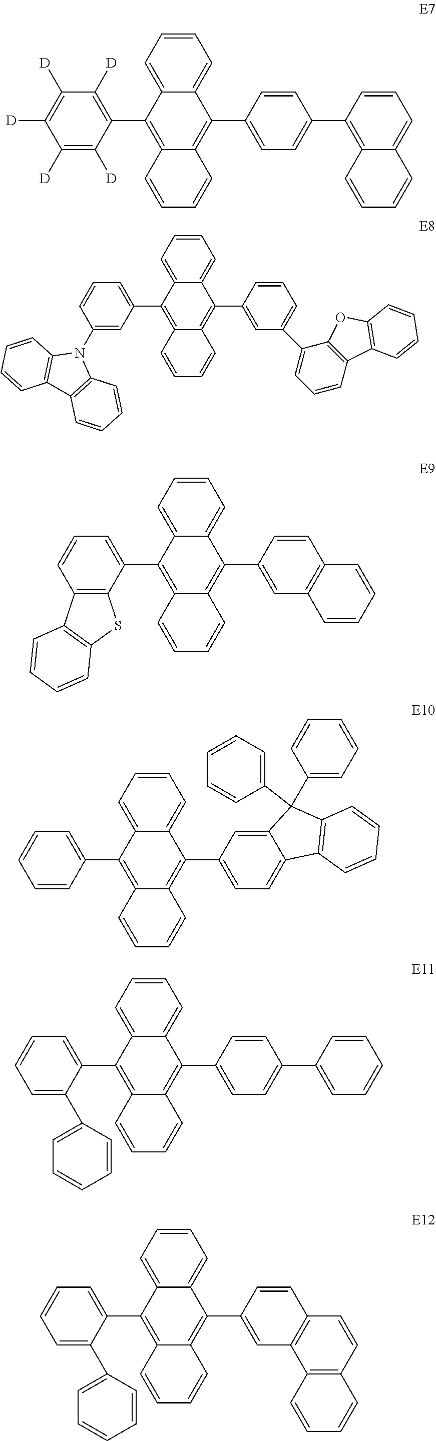

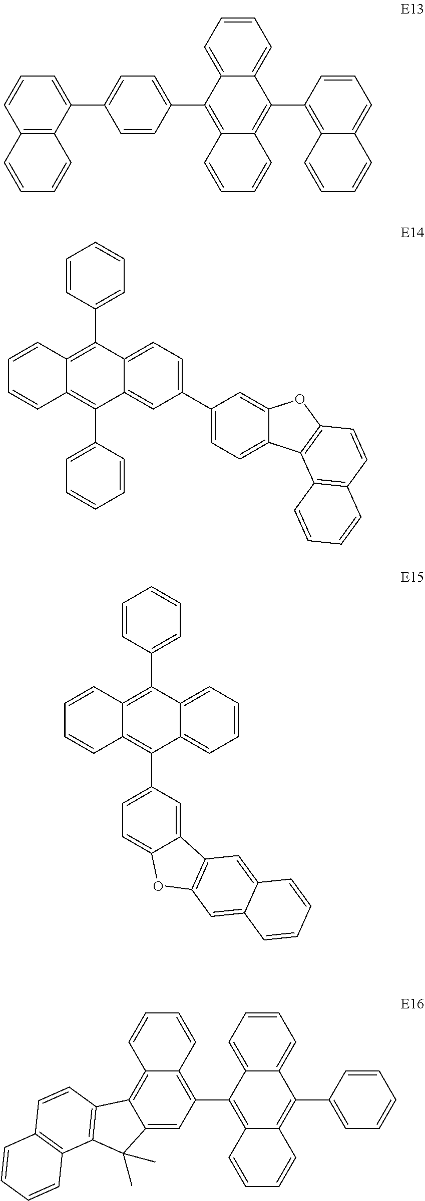

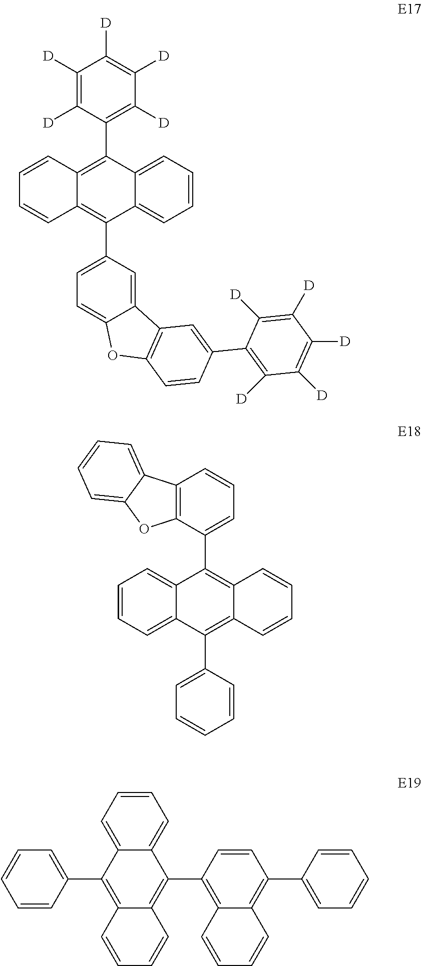

In one or more embodiments, the emission layers EML, EML-a, and EML-b may include a compound represented by Formula E-2a or Formula E-2b. The compound represented by Formula E-2a or Formula E-2b may be used as a host material for a phosphorescent element.

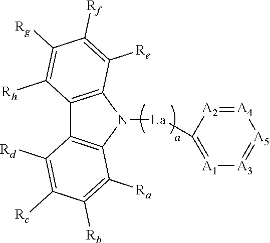

In Formula E-2a, a may be an integer of 0 to 10, and La may be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a is an integer of 2 or greater, multiple Lₐ may each independently be a substituted or unsubstituted arylene group having 6 to 30 ring-forming carbon atoms, or a substituted or unsubstituted heteroarylene group having 2 to 30 ring-forming carbon atoms.

In one or more embodiments, in Formula E-2a, A₁ to A₅ may each independently be N or CRᵢ. Rₐ to Rᵢ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, and/or may be independently bonded to an adjacent group to form a ring. In one or more embodiments, one or more selected from among Rₐ to Rᵢ may be each independently bonded to an adjacent group to form a hydrocarbon ring or a heterocycle containing N, O, S, and/or the like as a ring-forming atom.

In one or more embodiments, in Formula E-2a, two or three selected from among A₁ to A₅ may be N, and the others may be CRᵢ.

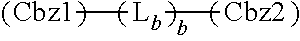

In Formula E-2b, Cbz1 and Cbz2 may each independently be an unsubstituted carbazole group or an aryl-substituted carbazole group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms, b may be an integer of 0 to 10, and if (e.g., when) b is an integer of 2 or greater, multiple L_{b} may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be any one selected from among the compounds from Compound Group E-2. However, the compounds listed in Compound Group E-2 are presented as an example, and the compound represented by Formula E-2a or Formula E-2b is not limited to those listed in Compound Group E-2.

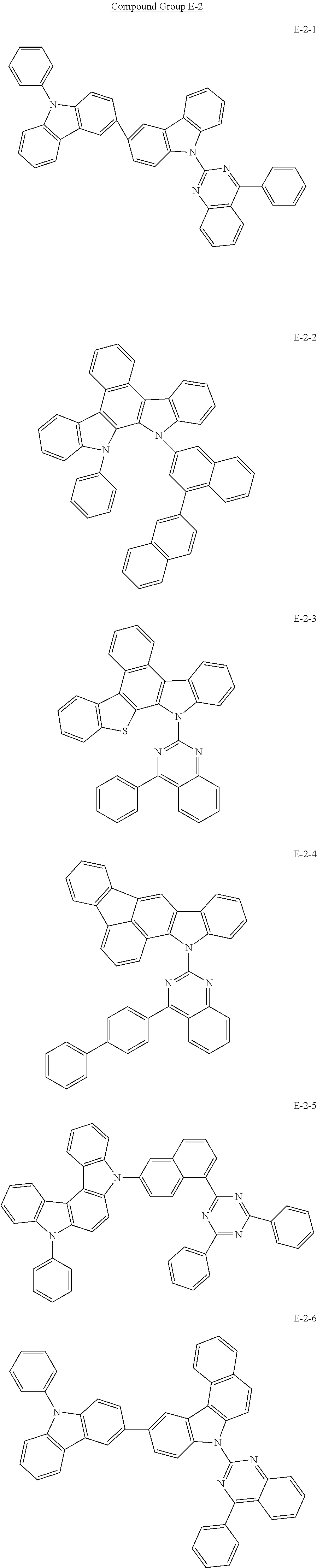 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5cc(-c6ccc7ccccc7c6)c6ccccc6c5)c4c32)cc1 ; c1ccc(-c2nc(-n3c4ccccc4c4c5ccccc5c5c6ccccc6sc5c43)nc3ccccc23)cc1 ; c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

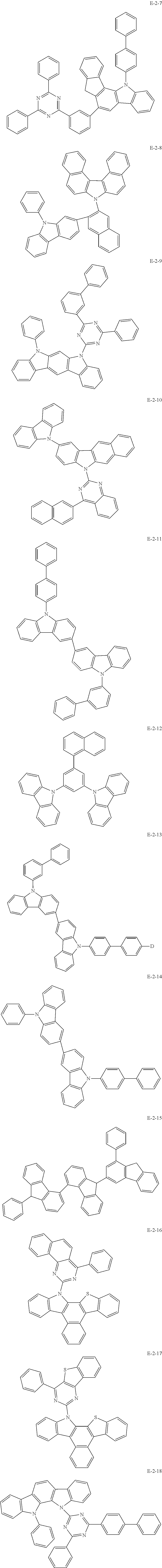

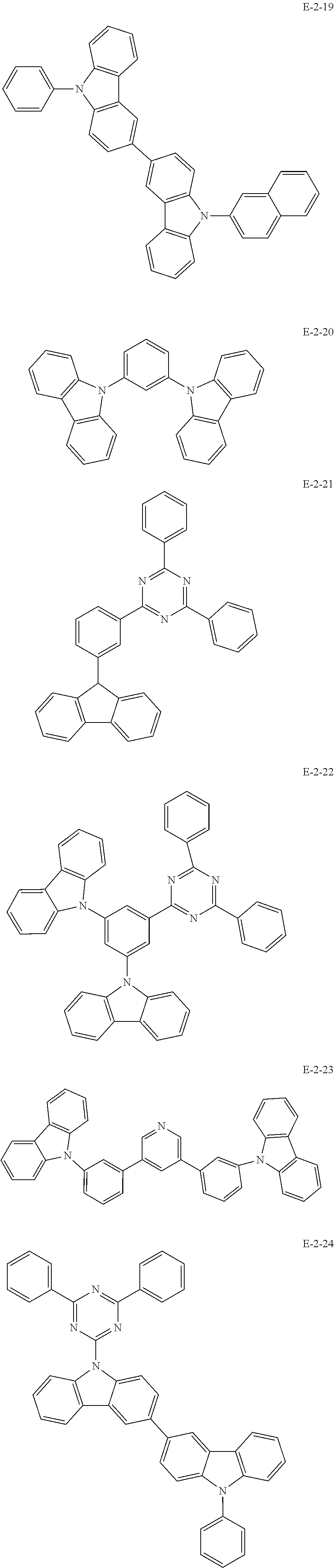 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(C4c5ccccc5-c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In one or more embodiments, the emission layers EML, EML-a, and EML-b may further include a general material suitable in the art as a host material. For example, the emission layers EML, EML-a, and EML-b may include, as a host material, at least one of bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), or 1,3,5-tris(1-phenyl-1H-benzo[d]imidazol-2-yl)benzene (TPBi). However, embodiments are not limited thereto, and for example, tris(8-hydroxyquinolino)aluminum (Alq3), 9, 10-di(naphthalen-2-yl) anthracene (ADN), 3-tert-butyl-9,10-di(naphth-2-yl) anthracene (TBADN), distyrylarylene (DSA), 4,4′-bis(9-carbazolyl)-2,2′-dimethyl-biphenyl (CDBP), 2-methyl-9,10-bis(naphthalen-2-yl) anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), and/or the like may be used as a host material.

In one or more embodiments, the emission layers EML, EML-a, and EML-b may include a compound represented by Formula M-a. The compound represented by Formula M-a may be used as a dopant material for a phosphorescent element.

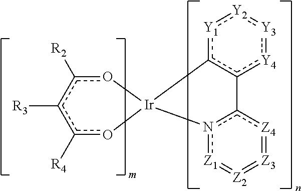

In Formula M-a above, Y₁ to Y₄ and Z₁ to Z₄ may each independently be CR₁ or N, and R₁ to R₄ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, and/or may be independently bonded to an adjacent group to form a ring. In Formula M-a, m is 0 or 1, and n is 2 or 3. In Formula M-a, if (e.g., when) m is 0, n is 3, and if (e.g., when) m is 1, n is 2.

The compound represented by Formula M-a may be any one selected from among compounds M-a1 to M-a25. However, the compounds M-a1 to M-a25 are presented as an example, and the compound represented by Formula M-a is not limited to those represented by the compounds M-a1 to M-a25.

The emission layers EML, EML-a, and EML-b may include a compound represented by Formula M-a. The compound represented by Formula M-a may be used as a dopant material for a phosphorescent element.

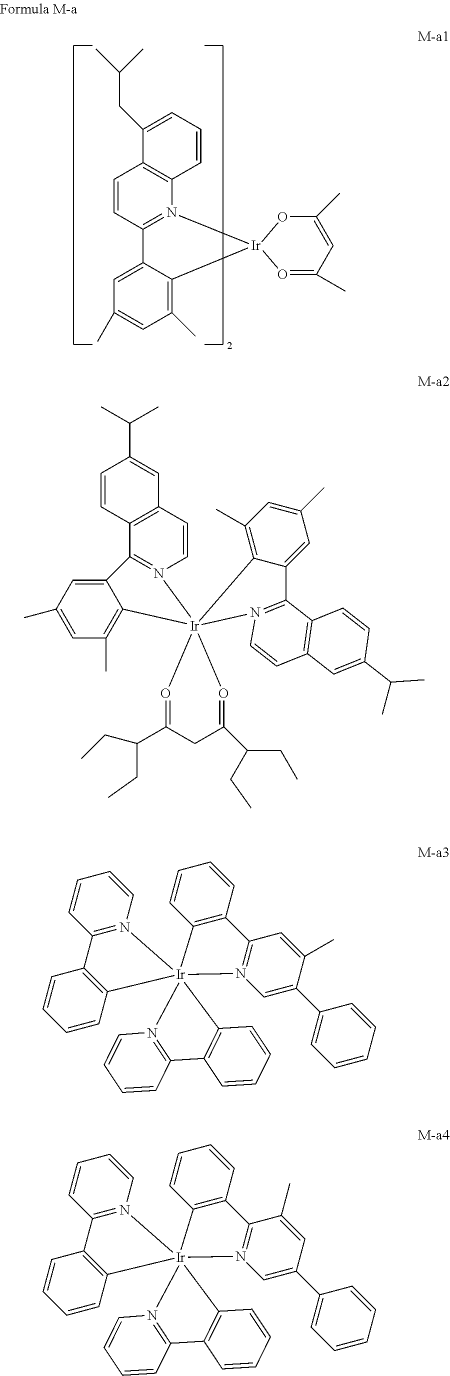

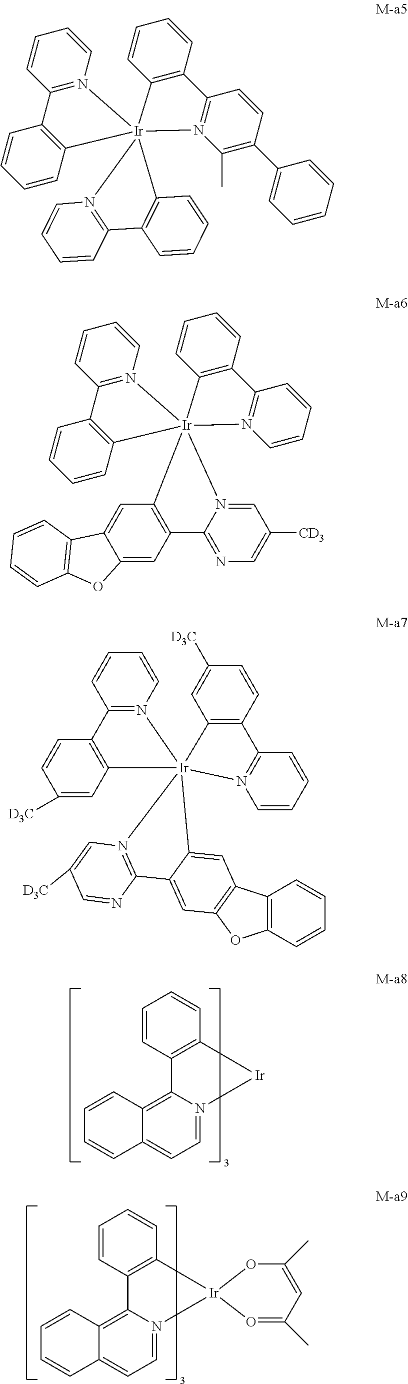

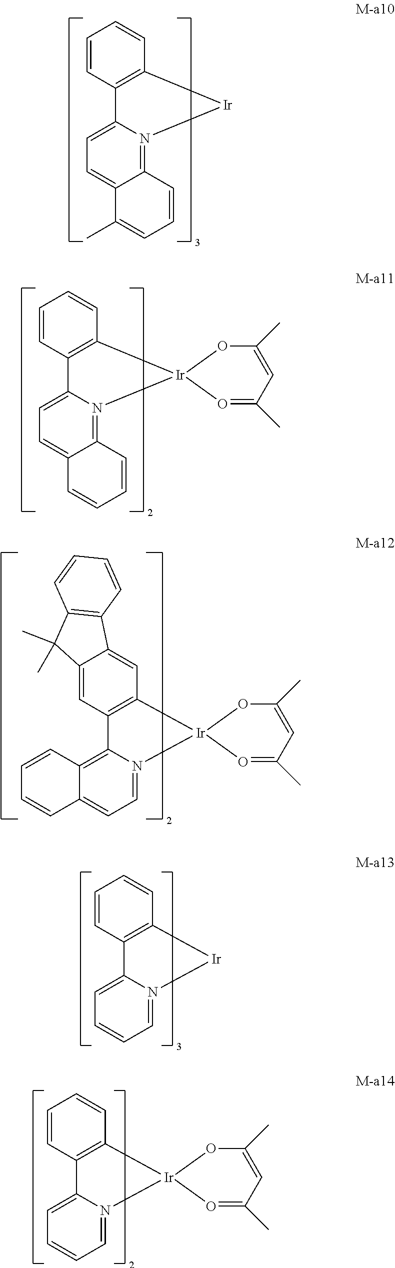

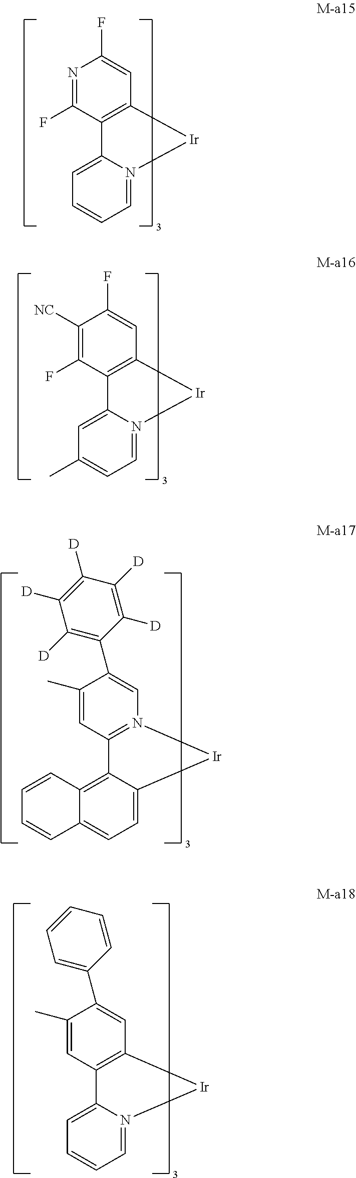

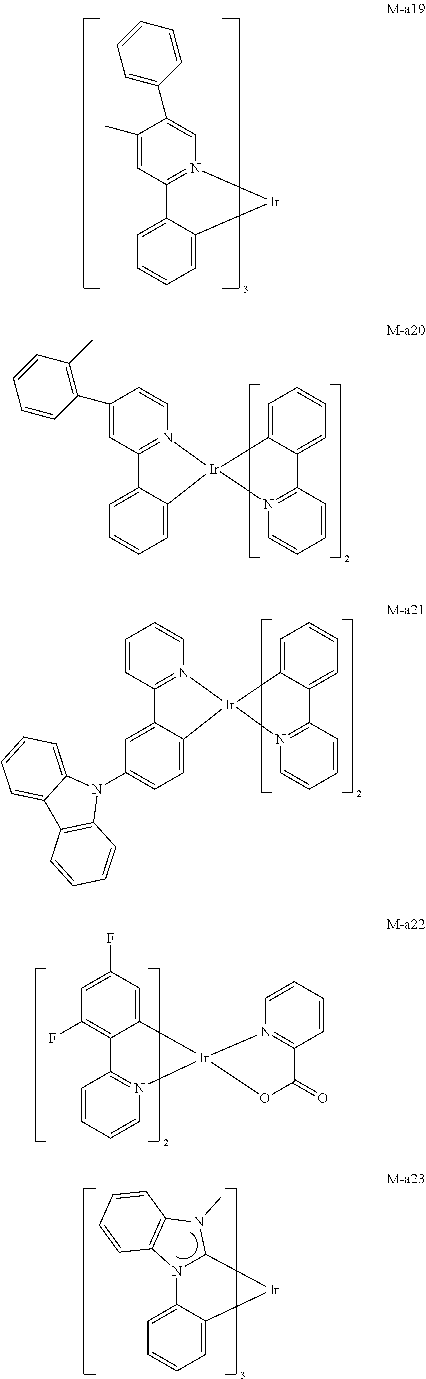

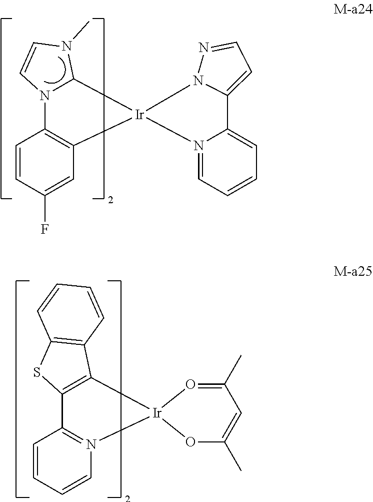

In one or more embodiments, the emission layers EML, EML-a, and EML-b may further include at least one selected from among a compound represented by Formulas F-a to F-c. The compounds represented by Formulas F-a to F-c may be used as a fluorescence dopant material.

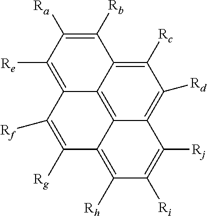

In Formula F-a above, two selected from among Rₐ to Rⱼ may each independently be substituted with *—NAr₁Ar₂. The others among Rₐ to Rⱼ which are not substituted with *—NAr₁Ar₂ may each independently be hydrogen, deuterium, a halogen, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In *—NAr₁Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, at least one of Ar₁ or Ar₂ may be a heteroaryl group containing O or S as a ring-forming atom.

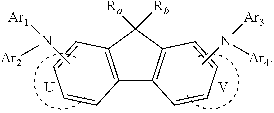

In Formula F-b above, Rₐ and R_{b} may each independently be hydrogen, deuterium, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, a substituted or unsubstituted heteroaryl group having 2 to 30 ring-forming carbon atoms, and/or bonded to an adjacent group to form a ring. Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms. At least one selected from among Ar₁ to Ar₄ may be a heteroaryl group containing O or S as a ring-forming atom.

In Formula F-b, the number of rings represented by U and V may each independently be 0 or 1. For example, in Formula F-b, if (e.g., when) the number of U or V is 1, one ring forms a fused ring in a portion indicated by U or V, and if (e.g., when) the number of U or V is 0, it refers to that no ring indicated by U or V is present. For example, if (e.g., when) the number of U is 0 and the number of V is 1, or if (e.g., when) the number of U is 1 and the number of V is 0, a fused ring having a fluorene core of Formula F-b may be a cyclic compound having four rings. In one or more embodiments, if (e.g., when) the number of U and V are both (e.g., simultaneously) 0, the fused ring of Formula F-b may be a cyclic compound having three rings. In addition, if (e.g., when) the number of U and V are both (e.g., simultaneously) 1, the fused ring having a fluorene core of Formula F-b may be a cyclic compound having five rings.

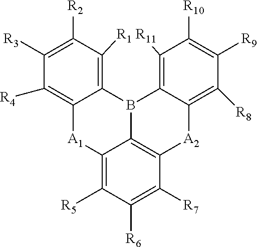

In Formula F-c, A₁ and A₂ may each independently be O, S, Se, or NRₘ, and Rₘ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-c, A₁ and A₂ may each independently be bonded to substituents of neighboring rings to form a fused ring. For example, if (e.g., when) A₁ and A₂ may each independently be NRₘ, A₁ may be bonded to R₄ or R₅ to form a ring. In one or more embodiments, A₂ may be bonded to R₇ or R₈ to form a ring.

In one or more embodiments, the emission layers EML, EML-a, and EML-b may further include, as a suitable dopant material, styryl derivatives (e.g., 1,4-bis[2-(3-N-ethylcarbazolyl) vinyl]benzene (BCzVB), 4-(di-p-tolylamino)-4′-[(di-p-tolylamino) styryl]stilbene (DPAVB), and N-(4-((E)-2-(6-((E)-4-(diphenylamino) styryl) naphthalen-2-yl) vinyl)phenyl)-N-phenylbenzenamine (N-BDAVBi)), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), and/or the like.

In one or more embodiments, the emission layers EML, EML-a, and EML-b may further include a suitable phosphorescent dopant material. For example, as a phosphorescent dopant, a metal complex including iridium (Ir), platinum (Pt), osmium (Os), gold (Au), titanium (Ti), zirconium (Zr), hafnium (Hf), europium (Eu), and terbium (Tb), or thulium (Tm) may be used. For example, iridium(III) bis(4,6-difluorophenylpyridinato-N, C2′) picolinate (FIrpic), bis(2,4-difluorophenylpyridinato)-tetrakis (1-pyrazolyl) borate iridium(III) (Fir6), platinum octaethyl porphyrin (PtOEP), and/or the like may be used as a phosphorescent dopant. However, embodiments are not limited thereto.

In one or more embodiments, the emission layers EML, EML-a, and EML-b may include a quantum dot material (e.g., quantum dot). In one or more embodiments, the core of a quantum dot may be selected from among a Group II-VI compound, a Group III-VI compound, a Group I-III-VI compound, a Group III-V compound, a Group III-II-V compound, a Group IV-VI compound, a Group IV element, a Group IV compound, and a combination thereof.

The Group II-VI compound may be selected from among the group consisting of a binary compound selected from the group consisting of CdSe, CdTe, CdS, ZnS, ZnSe, ZnTe, ZnO, HgS, HgSe, HgTe, MgSe, MgS, and a mixture thereof, a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof, and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The Group III-VI compound may include a binary compound such as In₂S₃ and In₂Se₃, a ternary compound such as InGaS₃ and InGaSe₃, or any combination thereof.

The Group I-III-VI compound may be selected from among a ternary compound selected from among the group consisting of AgInS, AgInS₂, CuInS, CuInS₂, AgGaS₂, CuGaS₂ CuGaO₂, AgGaO₂, AgAlO₂, or a mixture thereof, or a quaternary compound such as AgInGaS, AgInGaS₂, AgInGaSe, AgInGaSe₂, CuInGaS and CuInGaS₂.

The Group III-V compound may be selected from among the group consisting of a binary compound selected from the group consisting of GaN, GaP, GaAs, GaSb, AlN, AIP, AIAs, AISb, InN, InP, InAs, InSb, and a mixture thereof, a ternary compound selected from the group consisting of GaNP, GaNAs, GaNSb, GaPAs, GaPSb, AlNP, AlNAs, AlNSb, AIPAs, AIPSb, InGaP, InAIP, InNP, InNAs, InNSb, InPAs, InPSb, and a mixture thereof, and a quaternary compound selected from the group consisting of GaAINP, GaAINAs, GaAINSb, GaAIPAs, GaAIPSb, GalnNP, GalnNAs, GalnNSb, GalnPAs, GalnPSb, InAINP, InAINAs, InAINSb, InAIPAs, InAIPSb, and a mixture thereof. In one or more embodiments, the Group III-V compound may further include a Group II metal. For example, InZnP and/or the like may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

Each element included in the multi-element compound such as the binary compound, ternary compound, and/or quaternary compound may be present in particles at a substantially uniform concentration or a non-substantially uniform concentration. For example, the chemical formula (e.g., Formula F-c) representing a semiconductor compound above indicates the types (kinds) of elements included in a compound, and element ratios in the compound may be different. For example, AgInGaS₂ may indicate AgInₓGa₁₋ₓS₂ (x is a real number between 0 and 1).

In one or more embodiments, the quantum dot may have a single structure having a substantially uniform concentration of each element included in the corresponding quantum dot or a dual structure of core-shell. For example, materials included in the core may be different from materials included in the shell.

The shell of the quantum dot may serve as a protection layer to prevent or reduce the chemical deformation of the core so as to keep semiconductor properties, and/or a charging layer to impart electrophoresis properties to the quantum dot. The shell may be single-layered or multi-layered. An interface between the core and the shell may have a concentration gradient in which the concentration of an element present in the shell becomes lower towards the center.

In one or more embodiments, the quantum dot may have the above-described core/shell structure including a core having nano-crystals and a shell around (e.g., surrounding) the core. The shell of the quantum dot may serve as a protection layer to prevent or reduce the chemical deformation of the core so as to keep semiconductor properties, and/or a charging layer to impart electrophoresis properties to the quantum dot. The shell may be single-layered or multi-layered. Examples of the shell of the quantum dot may be a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, or a ternary compound such as MgAl₂O₄, CoFe₂O₄, NiFe₂O₄, and/or CoMn₂O₄, but the disclosure is not limited thereto.

In one or more embodiments, the semiconductor compound may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AIP, AISb, and/or the like, but the disclosure is not limited thereto.

Each element included in the multi-element compound, such as the binary compound and the ternary compound, may be present in particles at a substantially uniform concentration or a non-substantially uniform concentration. For example, the chemical formula representing the multi-element compound indicates the types (kinds) of elements included in a compound, and element ratios in the compound may be different.

The quantum dot may have, in a light emitting wavelength spectrum, a full width at half maximum (FWHM) of about 45 nm or less, about 40 nm or less, and more about 30 nm or less, and in this range, color purity or color reproducibility may be improved. In addition, light emitted through the quantum dot is emitted in all directions, and thereby improving the wide viewing angle.

In addition, the form of the quantum dot is not particularly limited as long as it is a form commonly used in the relevant art, but for example, a quantum dot in the form of spherical, pyramidal, multi-arm, or cubic nanoparticles, nanotubes, nanowires, nanofibers, nanoplatelets, and/or the like may be used.

As the size of the quantum dot or the ratio of elements in the quantum dot compound is regulated, an energy band gap may be accordingly controlled or selected to obtain light of one or more suitable wavelengths from the quantum dot emission layer. Therefore, by using the quantum dot as described above (using quantum dots of different sizes or having different element ratios in the quantum dot compound), a light emitting element emitting light of one or more suitable wavelengths may be obtained. For example, the size of the quantum dot or the ratio of elements in the quantum dot compound may be regulated to emit red color light, green color light, and/or blue color light. In addition, the quantum dots may be configured to emit white light by combining light of one or more suitable colors.

In the light emitting element EL according to one or more embodiments shown in FIGS. 7A-7D, an electron transport region ETR is provided on the emission layer EML. The electron transport region ETR may include at least one of a hole blocking layer, an electron transport layer ETL, or an electron injection layer EIL, but embodiments are not limited thereto. In the light emitting element EL-a according to one or more embodiments shown in FIG. 7E, electron transport regions ETR-a and ETR-b are provided on the emission layers EML-a and EML-b. For example, the electron transport region ETR-a included in the lower organic layers EE-a may be on the lower emission layer EML-a closer to the first electrode AE than the second electrode CE. The electron transport region ETR-b included in the upper organic layers EE-b may be on the upper emission layer EML-b closer to the second electrode CE than the first electrode AE. The electron transport regions ETR-a and ETR-b may include the electron transport layers ETL-a and ETL-b. However, embodiments are not limited thereto, and the electron transport regions ETR-a and ETR-b may further include at least one of an electron injection layer or a hole blocking layer.

The electron transport regions ETR, ETR-a, and ETR-b may have a single layer formed of a single material, a single layer formed of a plurality of different materials, or a multi-layer structure having a plurality of layers formed of a plurality of different materials.

The electron transport regions ETR, ETR-a, and ETR-b may be formed using one or more suitable methods such as a vacuum deposition method, a spin coating method, a cast method, a Langmuir-Blodgett (LB) method, an inkjet printing method, a laser printing method, a laser induced thermal imaging (LITI) method, and/or the like.

For example, the electron transport regions ETR, ETR-a, and ETR-b may have a single-layer structure of electron transport layers ETL, ETL-a, and ETL-b, and may have a single-layer structure formed of an electron injection material and an electron transport material. However, embodiments are not limited thereto, and the electron transport region ETR may also have a single-layer structure of an electron injection layer EIL. In addition, the electron transport region ETR included in the light emitting element EL according to one or more embodiments may have a single-layer structure formed of a plurality of different materials, or may have a structure of an electron transport layer ETL/electron injection layer EIL, or a hole blocking layer/electron transport layer ETL/electron injection layer EIL sequentially stacked from the emission layer EML, but the present disclosure is not limited thereto. The electron transport regions ETR-a and ETR-b included in the light emitting element EL-a according to one or more embodiments may have a single-layer structure formed of a plurality of different materials, or may have a structure of electron transport layers ETL-a and ETL-b/electron injection layer EIL, or a hole blocking layer/electron transport layers ETL-a and ETL-b/electron injection layer EIL sequentially stacked from the emission layers EML-a and EML-b, but the present disclosure is not limited thereto. The electron transport regions ETR, ETR-a, and ETR-b may have a thickness of, for example, about 1000 Å to about 1500 Å.

The electron transport regions ETR, ETR-a, and ETR-b may include a compound represented by Formula ET-1.

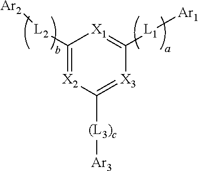

In Formula ET-1, at least one selected from among X₁ to X₃ may be N and the others are CRₐ. Rₐ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer of 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In one or more embodiments, if (e.g., when) a to c are an integer of 2 or greater, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

In one or more embodiments, the electron transport regions ETR, ETR-a, and ETR-b may include an anthracene-based compound. However, embodiments are not limited thereto, and the electron transport regions ETR, ETR-a, and ETR-b may include, for example, tris(8-hydroxyquinolinato)aluminum (Alq₃), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzimidazol-1-yl)phenyl)-9,10-dinaphthylanthracene, 1,3,5-tri (1-phenyl-1H-benz[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenyl-4-yl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenyl-4-yl)-5-(4-tert-butylphenyl)-1,3,4-oxadiazole (tBu-PBD), bis(2-methyl-8-quinolinolato-N1,08)-(1,1′-biphenyl-4-olato)aluminum (BAlq), berylliumbis(benzoquinolin-10-olate (Bebq₂), 9,10-di(naphthalen-2-yl) anthracene (ADN), 1,3-bis[3,5-di(pyridin-3-yl)phenyl]benzene (BmPyPhB), or a mixture thereof.

In one or more embodiments, the electron transport regions ETR, ETR-a, and ETR-b may include at least one selected from among compounds ET1 to ET38.

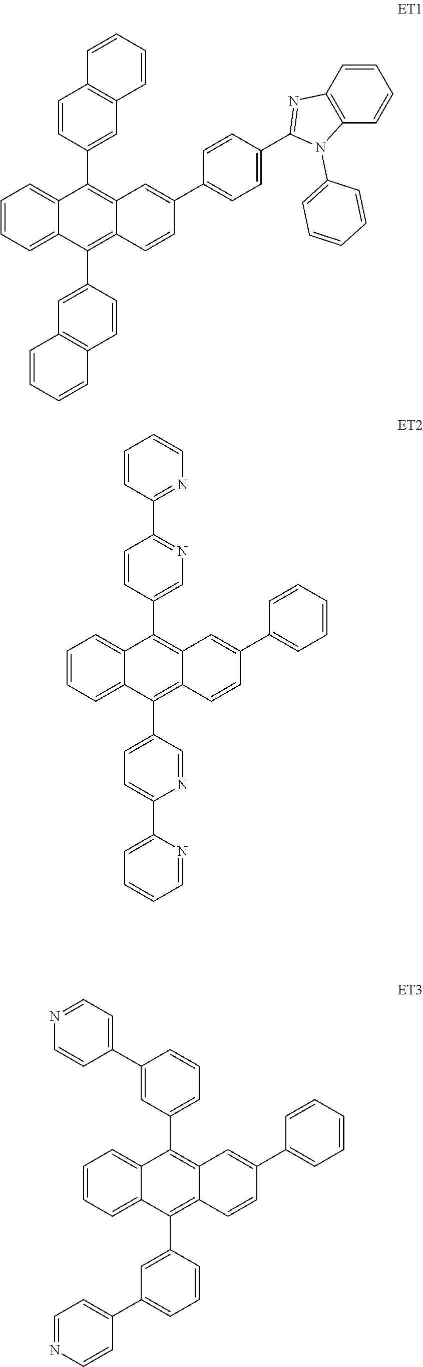 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

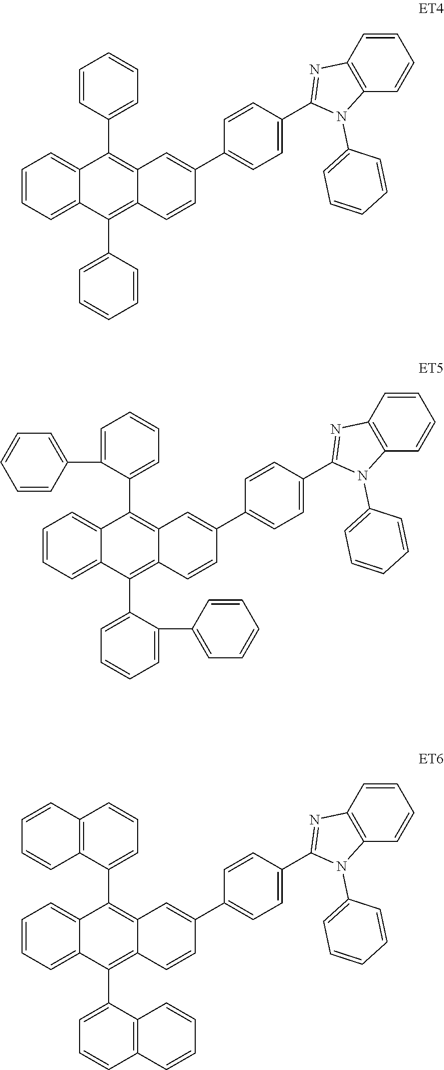 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

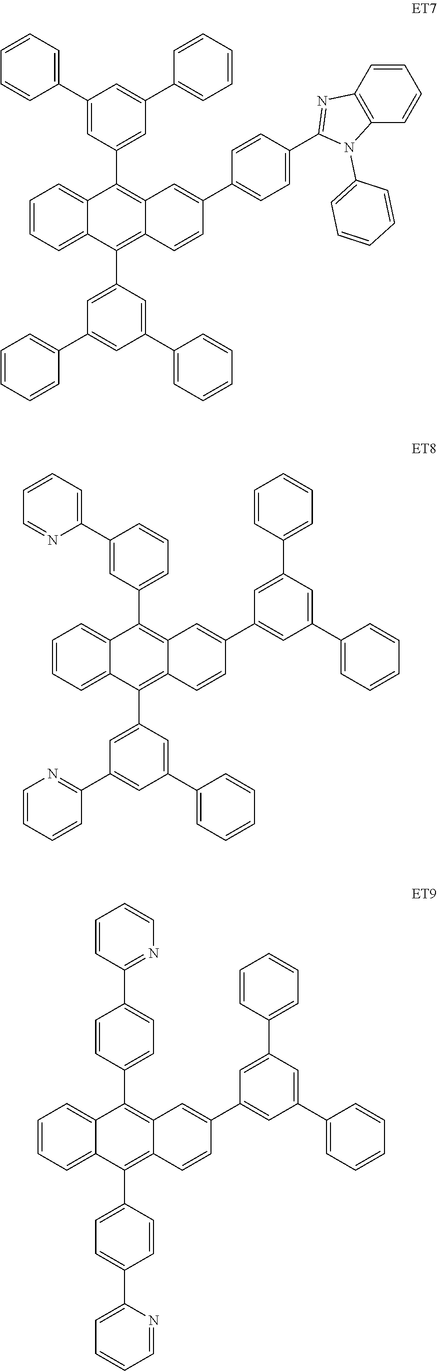 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cc(-c6ccccc6)cc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

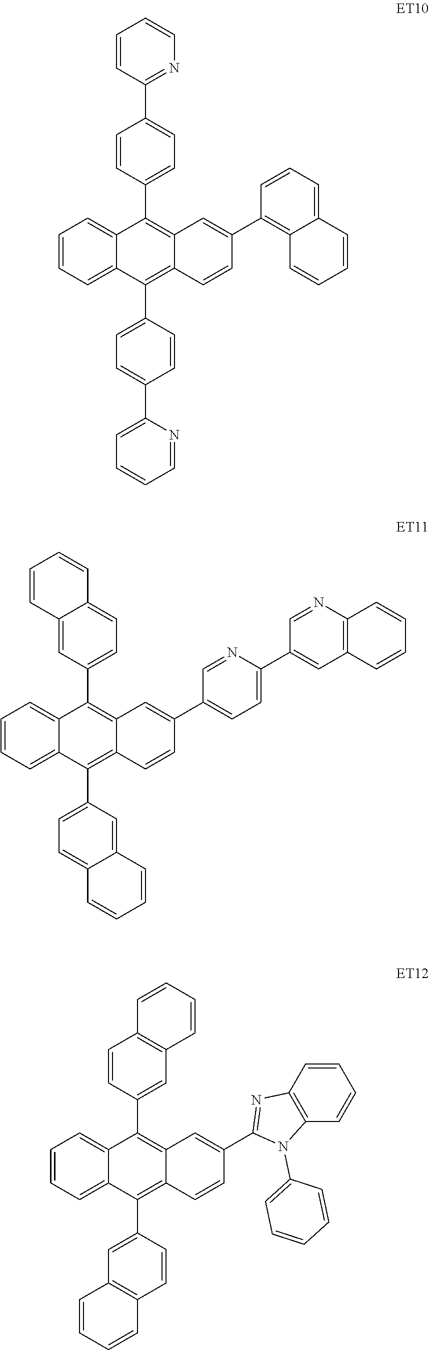 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

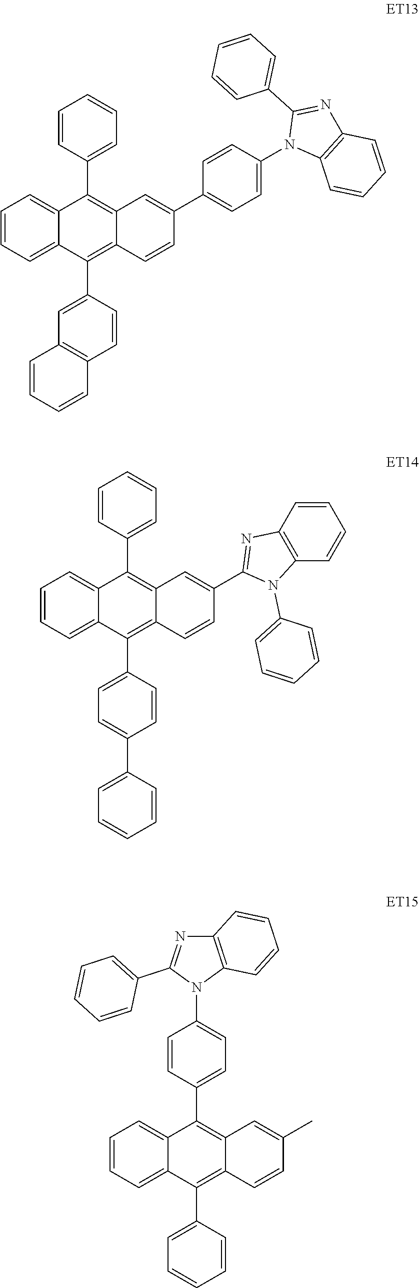 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

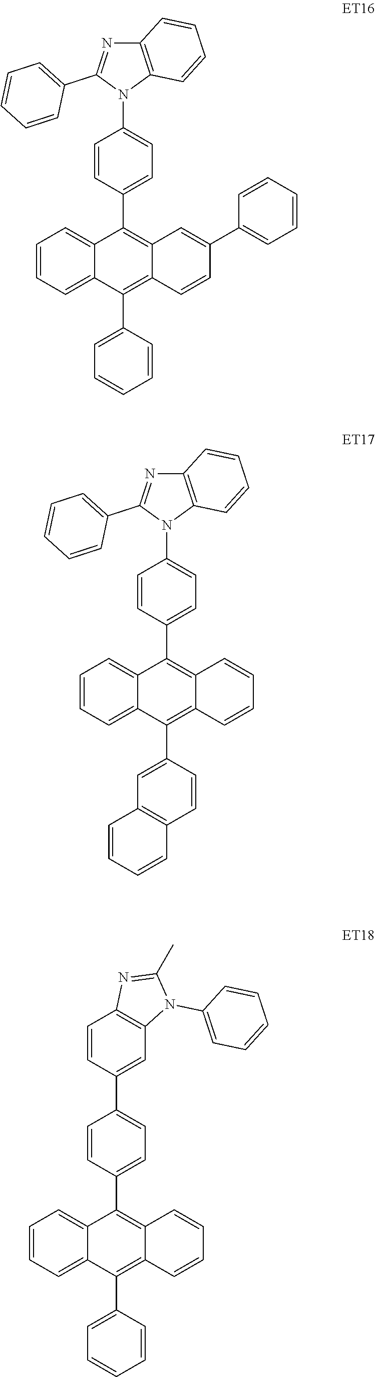 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

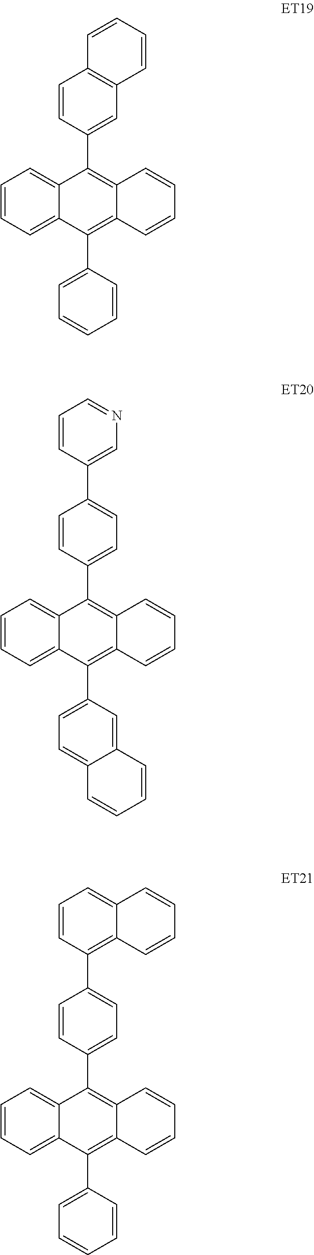

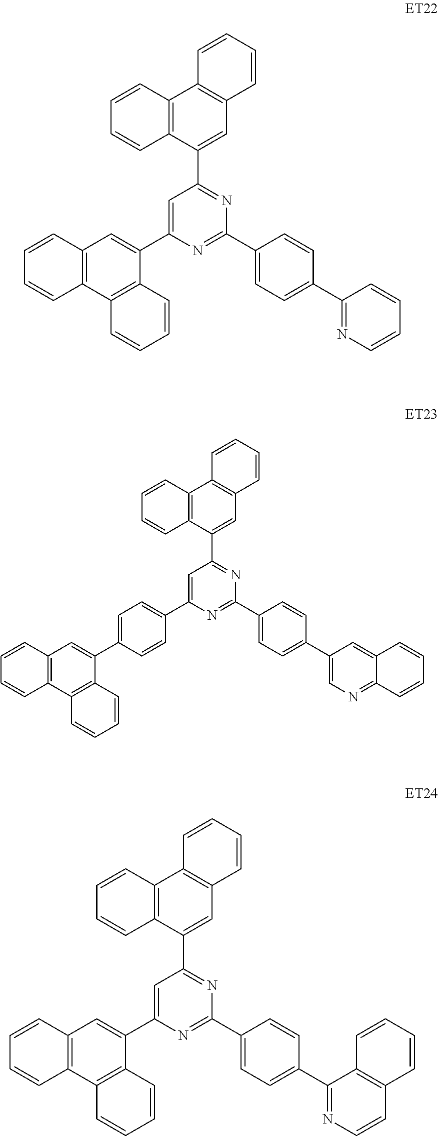 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

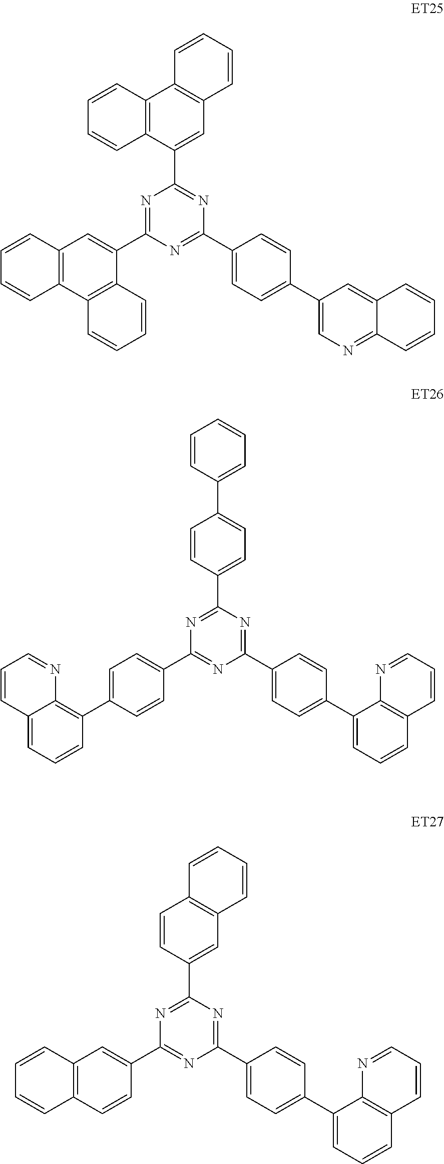 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

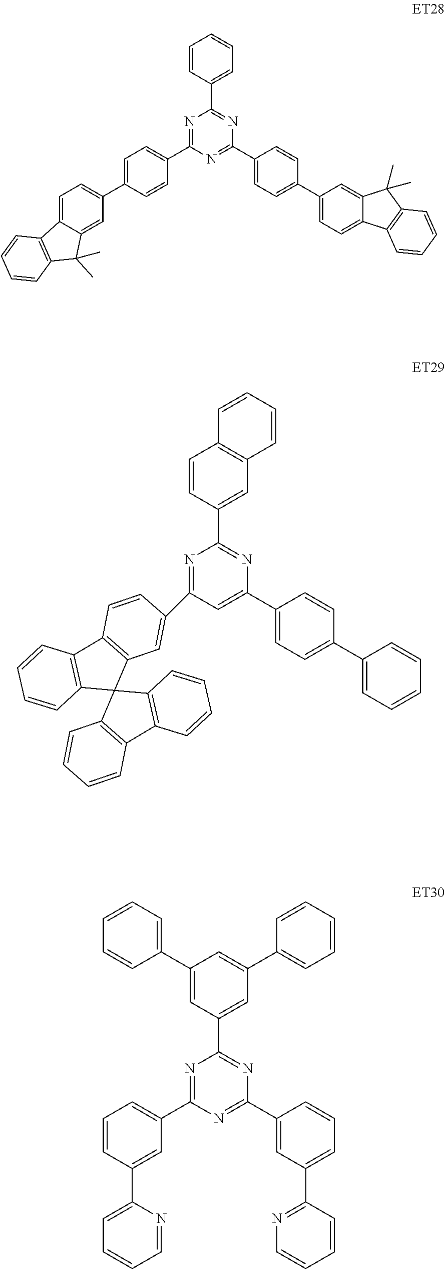 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

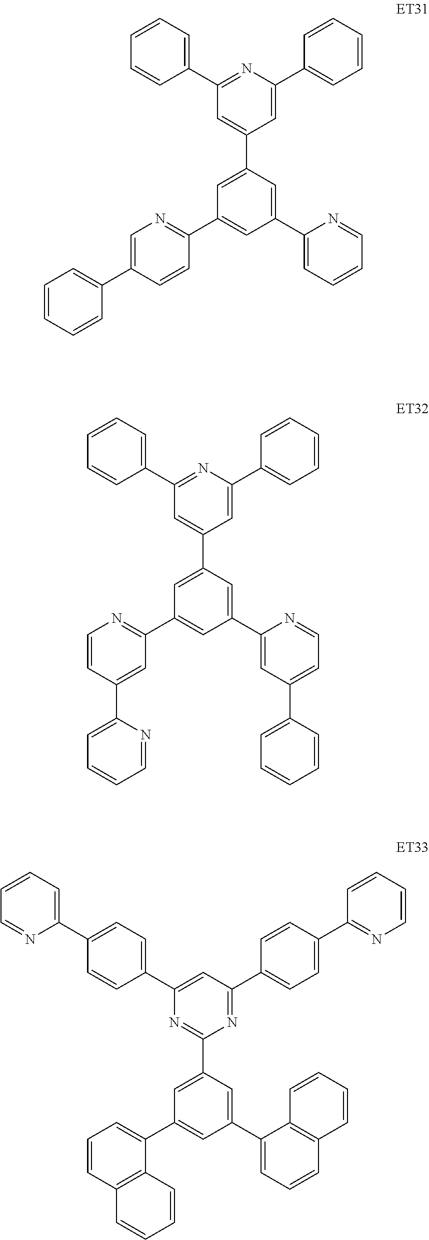 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccn5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

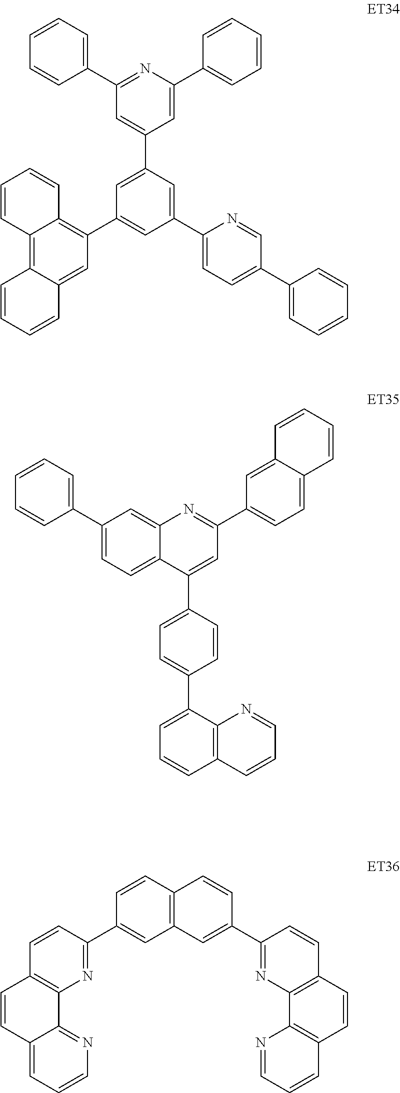 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

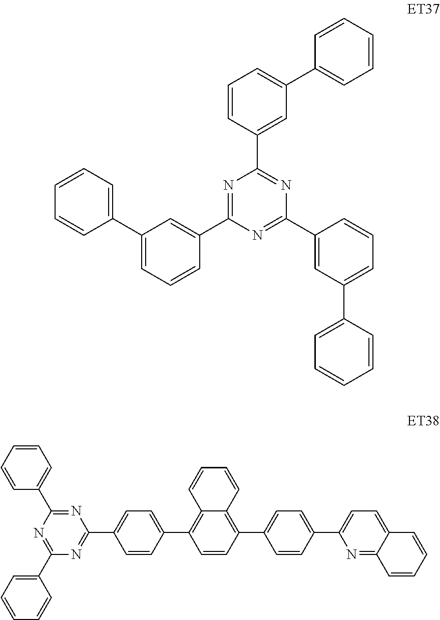 [SMILES: c1ccc(-c2cccc(-c3nc(-c4cccc(-c5ccccc5)c4)nc(-c4cccc(-c5ccccc5)c4)n3)c2)cc1 ; c1ccc(-c2nc(-c3ccccc3)nc(-c3ccc(-c4ccc(-c5ccc(-c6ccc7ccccc7n6)cc5)c5ccccc45)cc3)n2)cc1]

In one or more embodiments, the electron transport regions ETR, ETR-a, and ETR-b may include halogenated metals such as LiF, NaCl, CsF, RbCI, Rbl, Cul, and/or KI, lanthanide metals such as Yb, and/or co-deposition materials of a halogenated metal and a lanthanide metal. For example, the electron transport layers ETL, ETL-a, and ETL-b may include halogenated metals such as LiF, NaCl, CsF, RbCI, Rbl, Cul, and KI, lanthanide metals such as Yb, or co-deposition materials of a halogenated metal and a lanthanide metal. For example, the electron transport layers ETL, ETL-a, and ETL-b may include KI: Yb, Rbl: Yb, LiF: Yb, and/or the like as a co-deposition material. In one or more embodiments, for the electron transport layers ETL, ETL-a, and ETL-b, a metal oxide such as Li₂O and BaO, 8-hydroxyl-lithium quinolate (Liq), and/or the like may be used, but embodiments are not limited thereto. The electron transport layers ETL, ETL-a, and ETL-b may also be formed of a mixture material of an electron transport material and an insulating organo-metal salt. The organo metal salt may be a material having an energy band gap of about 4 eV or greater. For example, the organo-metal salt may include metal acetates, metal benzoates, metal acetoacetates, metal acetylacetonates, and/or metal stearates.

In one or more embodiments, the electron transport regions ETR, ETR-a, and ETR-b may further include, for example, at least one of 2,9-dimethyl-4,7-diphenyl-1,10-phenanthroline (BCP), diphenyl(4-(triphenylsilyl)phenyl)phosphine oxide (TSPO1), or 4,7-diphenyl-1,10-phenanthroline (Bphen) in addition to the materials described above, but embodiments are not limited thereto.

The electron transport regions ETR, ETR-a, and ETR-b may include the compounds of the electron transport region ETR, ETR-a, and ETR-b described above in at least one of the electron injection layer EIL, the electron transport layers ETL, ETL-a, and ETL-b, or the hole blocking layer.

If (e.g., when) the electron transport regions ETR, ETR-a, and ETR-b includes the electron transport layers ETL, ETL-a, and ETL-b, the electron transport layers ETL, ETL-a, and ETL-b may have a thickness of about 100 Å to about 1000 Å, for example, about 150 Å to about 500 Å. When the thickness of the electron transport layers ETL, ETL-a, and ETL-b satisfies the above-described range, satisfactory electron transport properties may be obtained without a substantial increase in driving voltage. If (e.g., when) the electron transport regions ETR, ETR-a, and ETR-b includes the electron injection layer EIL, the electron injection layer EIL may have a thickness of about 1 Å to about 100 Å, for example, about 3 Å to about 90 Å. If (e.g., when) the thickness of the electron injection layer EIL satisfies the above-described ranges, satisfactory electron injection properties may be obtained without a substantial increase in driving voltage.

The second electrode CE is provided on the electron transport regions ETR, ETR-a, and ETR-b. The second electrode CE may be a common electrode. The second electrode CE may be a cathode or an anode but embodiments are not limited thereto. For example, if (e.g., when) the first electrode AE is an anode, the second electrode CE may be a cathode, and if (e.g., when) the first electrode AE is a cathode, the second electrode CE may be an anode.

The second electrode CE may be a transmissive electrode, a transflective electrode, or a reflective electrode. If (e.g., when) the second electrode CE is a transmissive electrode, the second electrode CE may be formed of a transparent metal oxide, for example, indium tin oxide (ITO), indium zinc oxide (IZO), zinc oxide (ZnO), indium tin zinc oxide (ITZO), and/or the like.

If (e.g., when) the second electrode CE is a transflective electrode or a reflective electrode, the second electrode CE may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgYb). In one or more embodiments, the second electrode CE may have a multi-layer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), and/or the like. For example, the second electrode CE may include the above-described metal materials, a combination of two or more metal materials selected from among the above-described metal materials, or oxides of the above-described metal materials.

In one or more embodiments, the second electrode CE may be connected with an auxiliary electrode. If (e.g., when) the second electrode EL2 is connected with the auxiliary electrode, the resistance of the second electrode CE may decrease.

Referring to FIG. 7E, the light emitting element EL-a according to one or more embodiments may include a charge generation layer CGL arranged between the lower organic layers EE-a and the upper organic layers EE-b. When voltages are applied to the light emitting element EL-a, the charge generation layer CGL forms a complex through an oxidation-reduction reaction, thereby generating charges (electrons and holes). For example, the charge generation layer CGL may provide generated charges to each of adjacent lower organic layers EE-a and upper organic layers EE-b. The charge generation layer CGL may increase efficiency of current generated in each of the adjacent organic layers EE-a and EE-b, and may serve to adjust balance of charges between the adjacent organic layers EE-a and EE-b. The charge generation layer CGL may include an n-type (kind) charge generation layer nCGL and a p-type (kind) charge generation layer pCGL. The n-type (kind) charge generation layer nCGL and the p-type (kind) charge generation layer pCGL may have a layer structure that the two are joined to each other.

The n-type (kind) charge generation layer nCGL may be a charge generation layer that provides electrons to the adjacent lower organic layers EE-a. The n-type (kind) charge generation layer nCGL may be a layer in which a base material is doped with an n-dopant. The p-type (kind) charge generation layer pCGL may be a charge generation layer that provides holes to the adjacent organic layers EE-b. The p-type (kind) charge generation layer pCGL may be a layer in which a base material is doped with a p-dopant. In addition, in one or more embodiments, a buffer layer may be further arranged between the n-type (kind) charge generation layer nCGL and the p-type (kind) charge generation layer pCGL. For example, in one or more embodiments, the n-type (kind) charge generation layer nCGL may be an electron transport functional layer having an electron transport function, and the p-type (kind) charge generation layer pCGL may be a hole transport functional layer having a hole transport function.

The charge generation layer CGL may include an n-type (kind) arylamine-based material or a p-type (kind) metal oxide. For example, the charge generation layer CGL may include an arylamine-based organic compound, a carbazole-based compound, a metal, a metal oxide, a carbide, a fluoride, or a charge generation compound formed of a mixture thereof.

For example, the arylamine-based organic compound may be bathophenanthroline (Bphen), N,N′-di(naphthalen-1-yl)-N, N′-diphenyl-benzidine (a-NPD), 4,4′,4″-tris[N(2-naphthyl)-N-phenylamino]-triphenylamine (2-TNATA), 4,4′,4″-tris(N, N-diphenylamino)triphenylamine (TDATA), 4,4′,4″-[tris(3-methylphenyl)phenylamino]triphenylamine (m-TDATA), sprio-TAD, or sprio-NPB, and the carbazole-based compound may be 4,4′-bis(carbazol-9-yl) biphenyl (CBP). For example, the metal may be cesium (Cs), molybdenum (Mo), vanadium (V), titanium (Ti), tungsten (W), barium (Ba), or lithium (Li). In addition, the metal oxide, carbide, and fluoride may include Re₂O₇, MoO₃, V₂O₅, WO₃, TiO₂, Cs₂CO₃, BaF (e.g., BaF₂), LiF, or CsF.

A capping layer CPL may be further arranged on the second electrode CE of the light emitting elements EL and EL-a according to one or more embodiments. The capping layer CPL may include a multi-layer or a single layer.

In one or more embodiments, the capping layer CPL may be an organic layer or an inorganic layer. For example, if (e.g., when) the capping layer CPL includes an inorganic material, the inorganic material may include an alkali metal compound such as LiF, an alkaline earth metal compound such as MgF₂, SiON, SiNx, SiOy, and/or the like.

For example, if (e.g., when) the capping layer CPL includes an organic material, the organic material may include a-NPD, NPB, TPD, m-MTDATA, Alqs CuPc, N4, N4, N4′, N4′-tetra(biphenyl-4-yl) biphenyl-4,4′-diamine (TPD15), 4,4′,4″-tris(carbazol-9-yl)triphenylamine (TCTA), and/or the like or may include an epoxy resin and/or acrylate, such as methacrylate. However, embodiments are not limited thereto, and the capping layer CPL may include at least one of compounds P1 to P5.

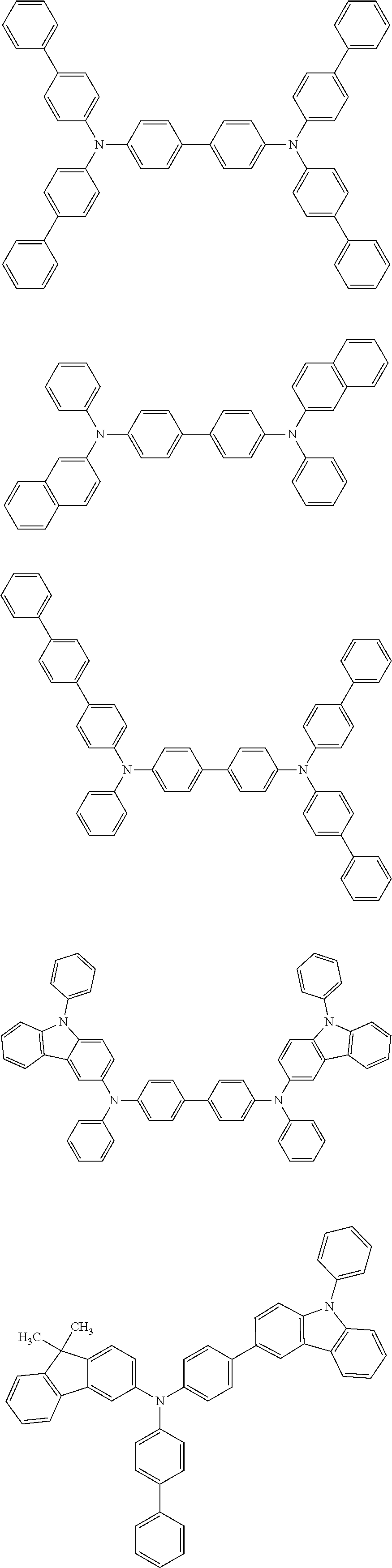 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In one or more embodiments, the capping layer CPL may have a refractive index of about 1.6 or greater. For example, the capping layer CPL may have a refractive index of about 1.6 or greater in a wavelength range of about 550 nm to about 660 nm.

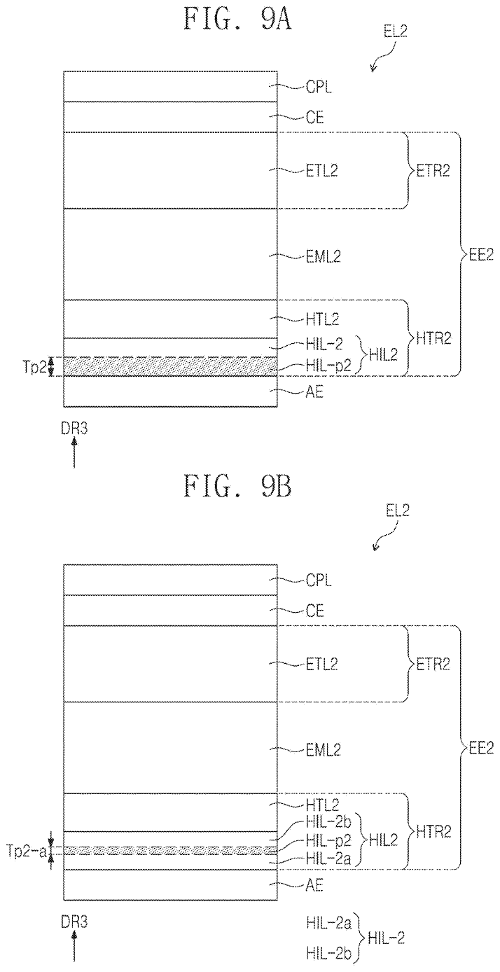

FIGS. 8, 9A, and 9B are cross-sectional views schematically showing a light emitting element according to one or more embodiments. FIG. 8 is a cross-sectional view schematically showing a light emitting element arranged corresponding to a wide pixel. FIGS. 9A and 9B are cross-sectional views schematically showing a light emitting element arranged corresponding to a narrow pixel. In one or more embodiments, the first light emitting element EL1 shown in FIG. 8 may be arranged corresponding to a first red pixel RPX1, a first green pixel GPX1, and a first blue pixel BPX1 shown in FIG. 5. For example, the first light emitting element EL1 of FIG. 8 may be the first light emitting element EL1 of FIG. 6A. In one or more embodiments, the second light emitting element EL2 shown in FIGS. 9A and 9B may be arranged corresponding to a second red pixel PRX2, a second green pixel GPX2, a first sub-blue pixel BPX2-1, and a second sub-blue pixel BPX2-2 shown in FIG. 5. For example, the second light emitting element EL2 shown in each of FIGS. 9A and 9B may be the second light emitting element EL2 of FIG. 6B. Hereinafter, if (e.g., when) describing the first light emitting element EL1 and the second light emitting element EL2 with reference to FIGS. 8, 9A, and 9B, the same/similar reference signs are used for the same/similar components described in FIGS. 6A-7E, and overlapping descriptions will not be provided.

Referring to FIG. 8, the light emitting element EL1 may include a first electrode AE, first organic layers EE1, and a second electrode CE, which are sequentially stacked. The first organic layers EE1 may include a first hole transport region HTR1, a first emission layer EML1, and a first electron transport region ETR1. The first light emitting element EL1 may further include a capping layer CPL arranged on the second electrode CE.

The first hole transport region HTR1 may be on the first electrode AE. The first hole transport region HTR1 may include a first hole injection layer HIL1 and a first hole transport layer HTL1. The first hole injection layer HIL1 may be positioned closer to the first electrode AE than the first hole transport layer HTL1 is. For example, the first hole injection layer HIL1 may be directly arranged on the first electrode AE, and the first hole transport layer HTL1 may be directly arranged on the first hole injection layer HIL1. The first hole transport region HTR1 may further include a buffer layer, an emission auxiliary layer, and/or an electron blocking layer.

The first hole injection layer HIL1 may include a first doped region HIL-p1 and a first undoped region HIL-1. Both the first doped region HIL-p1 and the first undoped region HIL-1 may include a hole injection material. The first doped region HIL-p1 includes a p-dopant, and the first undoped region HIL-1 does not include a p-dopant. The first hole injection layer HIL1 may be divided into a region including a p-dopant and a region not including a p-dopant. The description with reference to FIGS. 7A-7E may also apply to a hole injection material and a p-dopant included in the first hole injection layer HIL1.

The first doped region HIL-p1 may include a p-dopant and a hole injection material. The first doped region HIL-p1 may be a region formed by providing a hole injection material and a p-dopant together on the first electrode AE if (e.g., when) forming the first hole injection layer HIL1. The first doped region HIL-p1 may be a region in which a p-dopant is dispersed (or distributed) between hole injection materials forming the first hole injection layer HIL1.

The first doped region HIL-p1 may be on the first electrode AE. The first doped region HIL-p1 may be in direct contact with the first electrode AE. On a plane, the first doped region HIL-p1 may overlap the first electrode AE entirely. The first doped region HIL-p1 may have a first thickness Tp1. For example, the first thickness Tp1 may be greater than about 0 Å and about 50 Å or less, or greater than about 0 Å and about 75 Å or less. If (e.g., when) the first thickness Tp1 is smaller than a second thickness Tp2 (FIG. 9A), the first thickness Tp1 may be greater than about 0 Å and about 50 Å or less. If (e.g., when) the first thickness Tp1 is equal to a third thickness Tp2-a (FIG. 9B), the first thickness Tp1 may be greater than about 0 Å and about 75 Å or less. However, embodiments are not limited thereto.

The first undoped region HIL-1 may be on the first doped region HIL-p1. The first undoped region HIL-1 may be positioned closer to the first emission layer EML1 than the first doped region HIL-p1 is. A thickness of the first undoped region HIL-1 may be greater than the first thickness Tp1. The first undoped region HIL-1 may be spaced and/or apart (e.g., spaced apart or separated) from the first electrode AE in the thickness direction DR3 with the first doped region HIL-p1 therebetween.

The first undoped region HIL-1 may be a region in which a p-dopant is substantially absent in the first hole injection layer HIL1. The first undoped region HIL-1 may include a hole injection material. The first undoped region HIL-1 may be formed only with a hole injection material for forming the first hole injection layer HIL1. The hole injection material included in the first doped region HIL-p1 and the hole injection material included in the first undoped region HIL-1 may be the same material.

The first doped region HIL-p1 and the first undoped region HIL-1 may be consecutively formed through a process for forming the first hole injection layer HIL. For example, the first doped region HIL-p1 may be formed to have the first thickness Tp1 by opening a first shutter for injecting a hole injection material for forming the first hole injection layer HIL1 while opening a second shutter for injecting a p-dopant together to provide both (e.g., simultaneously) the hole injection material and the p-dopant on the first electrode AE. After the first doped region HIL-p1 is formed to have the first thickness Tp1, only the second shutter may be closed and a hole injection material may be on the first doped region HIL-p1 through the open first shutter, thereby forming the first undoped region HIL-1.

The first hole transport layer HTL1 may be on the first hole injection layer HIL1. The first hole transport layer HTL1 may be in direct contact with the first undoped region HIL-1 included in the first hole injection layer HIL1. The first hole transport layer HTL1 may not be in contact with the first doped region HIL-p1. If (e.g., when) the first hole transport region HTR1 further includes a buffer layer, an emission auxiliary layer, and/or an electron blocking layer, the buffer layer, the emission auxiliary layer, and/or the electron blocking layer may be between the first hole transport layer HTL1 and the first emission layer EML1.

The first emission layer EML1 may be on the first hole transport region HTR1. For example, the first emission layer EML1 may be on an upper surface of the first hole transport layer HTL1. The description of the emission layers EML, EML-a, and EML-b with reference to FIGS. 7A-7E may also apply to the first emission layer EML1. The first electron transport region ETR1 may be provided on the first emission layer EML1. The first electron transport region ETR1 may include a first electron transport layer ETL1. However, embodiments are not limited thereto, and the first electron transport region ETR1 may further include an electron injection layer EIL or a hole blocking layer. The description of the electron transport regions ETR, ETR-a, and ETR-b with reference to FIGS. 7A-7E may also apply to the first electron transport region ETR1.

The second electrode CE may be on the first electron transport region ETR1, and the capping layer CPL may be on the second electrode CE. The description of the second electrode CE and the capping layer CPL with reference to FIGS. 7A-7E may also apply to the second electrode CE and the capping layer CPL of FIG. 8.

Referring to FIGS. 9A and 9B, the second light emitting element EL2 may include a first electrode AE, second organic layers EE2, and a second electrode CE, which are sequentially stacked. The second organic layers EE2 may include a second hole transport region HTR2, a second emission layer EML2, and a second electron transport region ETR2. The second light emitting element EL2 may further include a capping layer CPL arranged on the second electrode CE.

The second hole transport region HTR2 may be on the first electrode AE. The second hole transport region HTR2 may include a second hole injection layer HIL2 and a second hole transport layer HTL2. The second hole injection layer HIL2 may be arranged closer to the first electrode AE than the second hole transport layer HTL2 is. For example, the second hole injection layer HIL2 may be directly arranged on the first electrode AE, and the second hole transport layer HTL2 may be directly arranged on the second hole injection layer HIL2. The second hole transport region HTR2 may further include a buffer layer, an emission auxiliary layer, and/or an electron blocking layer.

The second hole injection layer HIL2 may include a second doped region HIL-p2 and a second undoped region HIL-2. Both the second doped region HIL-p2 and the second undoped region HIL-2 may include a hole injection material. The second doped region HIL-p2 includes a p-dopant, and the second undoped region HIL-2 does not include a p-dopant. The second hole injection layer HIL2 may be divided into a region including a p-dopant and a region not including a p-dopant. The description with reference to FIGS. 7A-7E may also apply to a hole injection material and a p-dopant included in the second hole injection layer HIL2.

The second doped region HIL-p2 may include a p-dopant and a hole injection material. The second doped region HIL-p2 may be a region formed by providing a hole injection material and a p-dopant together if (e.g., when) forming the second hole injection layer HIL2. For example, the second doped region HIL-p2 may be a region in which a p-dopant is dispersed (or distributed) between hole injection materials forming the second hole injection layer HIL2. The p-dopant and the hole injection material included in the second doped region HIL-p2 may be the same as the p-dopant and the hole injection material included in the first doped region HIL-p1 (FIG. 8).

The second doped region HIL-p2 may be on the first electrode AE. On a plane, the second doped region HIL-p2 may overlap the first electrode AE entirely. The second doped region HIL-p2 may have a thickness greater than or equal to the first thickness Tp1 (FIG. 8) of the first doped region HIL-p1 (FIG. 8). The second doped region HIL-p2 may or may not be in contact with the first electrode AE, depending on the thickness of the second doped region HIL-p2.

For example, as shown in FIG. 9A, the second doped region HIL-p2 may have a second thickness Tp2. The second thickness Tp2 may be greater than the first thickness Tp1 (FIG. 8). The second thickness Tp2 may be greater than about 0 Å and about 100 Å or less, but the present disclosure is not limited thereto. The second doped region HIL-p2 having the second thickness Tp2 may be in direct contact with the first electrode AE.

For example, as shown in FIG. 9B, the second doped region HIL-p2 may have a third thickness Tp2-a. The third thickness Tp2-a may be the same as the first thickness Tp1 (FIG.). The third thickness Tp2-a may be greater than about 0 Å and about 75 Å or less, but the present disclosure is not limited thereto. The second doped region HIL-p2 having the third thickness Tp2-a may not be in contact with the first electrode AE. The second doped region HIL-p2 having the third thickness Tp2-a may be spaced apart from the first electrode AE. In addition, the second doped region HIL-p2 having the third thickness Tp2-a may not be in contact with the second emission layer EML2, and may be spaced and/or apart (e.g., spaced apart or separated) from the second emission layer EML2.

The second undoped region HIL-2 may be a region in which a p-dopant is substantially absent in the second hole injection layer HIL2. The second undoped region HIL-2 may include a hole injection material. The second undoped region HIL-2 may be formed only with a hole injection material for forming the second hole injection layer HIL2. The hole injection material included in the second doped region HIL-p2 and the hole injection material included in the second undoped region HIL-2 may be the same or similar material.

The second undoped region HIL-2 may not be in contact with the first electrode AE or at least a portion of the second undoped region HIL-2 may be in contact with the first electrode AE depending on the thickness of the second doped region HIL-p2. For example, referring to FIG. 9A, if (e.g., when) the second doped region HIL-p2 has the second thickness Tp2, the second undoped region HIL-2 may be in contact with the first electrode AE and be on the second doped region HIL-p2. In this case, the second undoped region HIL-2 may be positioned closer to the second emission layer EML2 than the second doped region HIL-p2 is. The second undoped region HIL-2 may be spaced and/or apart (e.g., spaced apart or separated) from the first electrode AE in the thickness direction DR3 with the second doped region HIL-p2 therebetween. If (e.g, when) the second undoped region HIL-2 is not in contact with the first electrode AE is on the second doped region HIL-p2 having the second thickness Tp2, the second undoped region HIL-2 may have a thickness greater than the second thickness Tp2 of the second doped region HIL-p2.

Referring to FIG. 9B, at least a portion of the second undoped region HIL-2 may be on the first electrode AE. The second undoped region HIL-2 may include a (2-1)-th undoped region HIL-2a and a (2-2)-th undoped region HIL-2b. The (2-1)-th undoped region HIL-2a may be in direct contact with the first electrode AE, and the (2-2)-th undoped region HIL-2b may not be in contact with the first electrode AE. The second doped region HIL-p2 may be formed between the (2-1)-th undoped region HIL-2a and the (2-2)-th undoped region HIL-2b. The (2-2)-th undoped region HIL-2b may positioned closer to the second emission layer EML2 than the second doped region HIL-p2 is, and the second doped region HIL-p2 may be positioned closer to the second emission layer EML2 than the (2-1)-th undoped region HIL-2a.

The thickness of the (2-1)-th undoped region HIL-2a and the thickness of the (2-2)-th undoped region HIL-2b may be the same as or different from each other. In FIG. 9B, the thickness of the second undoped region HIL-2 may be the sum of the thicknesses of the (2-1)-th undoped region HIL-2a and the (2-2)-th undoped region HIL-2b, and the thickness of the second undoped region HIL-2 may be greater than the third thickness Tp2-a of the second doped region HIL-p2.

The second doped region HIL-p2 and the second undoped region HIL-2 may be consecutively formed through a process for forming the second hole injection layer HIL2. The second hole injection layer HIL2 may be formed with the second doped region HIL-p2 and the second undoped region HIL-2 distinguished according to the opening and closing of the second shutter for injecting a p-dopant while the first shutter for injecting a hole injection material remains open.

For example, the second doped region HIL-p2 shown in FIG. 9A may be formed to have the second thickness Tp2 by opening the second shutter together with the first shutter if (e.g., when) the first shutter is open and a hole injection material is provided to an upper surface of the first electrode AE to provide the hole injection material and the p-dopant together to the upper surface of the first electrode AE. After the second doped region HIL-p2 is formed to have the second thickness Tp2, the second shutter may be closed while only the first shutter remains open, allowing only the hole injection material to be provided onto the second doped region HIL-p2, thereby forming the second undoped region HIL-2.

For example, the (2-1)-th undoped region HIL-2a shown in FIG. 9B may be formed by providing only the hole injection material on an upper surface of the first electrode AE while the first shutter is open and the second shutter is closed. Thereafter, while the first shutter and the second shutter are open together, the hole injection material and the p-dopant may be provided together onto the (2-1)-th undoped region HIL-2a to form the second doped region HIL-p2 having the third thickness Tp2-a. Then, by closing only the second shutter among the open first and second shutters, only the hole injection material may be provided onto the second doped region HIL-p2, thereby forming the (2-2)-th undoped region HIL-2b.

The second hole injection layer HIL2 shown in FIGS. 9A and 9B may have the same thickness as the first hole injection layer HIL1 shown in FIG. 8. Accordingly, even if (e.g., when) the first doped region HIL-p1 included in the first light emitting element EL1 and the second doped region HIL-p2 included in the second light emitting element EL2 have different thicknesses or positions, a resonance thickness of the first light emitting element EL1 and a resonance thickness of the second light emitting element EL2 may be substantially the same.

The second hole transport layer HTL2 may be on the second hole injection layer HIL2. The second hole transport layer HTL2 may be in direct contact with a portion of the second undoped region HIL-2 included in the second hole injection layer HIL2. The second hole transport layer HTL2 may not be in contact the (2-1)-th undoped region HIL-2a and may be in direct contact with the (2-2)-th undoped region HIL-2b. The second hole transport layer HTL2 may not be in contact with the second doped region HIL-p2. When the second hole transport region HTR2 further includes a buffer layer, an emission auxiliary layer, and/or an electron blocking layer may be between the second hole transport layer HTL2 and the second emission layer EML2.

The second emission layer EML2 may be on the second hole transport region HTR2. For example, the second emission layer EML2 may be on an upper surface of the second hole transport layer HTL2. The description of the emission layers EML, EML-a, and EML-b with reference to FIGS. 7A-7E may also apply to the second emission layer EML2. The second electron transport region ETR2 may be on the second emission layer EML2. The second electron transport region ETR2 may include a second electron transport layer ETL2. However, embodiments are not limited thereto, and the second electron transport region ETR2 may further include an electron injection layer EIL and/or a hole blocking layer. For example, the second electron transport region ETR2 may include a second electron transport layer ETL2 and an electron injection layer. The description of the electron transport regions ETR, ETR-a, and ETR-b with reference to FIGS. 7A-7E may also apply to the second electron transport region ETR2.

The second electrode CE may be on the second electron transport region ETR2, and the capping layer CPL may be on the second electrode CE. The description of the second electrode CE and the capping layer CPL with reference to FIGS. 7A-7E may also apply to the second electrode CE and the capping layer CPL of FIG. 9A and FIG. 9B.

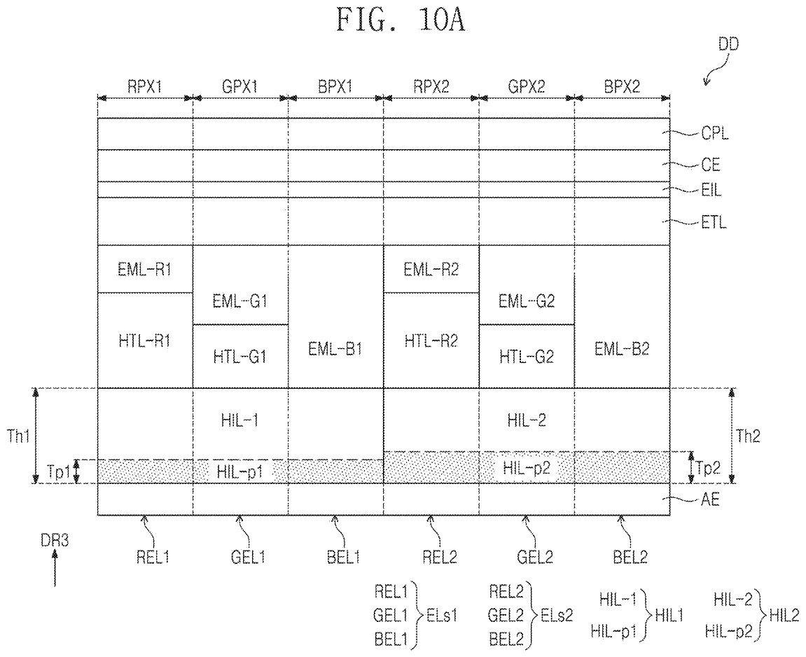

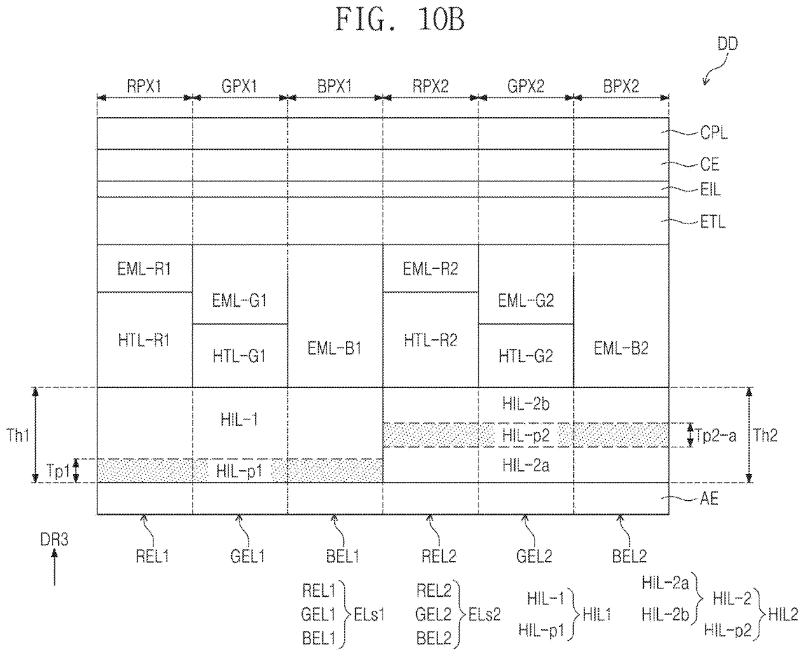

FIGS. 10A and 10B are cross-sectional views showing some components of a display device DD according to one or more embodiments. FIGS. 10A and 10B are cross-sectional views schematically showing a display panel included in a display device DD according to one or more embodiments. FIGS. 10A and 10B schematically show a display panel including light emitting elements according to one or more embodiments. For example, FIGS. 10A and 10B schematically show a form in which a plurality of arbitrary light emitting elements are provided corresponding to each of wide pixels and narrow pixels. FIGS. 10A and 10B schematically show light emitting elements REL1, GEL1, BEL1, REL2, GEL2, and BEL2 arranged corresponding to each of a first red pixel RPX1, a first green pixel GPX1, a first blue pixel BPX1, a second red pixel RPX2, a second green pixel GPX2, and a second blue pixel BPX2. For FIGS. 10A and 10B, the same/similar reference signs are used for the same/similar components described in FIGS. 5-9B, and any description overlapping those described in FIGS. 5-9B will not be provided.

Referring to FIGS. 10A and 10B, the display device DD according to one or more embodiments may include first light emitting elements ELs1 arranged corresponding to wide pixels RPX1, GPX1, and BPX1 and second light emitting elements ELs2 arranged corresponding to narrow pixels RPX2, GPX2, and BPX2. In FIGS. 10A and 10B, the sizes of the first light emitting elements ELs1 and the second light emitting elements ELs2 are shown to be similar, but are not limited thereto. For example, in one direction perpendicular to the third direction DR3, the first light emitting elements ELs1 corresponding to the wide pixels RPX1, GPX1, and BPX1 may have a greater width than the second light emitting elements ELs2 corresponding to the narrow pixels RPX2, GPX2, and BPX2.

The first light emitting elements ELs1 may include a first red light emitting element REL1, a first green light emitting element REL1, and a first blue light emitting element BEL1. On a plane, the first red light emitting element REL1 may overlap the first red pixel RPX1, the first green light emitting element GEL1 may overlap the first green pixel GPX1, and the first blue light emitting element BEL1 may overlap the first blue pixel BPX1.

A stack structures of the first red light emitting element REL1, the first green light emitting element GEL1, and the first blue light emitting element BEL1 may be the same as or different from each other. In one or more embodiments, the first red light emitting element REL1 may include a first electrode AE, a first hole injection layer HIL1, a first red hole transport layer HTL-R₁, a first red emission layer EML-R₁, an electron transport layer ETL, an electron injection layer EIL, and a second electrode CE, which are sequentially stacked in the thickness direction DR3. The first green light emitting element GEL1 may include a first electrode AE, a first hole injection layer HIL1, a first green hole transport layer HTL-G1, a first green emission layer EML-G1, an electron transport layer ETL, an electron injection layer EIL, and a second electrode CE, which are sequentially stacked in the thickness direction DR3. The first blue light emitting element BEL1 may include a first electrode AE, a first hole injection layer HIL1, a first blue emission layer EML-B1, an electron transport layer ETL, an electron injection layer EIL, and a second electrode CE, which are sequentially stacked in the thickness direction DR3. The first red light emitting element REL1, the first green light emitting element GEL1, and the first blue light emitting element BEL1 may further include a capping layer CPL.

The second light emitting elements ELs2 may include a second red light emitting element REL2, a second green light emitting element GEL2, and a second blue light emitting element BEL2. On a plane, the second red light emitting element REL2 may overlap the second red pixel RPX2, the second green light emitting element GEL2 may overlap the second green pixel GPX2, and the second blue light emitting element BEL2 may overlap the second blue pixel BPX2. The second blue light emitting element BEL2 may be arranged corresponding to each of the first sub-blue pixel BPX2-1 (FIG. 5) and the second sub-blue pixel BPX2-2 (FIG. 5). The stack structures of the second red light emitting element REL2, the second green light emitting element GEL2, and the second blue light emitting element BEL2 may be the same as or different from each other.

The stack structures of the second red light emitting element REL2, the second green light emitting element GEL2, and the second blue light emitting element BEL2 may be the same as or different from each other. In one or more embodiments, the second light emitting element REL2 may include a first electrode AE, a second red hole injection layer HIL2, a second red hole transport layer HTL-R2, a second red emission layer EML-R2, an electron transport layer ETL, an electron injection layer EIL, and a second electrode CE, which are sequentially stacked in the thickness direction DR3. The second green light emitting element GEL2 may include a first electrode AE, a second hole injection layer HIL2, a second green hole transport layer HTL-G2, a second green emission layer EML-G2, an electron transport layer ETL, an electron injection layer EIL, and a second electrode CE, which are sequentially stacked in the thickness direction DR3. The second blue light emitting element BEL2 may include a first electrode AE, a second hole injection layer HIL2, a second blue emission layer EML-B2, an electron transport layer ETL, an electron injection layer EIL, and a second electrode CE, which are sequentially stacked in the thickness direction DR3. The second red light emitting element REL2, the second green light emitting element GEL2, and the second blue light emitting element BEL2 may further include a capping layer CPL.

In the first light emitting elements ELs1 and the second light emitting elements Els2, each of the first hole injection layer HIL1 and the second hole injection layer HIL2 may be formed using a fine metal mask (FMM). For example, the first hole injection layer HIL1 may be formed as a common layer overlapping the first red pixel RPX1, the first green pixel GPX1, and the first blue pixel BPX1, using a fine metal mask (FMM). The first hole injection layer HIL1 may not overlap the second red pixel RPX2, the second green pixel GPX2, and the second blue pixel BPX2. The second hole injection layer HIL2 may be formed as a common layer overlapping the second red pixel RPX2, the second green pixel GPX2, and the second blue pixel BPX2, using a fine metal mask (FMM). The second hole injection layer HIL2 may not overlap the first red pixel RPX1, the first green pixel GPX1, and the first blue pixel BPX1. A thickness Th1 of the first hole injection layer HIL1 and a thickness Th2 of the second hole injection layer HIL2 may be the same. In one or more embodiments, the first hole injection layer and the second hole injection layer may be formed utilizing the same fine metal mask (FMM) process described herein. This should enable consistent layer alignment and thickness control across pixel groups.

Referring to FIG. 10A, the first doped region HIL-p1 included in the first hole injection layer HIL1 may have a different thickness from the second doped region HIL-p2 included in the second hole injection layer HIL2. The first doped region HIL-p1 may have a first thickness Tp1, and the second doped region HIL-p2 may have a second thickness Tp2 greater than the first thickness Tp1. The first doped region HIL-p1 and the second doped region HIL-p2 having different thicknesses may be both (e.g., simultaneously) in direct contact with the first electrode AE.

The first doped region HIL-p1 having the first thickness Tp1 may overlap the first red pixel RPX1, the first green pixel GPX1, and the first blue pixel BPX1, and be on the first electrode AE. The second doped region HIL-p2 having the second thickness Tp2 may commonly overlap the second red pixel RPX2, the second green pixel GPX2, and the second blue pixel BPX2, and be on the first electrode AE. In addition, the first undoped region HIL-1 may commonly overlap the first red pixel RPX1, the first green pixel GPX1, and the first blue pixel BPX1, and be on the first doped region HIL-p1. The second undoped region HIL-2 may commonly overlap the second red pixel RPX2, the second green pixel GPX2, and the second blue pixel BPX2, and be on the second doped region HIL-p2.

The narrow pixels RPX2, GPX2, and BPX2 may have a relatively smaller opening area than the wide pixels RPX1, GPX1, and BPX1, and the wide pixels RPX1, GPX1, and BPX1 and the narrow pixels RPX2, GPX2, and BPX2 having different opening areas may have differences in luminous efficiency, resulting in different levels of gray crushing if (e.g., when) the display device DD is driven in the first mode and the second mode. The display device DD according to one or more embodiments may form a first doped region HIL-p1 of a first hole injection layer HIL1 corresponding to wide pixels RPX1, GPX1, and BPX1 and a second doped region HIL-p2 of a second hole injection layer HIL2 corresponding to narrow pixels RPX2, GPX2, and BPX2 with different thicknesses, thereby reducing a difference in gray crushing level between the wide pixels RPX1, GPX1, and BPX1 and the narrow pixels RPX2, GPX2, and BPX2. Accordingly, a color difference occurring between the wide pixels RPX1, GPX1, and BPX1 and the narrow pixels RPX2, GPX2, and BPX2 if (e.g., when) driving in the first mode and the second mode may be reduced. Accordingly, the display device DD according to one or more embodiments may provide the same color perception in both (e.g., simultaneously) the first mode and the second mode if (e.g., when) driving the same image in each of the first mode and the second mode.

FIG. 10B partially differs in components of the second hole injection layer HIL2 compared to FIG. 10A. Referring to FIG. 10B, the second doped region HIL-p2 included in the second hole injection layer HIL2 may have the same thickness as the first doped region HIL-p1 included in the first hole injection layer HIL1. The second doped region HIL-p2 may have a third thickness Tp2a that is the same as the first thickness Tp1.

The second doped region HIL-p2 having the third thickness Tp2a that is the same as the first thickness Tp1 may be spaced and/or apart (e.g., spaced apart or separated) from the first electrode AE. The second doped region HIL-p2 having the third thickness Tp2a may overlap the second red pixel RPX2, the second green pixel GPX2, and the second blue pixel BPX2, and may be in non-contact with the first electrode AE. The second doped region HIL-p2 having the third thickness Tp2a may be located farther from the first electrode AE than the first doped region HIL-p1 is. In addition, the second doped region HIL-p2 having the third thickness Tp2a may be positioned closer to the second electrode CE than the first doped region HIL-p1 is.

The second undoped region HIL-2 may include a (2-1)-th undoped region HIL-2a and a (2-2)-th undoped region HIL-2b overlapping the second red pixel RPX2, the second green pixel GPX2, and the second blue pixel BPX2. The (2-1)-th undoped region HIL-2a and the (2-2)-th undoped region HIL-2b may commonly overlap the second red pixel RPX2, the second green pixel GPX2, and the second blue pixel BPX2, and be provided on the first electrode AE. The (2-1)-th undoped region HIL-2a may be located between the first electrode AE and the second doped region HIL-p2, and may be in direct contact with the first electrode AE. The (2-2)-th undoped region HIL-2b may be provided on the second doped region HIL-p2, and may not be in contact with the first electrode AE.

In one or more embodiments, the display device DD according to one or more embodiments may form the second doped region HIL-p2 at a position spaced and/or apart (e.g., spaced apart or separated) from the first electrode AE if (e.g., when) the first doped region HIL-p1 of the first hole injection layer HIL1 corresponding to the wide pixels RPX1, GPX1, and BPX1 and the second doped region HIL-p2 of the second hole injection layer HIL2 corresponding to the narrow pixels RPX2, GPX2, and BPX2 have the same thickness, thereby reduce a difference in gray crushing level between the wide pixels RPX1, GPX1, and BPX1 and the narrow pixels RPX2, GPX2, and BPX2. Accordingly, a color difference occurring between the wide pixels RPX1, GPX1, and BPX1 and the narrow pixels RPX2, GPX2, and BPX2 if (e.g., when) driving in the first mode and the second mode may be reduced. Accordingly, the display device DD according to one or more embodiments may provide the same color perception in both (e.g., simultaneously) the first mode and the second mode if (e.g., when) driving the same image in each of the first mode and the second mode.

The display device DD according to one or more embodiments and the electronic device ED (FIGS. 1 and 3, and/or the like) including the same may provide excellent or suitable display quality in both (e.g., simultaneously) the first mode and the second mode as the color difference between the wide pixel and the narrow pixel is reduced in the first mode which is a public mode (general mode) and the second mode which is a viewing angle control mode.

Referring to FIGS. 10A and 10B, the first red hole transport layer HTL-R1, the first green hole transport layer HTL-G1, the second red hole transport layer HTL-R2, and the second green hole transport layer HTL-G2 may be provided as pattern layers overlapping only corresponding pixels. For example, the first red hole transport layer HTL-R1 may overlap the first red pixel RPX1 and may not overlap the other pixels GPX1, BPX1, RPX2, GPX2, and BPX2, and the first green hole transport layer HTL-G1 may overlap the first green pixel GPX1 and may not overlap the other pixels RPX1, BPX1, RPX2, GPX2, and BPX2. In addition, the second red hole transport layer HTL-R2 may overlap the second red pixel RPX2 and may not overlap the other pixels GPX1, BPX1, BPX1, GPX2, and BPX2, and the second green hole transport layer HTL-G2 may overlap the second green pixel GPX2 and may not overlap the other pixels RPX1, BPX1, RPX1, RPX2, and BPX2.

The thicknesses of the hole transport layers HTL-R1, HTL-G1, HTL-R2, and HTL-G2 included in the first light emitting elements ELs1 and the second light emitting elements ELs2 may be the same or different. For example, the thicknesses of the first red hole transport layer HTL-R1 and the second red hole transport layer HTL-R2 may be the same, and the thicknesses of the first green hole transport layer HTL-G1 and the second green hole transport layer HTL-G2 may be the same. The first red hole transport layer HTL-R1 and the second red hole transport layer HTL-R2 may have a greater thickness than the first green hole transport layer HTL-G1 and the second green hole transport layer HTL-G2, but embodiments are not limited thereto. In one or more embodiments, the thicknesses of the hole transport layers HTL-R1, HTL-G1, HTL-R2, and HTL-G2 included in the first light emitting elements ELs1 and the second light emitting elements ELs2 may all be the same. In FIGS. 10A and 10B, the first blue light emitting element BEL1 and the second blue light emitting element BEL2 are shown not to include a hole transport layer, but may include a hole transport layer unlike what is shown.

The first red emission layer EML-R1, the first green emission layer EML-G1, the first blue emission layer EML-B1, the second red emission layer EML-R2, the second green emission layer EML-G2, and the second blue emission layer EML-B2 may be provided as pattern layers overlapping only corresponding pixels. For example, the first red emission layer EML-R1 may overlap the first red pixel RPX1 and may not overlap the other pixels GPX1, BPX1, RPX2, GPX2, and BPX2 except for the first red pixel RPX1. The first green emission layer EML-G1 may overlap the first green pixel GPX1 and may not overlap the other pixels RPX1, BPX1, RPX2, GPX2, and BPX2 except for the first green pixel GPX1. The first blue emission layer EML-B1 may overlap the first blue pixel BPX1 and may not overlap the other pixels RPX1, GPX1, RPX2, GPX2, and BPX2 except for the first blue pixel BPX1. In addition, the second red emission layer EML-R2 may overlap the second red pixel RPX2 and may not overlap the other pixels GPX1, BPX1, BPX1, GPX2, and BPX2 except for the second red pixel RPX2, and the second green emission layer EML-G2 may overlap the second green pixel GPX2 and may not overlap the other pixels RPX1, BPX1, RPX1, RPX2, and BPX2 except for the second green pixel GPX2. The second blue emission layer EML-B2 may overlap the second blue pixel BPX2 and may not overlap the other pixels RPX1, GPX1, BPX1, RPX2, and GPX2 except for the second blue pixel BPX2.

The thicknesses of the emission layers EML-R1, EML-G1, EML-B1, EML-R2, EML-G2, and EML-B2 included in the first light emitting elements ELs1 and the second light emitting elements ELs2 may be the same as or different from each other. For example, the thicknesses of the first red emission layer EML-R1, the first green emission layer EML-G1, the second red emission layer EML-R2, and the second green emission layer EML-G2 may be substantially the same. The thicknesses of the first red emission layer EML-R1 and the second red emission layer EML-R2 may be different from the thicknesses of the first green emission layer EML-G1 and the second green emission layer EML-G2. The first blue emission layer EML-B1 may have the same thickness as the second blue emission layer EML-B2. The first blue emission layer EML-B1 and the second blue emission layer EML-B2 may have a greater thickness than the first red emission layer EML-R1, the first green emission layer EML-G1, the second red emission layer EML-R2, and the second green emission layer EML-G2, but embodiments are not limited thereto. In one or more embodiments, the thicknesses of the emission layers EML-R1, EML-G1, EML-B1, EML-R2, EML-G2, and EML-B2 included in the first emitting elements ELs1 and the second emitting elements ELs2 may all be the same.

The electron transport layer ETL, the electron injection layer EIL, the second electrode CE, and the capping layer CPL may be commonly formed in a plurality of pixels using an open mask. The electron transport layer ETL, the electron injection layer EIL, the second electrode CE, and the capping layer CPL may be provided as common layers overlapping all of the first red pixel RPX1, the first green pixel GPX1, the first blue pixel BPX1, the second red pixel RPX2, the second green pixel GPX2, and the second blue pixel BPX2.

Hereinafter, with reference to the Example and Comparative Example, characteristic evaluation results of a display device according to one or more embodiments of the disclosure will be described. Examples are shown only for the understanding of the disclosure, and the scope of the disclosure is not limited thereto.

### Manufacturing of Display Device and Results of Characteristic Evaluation

Display devices of the Comparative Example and Example were manufactured to include light emitting elements corresponding to the wide pixels RPX1, GPX1, and BPX1 and the narrow pixels RPX2, GPX2, and BPX2 each shown in FIG. 5. For example, the display device of Comparative Example was manufactured to include a light emitting element having the stack structure shown in FIG. 10A, and to have hole injection layers, included in the light emitting elements corresponding to the wide pixels and the light emitting elements corresponding to the narrow pixels, having a thickness of 1400 Å, and a first doped region and a second doped region having the same thickness as 75 Å formed therein. The display device of Example was manufactured to include a light emitting element having the stack structure shown in FIG. 10A, and to have hole injection layers, included in the light emitting elements corresponding to the wide pixels and the light emitting elements corresponding to the narrow pixels, having a thickness of 1400 Å, and the second doped region (75 Å) having a greater thickness than the first doped region (50 Å) formed therein. The display devices of Comparative Example and Example were formed with the same first electrodes, organic layers, and second electrodes of the light emitting elements corresponding to each of the wide pixels WP and the narrow pixels NP, except for a thickness relationship between the second doped region and the first doped region including a p-dopant.

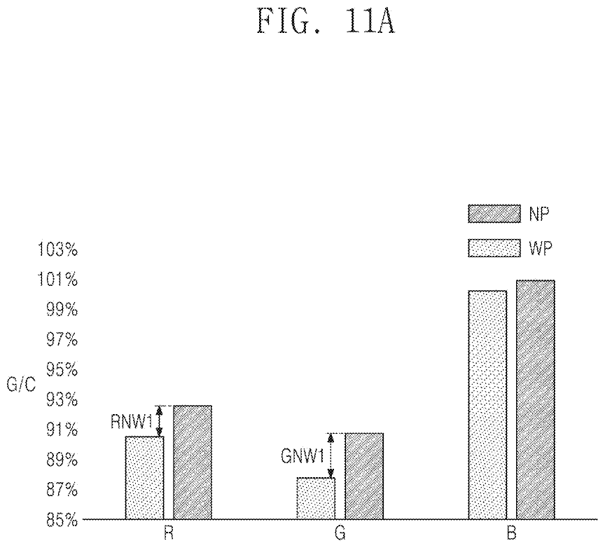

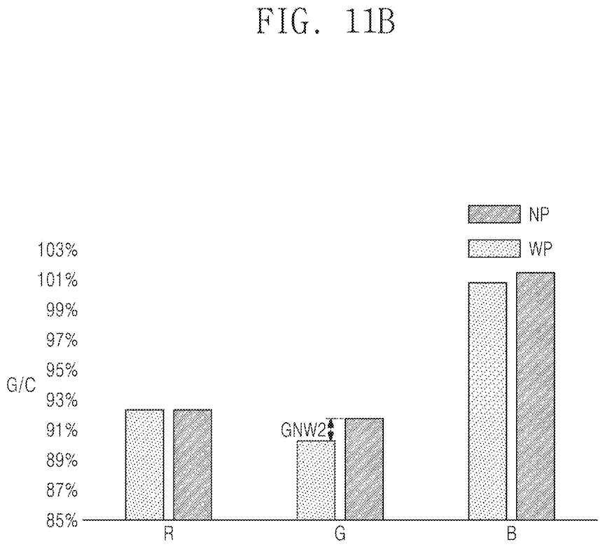

FIGS. 11A and 11B are graphs showing the results of evaluating gray crushing indices for display devices according to Comparative Example and Example. In FIG. 11A, a gray crushing index of the display device of Comparative Example was measured and shown, and in FIG. 11B, a gray crushing index of the display device of Example was measured and shown. When the gray crushing index is about 90% or greater, there is no gradation collapse, and thus may be determined that the display device exhibits excellent or suitable luminance and luminous efficiency at all luminance levels.

In each of FIGS. 11A and 11B, “NP” indicates a narrow pixel, and “WP” indicates a wide pixel. In addition, in each of FIGS. 11A and 11B, as indicated on the x-axis, “R” refers to a red pixel, “G” refers to a green pixel, and “B” refers to a blue pixel. In each of FIGS. 11A and 11B, as indicated on the y-axis, “G/C” refers to a gray crushing index. In FIG. 11A, “RNW1” refers to a gray crushing index difference between a red pixel of a wide pixel and a red pixel of a narrow pixel. In addition, in FIGS. 11A and 11B, “GNW1” and “GNW2” refer to a gray crushing index difference between a green pixel of a wide pixel and a green pixel of a narrow pixel. In FIGS. 11A and 11B, the gray crushing index is an item indicating a degree of color mixing in a low field, and was calculated by measuring the luminance and chromaticity of white (W), red (R), green (G), and blue (B). The luminance and chromaticity of the W, R, G, and B patterns corresponding to 51 gradations were measured with a spectrometer at a dimming brightness targeting 10 nit for 255 gradations, and a ratio of the measured luminance to the desired or required luminance for each of R, G, and B was expressed as a gray crushing index. When the measured luminance and the desired or required luminance may each independently be the same, the gray crushing index is 100%, indicating that there is no gradation collapse. The luminance and chromaticity measurements utilized to calculate the gray crushing index may be obtained utilizing a suitable spectroradiometer. Comparable instruments should yield indistinguishable results under the same measurement conditions.

Referring to FIGS. 11A and 11B, the display device of Comparative Example was observed to have a gray crushing index of less than about 90% for the green pixel (G) included in the wide pixel WP. In comparison, the display device of Example was observed to have a gray crushing index of about 90% or greater for all of the red/green/blue pixels (R, G, B) included in the wide pixel WP and the narrow pixel NP. Accordingly, it may be determined that the display device of Example exhibits superior luminance and luminous efficiency compared to the display device of Comparative Example.

In addition, the display device of Comparative Example was observed to have RNW1, while the display device of Example was observed to have substantially the same gray crushing index between the red pixel of the wide pixel WP and the red pixel of the narrow pixel NP. In addition, the display device of Example was observed to have GNW2 smaller than GNW1 of the display device of Comparative Example. Accordingly, it may be seen that the display device of Example has a smaller gray crushing index difference between the wide pixel and the narrow pixel, resulting in a reduced cause of color difference. Therefore, the display device of Example exhibiting a reduced cause of color difference may maintain substantially the same color perception in both (e.g., simultaneously) the normal mode and the viewing angle control mode if (e.g., when) driving images. In addition, an electronic device according to one or more embodiments includes the display device of Example, and thus may maintain images with the same color perception if (e.g., when) switching to either the normal mode or the viewing angle control mode, thereby exhibiting excellent or suitable reliability and improved display quality.

An electronic device according to one or more embodiments may include a first light emitting element corresponding to a wide pixel and a second light emitting element corresponding to a narrow pixel, and may include doped regions having different thicknesses or positions in a hole injection layer of the first light emitting element and the second light emitting element. Accordingly, the electronic device according to one or more embodiments may be improved to prevent or reduce a gray crushing difference between the wide pixel and the narrow pixel from taking place.

In addition, the electronic device according to one or more embodiments may be switchable to a normal mode or a viewing angle control mode, and if (e.g., when) the same image is driven in the normal mode and the viewing angle control mode, a color difference between the wide pixel and the narrow pixel may be reduced, and this allows the color perception of the image to remain substantially consistent, regardless of the driving mode. Therefore, the electronic device according to one or more embodiments may provide improved image display quality and reliability.

The utilization of “may” when describing embodiments of the present disclosure refers to “one or more embodiments of the present disclosure.”

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value. Also, it should be understood that, even if the terms “about,” “approximately,” or “substantially” are not expressly recited in a given element *e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

In the context of the present application and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light-emitting element, the display apparatus/device, the electronic apparatus/device, the manufacturing apparatuses thereof, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

In the present disclosure, each suitable feature of the various embodiments of the disclosure may be combined or combined with each other, partially or entirely, and may be technically interlocked and operated in various suitable ways, and each embodiment may be implemented independently of each other or in conjunction with each other in any suitable manner unless otherwise stated or implied.

In the above, description has been made with reference to one or more embodiments of the disclosure, but those skilled or of ordinary skill in the art may understand that one or more suitable modifications and changes may be made to the disclosure insofar as such modifications and changes do not depart from the spirit and technical scope of the disclosure set forth in the appended claims and equivalents thereof. Therefore, the technical scope of the disclosure is not to be limited to the contents stated in the detailed description of the specification, but should be determined by the appended claims and equivalents thereof.

What is claimed is:

1. An electronic device comprising a display panel comprising a first pixel having a first opening area, a second pixel having a second opening area smaller than the first opening area, a first light emitting element corresponding to the first pixel, and a second light emitting element corresponding to the second pixel,
wherein each of the first light emitting element and the second light emitting element comprises a first electrode, a plurality of organic layers, and a second electrode,
the organic layers of the first light emitting element comprise a first hole transport region comprising a first hole injection layer, a first emission layer, and a first electron transport region,
the organic layers of the second light emitting element comprise a second hole transport region comprising a second hole injection layer, a second emission layer, and a second electron transport region,
the first hole injection layer comprises a first doped region comprising a p-dopant and having a first thickness, and
the second hole injection layer comprises a second doped region comprising the p-dopant and having a second thickness greater than the first thickness, or comprises a second doped region comprising the p-dopant and having a third thickness equal to the first thickness.

2. The electronic device of claim 1, wherein the second hole injection layer comprises the second doped region having the second thickness,
the first doped region is in direct contact with the first electrode of the first light emitting element, and
the second doped region is in direct contact with the first electrode of the second light emitting element.

3. The electronic device of claim 2, wherein the first hole injection layer further comprises a first undoped region that does not comprise the p-dopant,
the second hole injection layer further comprises a second undoped region that does not comprise the p-dopant, and
the first undoped region is on the first doped region, and the second undoped region is on the second doped region.

4. The electronic device of claim 2, wherein the first thickness is greater than 0 Å and 50 Å or less, and
the second thickness is greater than 0 Å and 100 Å or less.

5. The electronic device of claim 1, wherein the second hole injection layer comprises the second doped region having the third thickness, and
the first doped region is in direct contact with the first electrode of the first light emitting element, and the second doped region is spaced apart from the first electrode of the second light emitting element in a thickness direction.

6. The electronic device of claim 5, wherein the first hole injection layer further comprises a first undoped region that does not comprise the p-dopant,
the second hole injection layer further comprises a second undoped region that does not comprise the p-dopant, and
the second undoped region comprises a first sub-undoped region and a second sub-undoped region.

7. The electronic device of claim 6, wherein
the first undoped region is on the first doped region;
the first sub-undoped region is in direct contact with the first electrode of the second light emitting element; and
the second sub-undoped region is spaced apart from the first sub-undoped region with the second doped region therebetween.

8. The electronic device of claim 6, wherein each of the first thickness and the third thickness is greater than 0 Å and 75 Å or less.

9. The electronic device of claim 1, wherein the first hole injection layer and the second hole injection layer have the same thickness.

10. The electronic device of claim 1, wherein the first hole transport region further comprises a first hole transport layer, and the second hole transport region further comprises a second hole transport layer,
the first hole transport layer is between the first hole injection layer and the first emission layer, and
the second hole transport layer is between the second hole injection layer and the second emission layer.

11. The electronic device of claim 1, wherein the first electron transport region and the second electron transport region each comprise at least one of an electron injection layer, an electron transport layer, or a hole blocking layer.

12. The electronic device of claim 1, wherein the display panel is configured to display an image in a first mode or a second mode,
the first mode is a mode that displays the image at a first viewing angle, and
the second mode is a mode that displays the image at a second viewing angle that is narrower than the first viewing angle.

13. The electronic device of claim 12, wherein in the first mode, the first light emitting element is driven and the second light emitting element is not driven, and
in the second mode, the first light emitting element is not driven and the second light emitting element is driven.

14. The electronic device of claim 12, comprising a display device comprising the display panel,
wherein the display device comprises a first region and a second region adjacent to the first region, and
at least one of the first region or the second region is switched to the first mode or the second mode.

15. The electronic device of claim 1, further comprising an optical path control layer on the display panel,
wherein the optical path control layer comprises a black matrix in which a transmitting portion is defined.

16. The electronic device of claim 15, wherein in plan view, the second light emitting element overlaps the black matrix.

17. An electronic device comprising a display device, the display device comprising a first pixel group and a second pixel group that are spaced apart in a first direction and displaying an image,
wherein the first pixel group comprises a first red pixel, a first green pixel, and a first blue pixel that are spaced apart in a second direction crossing the first direction,
the second pixel group comprises a second red pixel, a second green pixel, and a second blue pixel that are spaced apart in the second direction,
the display device comprises:
a plurality of first light emitting elements corresponding to each of the first red pixel, the first green pixel, and the first blue pixel; and a plurality of second light emitting elements corresponding to each of the second red pixel, the second green pixel, and the second blue pixel,
the first light emitting elements comprise a first hole injection layer commonly overlapping the first red pixel, the first green pixel, and the first blue pixel,
the second light emitting elements comprise a second hole injection layer commonly overlapping the second red pixel, the second green pixel, and the second blue pixel,
the first hole injection layer comprises a first doped region comprising a p-dopant and having a first thickness, and
the second hole injection layer comprises a second doped region comprising the p-dopant and having a second thickness greater than the first thickness, or comprises a second doped region comprising the p-dopant and having a third thickness equal to the first thickness.

18. The electronic device of claim 17, wherein the first red pixel has a greater area in plan view than the second red pixel,
the first green pixel has a greater area in plan view than the second green pixel, and
the first blue pixel has a greater area on a plane than the second blue pixel.

19. The electronic device of claim 17, wherein the first light emitting elements comprise a first red light emitting element corresponding to the first red pixel, a first green light emitting element corresponding to the first green pixel, and a first blue light emitting element corresponding to the first blue pixel,
the second light emitting elements comprise a second red light emitting element corresponding to the second red pixel, a second green light emitting element corresponding to the second green pixel, and a second blue light emitting element corresponding to the second blue pixel, and
each of the first red light emitting element, the first green light emitting element, the first blue light emitting element, the second red light emitting element, the second green light emitting element, and the second blue light emitting element overlaps only the corresponding pixel and comprises an emission layer provided as a pattern layer.

20. The electronic device of claim 17, wherein each of the first light emitting elements and the second light emitting elements further comprises a first electrode,
when the second doped region has the second thickness, the first doped region and the second doped region are in contact with the first electrode, and when the second doped region has the third thickness, the first doped region is in contact with the first electrode and the second doped region is spaced apart from the first electrode.
